(19) United States
(12) Patent Application Publication
(10) Pub. No.: US 2016/0054616 A1
(43) Pub. Date: Feb. 25, 2016

(54) ARRAY SUBSTRATE, LIQUID CRYSTAL DISPLAY ELEMENT, AND RADIATION-SENSITIVE RESIN COMPOSITION

(71) Applicant: JSR CORPORATION, Tokyo (JP)

(72) Inventors: Naoyuki MAKIUCHI, Minato-ku (JP); Yasunobu SUZUKI, Minato-ku (JP)

(73) Assignee: JSR CORPORATION, Minato-ku, Tokyo (JP)

(21) Appl. No.: 14/782,421

(22) PCT Filed: Apr. 2, 2014
(86) PCT No.: PCT/JP2014/059758

§ 371 Date: Oct. 5, 2015

(30) Foreign Application Priority Data
Apr. 5, 2013 (JP) 2013-079537

(51) Int. Cl. G02F 1/1333; G03F 7/039; G03F 7/038; G02F 1/1343

(52) U.S. Cl. CPC G02F 1/133345; G02F 1/134363; G03F 7/039; G03F 7/038; G02F 2001/134372

(57) ABSTRACT

An array substrate with an insulation film which can easily be formed and the dielectric properties of which can be controlled, a liquid crystal display element including the array substrate, and a radiation-sensitive resin composition for forming the insulation film are provided. The insulation film is formed on a substrate in which an active element is formed, and then a common electrode, an interlayer insulation film, and a comb-shaped pixel electrode are provided on the insulation film to produce the array substrate. To form the interlayer insulation film, the radiation-sensitive resin composition including [X] an alkali-soluble resin; [Y] oxide particles of at least one metal selected from the group consisting of aluminum, zirconium, titanium, zinc, indium, tin, antimony, and cerium; [Z] a polyfunctional acrylate; [V] a chain transfer agent; and [W] a radiation-sensitive polymerization initiator, is used. The liquid crystal display element includes the array substrate.

### TECHNICAL FIELD

The present invention relates to an array substrate, a liquid crystal display element, and a radiation-sensitive resin composition.

### BACKGROUND ART

Liquid crystal display elements have an arrangement in which a liquid crystal is sandwiched between a pair of substrates. The substrates can be provided with alignment films on surfaces thereof in order to control the alignment of the liquid crystal. Moreover, the pair of substrates is sandwiched by a pair of polarizing plates, for example. Upon application of an electric field to between the substrates, the liquid crystal is changed in its alignment, so that it will partly transmit or block light. A liquid crystal display element displays images using such a property. Advantageously, such a liquid crystal display element can be reduced in thickness or weight as compared with conventional CRT based display devices.

Early liquid crystal display elements were used as display elements of calculators and clocks typified by character displays, and the like. Then, development of a simple matrix system made dot matrix display easier, so that the applications have expanded to display elements of laptop computers, etc. Subsequently, development of an active matrix system in which an active element for switching is disposed to each pixel made it possible to realize good image quality excelling in contrast ratio and response performance. Moreover, liquid crystal display elements have met such challenges as improvement in fineness, colorization, and widening of viewing angle, so that they have come to be used for monitors of desktop computers, and the like. Due to recent realization of a wider viewing angle, faster response of liquid crystals, improvement in display quality, and the like, liquid crystal display elements have been used as display elements for large, thin televisions.

Liquid crystal display elements are known to include various liquid crystal modes differing in initial alignment state of a liquid crystal or in alignment change action. For example, such liquid crystal modes include TN (Twisted Nematic), STN (Super Twisted Nematic), IPS (In-Planes Switching) (FFS (Fringe Field Switching)), VA (Vertical Alignment) or OCB (Optically Compensated Birefringence).

Among the above-mentioned liquid crystal modes, the IPS mode is a mode that has gained much attention in recent years due to its possession of a wide viewing angle, a high response speed, and a high contrast ratio. The IPS mode as used herein is a liquid crystal mode in which liquid crystals undergo a switching (alignment change) operation in the plane of the substrates sandwiching them as described later, and it is a concept containing a so-called in-plane switching mode as well as an FFS (Fringe Field Switching) mode which realizes in-plane switching of liquid crystals using an oblique electric field (fringe field).

In a liquid crystal display element of an IPS mode including an FFS mode (this hereinafter may be referred to simply as “IPS mode”), the initial alignment state of liquid crystals is controlled so that liquid crystals sandwiched between a pair of substrates may be aligned approximately in parallel with the substrates. By applying voltage to between a pixel electrode and a common electrode disposed on one of those substrates, an electric field mainly composed of a component parallel to the substrate plane (so-called lateral electric field and oblique electric field (fringe field)) is formed and the alignment state of the liquid crystals is changed. For this reason, in the IPS mode, the alignment change of liquid crystals caused by applying an electric field mainly involves, a rotational motion of liquid crystal molecules in a plane parallel to the substrate plane as its name suggests.

Under such circumstances, the IPS mode including an FFS mode allows liquid crystals to exhibit small change in tilt angle with respect to the substrates sandwiching the liquid crystals in contrast to a TN mode in which liquid crystals aligned in parallel undergo standing-up motion due to application of an electric field. For this reason, an IPS mode liquid crystal display element is limited to exhibit small change in effective value of retardation following the application of voltage and enables high-quality image display at a wide viewing angle.

Regarding the above-described IPS mode liquid crystal display elements, an electrode structure in which an inorganic insulation film made of an inorganic material is laminated on a transparent solid electrode (for example, common electrode) and a comb-shaped electrode (for example, pixel electrode) is superimposed thereon is now under development (see, for example, Patent Literature 1 or Patent Literature 2). By this structure, the aperture ratio of a pixel is increased and image display at high brightness is realized.

### CITATION LIST

### Patent Literature

[PTL 1] Japanese Patent Application Laid-Open No. 2011-48394
[PTL 2] Japanese Patent Application Laid-Open No. 2011-59314

### SUMMARY OF INVENTION

### Technical Problem

Further improvement in image quality, especially, fineness, has recently been demanded with IPS mode liquid crystal display elements in order to adapt to televisions to display moving images, and displays of portable electronic devices, such as smart phones with which a high density display is needed.

In a liquid crystal display element of an IPS mode including an FFS mode, an active element for switching, such as a thin film transistor (TFT), is disposed on one of a pair of substrates sandwiching liquid crystals. In addition, a pixel electrode, a common electrode, and wires connected thereto, etc. are also disposed to constitute an array substrate. For this reason, an IPS mode liquid crystal display element has many constitutional members disposed on its array substrate, so that the electrode structure and the wire arrangement structure on the array substrate are more complicated as compared with other liquid crystal modes such as TN mode. Accordingly, an attempt at further improving fineness has a probability to induce decrease in brightness of display due to reduction in aperture ratio of a pixel caused by decrease in the area of a pixel electrode in a pixel.

Patent Literature 2 discloses an array substrate in which a pixel electrode having a part formed in a comb-like shape (hereinafter also referred to as “comb-shaped pixel electrode”) is disposed on a solid common electrode via an interlayer insulation film made of an inorganic material (hereinafter also referred to as “inorganic interlayer insulation film”). Patent Literature 2 discloses a technology of providing an insulation film made of an organic material (hereinafter referred to also as “organic insulation film”) between a solid common electrode and an underlying wire. This can be expected to improve the aperture ratio while suppressing increase in coupling capacitance between a pixel electrode and a wire.

At this time, in the conventional IPS mode liquid crystal display element disclosed in Patent Literature 2, an inorganic interlayer insulation film made of dense SiN (silicon nitride) is provided between a solid common electrode and a comb-shaped pixel electrode for securing the insulation property between them. This inorganic interlayer insulation film made of SiN (silicon nitride) is usually formed by CVD (Chemical Vapor Deposition).

Accordingly, the conventional IPS mode liquid crystal display element requires to provide a CVD process when forming an inorganic interlayer insulation film between a common electrode and a comb-shaped pixel electrode, and therefore production apparatuses are large in scale. In addition, an attempt to use a large substrate in order to increase productivity requires an increasingly large production apparatus. For this reason, regarding the conventional IPS mode liquid crystal display element, formation of an inorganic interlayer insulation film was a restriction in improving the productivity and a factor of high costs.

Therefore, in the IPS mode liquid crystal display element, a technology to easily form an interlayer insulation film disposed between a common electrode and a comb-shaped pixel electrode is desired. That is, there is desired an insulation film that does not require a large-scale manufacturing apparatus for CVD and the like and that can be formed easily on a large substrate. The insulation film preferably excels in patterning property, light transmission property, and insulation property, and the dielectric property and the refractive index property thereof are preferably the same as those of conventional interlayer insulation films. In particular, the insulation film preferably has the same dielectric property as a conventional TFT so that it may become easy to combine the insulation film with the conventional TFT to substitute for an inorganic interlayer insulation film made of SiN.

The present invention was devised in view of the problems described above. That is, an object of the present invention is to provide an array substrate with an insulation film which can easily be formed and the dielectric properties of which can be controlled. Especially, an object of the present invention is to provide an array substrate having an interlayer insulation film which can easily be formed and the dielectric properties of which can be controlled and being suitable for providing an FFS-mode liquid crystal display element.

In addition, another object of the present invention is to provide a liquid crystal display element using an array substrate with an insulation film which can easily be formed and the dielectric properties of which can be controlled. Especially, an object of the present invention is to provide an FFS-mode liquid crystal display element using an array substrate with an insulation film which can easily be formed and the dielectric properties of which can be controlled.

Moreover, another object of the present invention is to provide a radiation-sensitive resin composition to be used for the formation of an insulation film of an array substrate. Especially, an object of the present invention is to provide a radiation-sensitive resin composition to be used for the formation of an interlayer insulation film disposed between a pixel electrode and a common electrode of an array substrate.

### Solution to Problem

According to a first aspect of the present invention, an array substrate for an FFS-mode liquid crystal display element includes a common electrode, a pixel electrode, and an interlayer insulation film disposed between the common electrode and the pixel electrode. The interlayer insulation film is formed using a radiation-sensitive resin composition. The radiation-sensitive resin contains [X] an alkali-soluble resin, [Y] oxide particles of at least one metal selected from the group consisting of aluminum, zirconium, titanium, zinc, indium, tin, antimony, and cerium, and [V] a chain transfer agent.

In the array substrate according to the first aspect of the present invention, the [X] alkali-soluble resin is preferably a polymer comprising a (X1) constitutional unit having an aromatic ring and a (X2) constitutional unit having a (meth)acryloyloxy group.

In the array substrate according to the first aspect of the present invention, the content of the (X1) constitutional unit having the aromatic ring in the [X] alkali-soluble resin is preferably 20 mol % to 90 mol % of the whole of the [X] polymer.

In the array substrate according to the first aspect of the present invention, the [Y] oxide particles are preferably particles of a titanic acid salt.

In the array substrate according to the first aspect of the present invention, the [V] chain transfer agent preferably includes a compound having a mercapto group.

In the array substrate according to the first aspect of the present invention, it is preferably that one of the common electrode and the pixel electrode has a comb-like shape and the other has a solid-like shape, and the one of the common electrode and the pixel electrode having the comb-like shape is disposed on the interlayer insulation film.

In the array substrate according to the first aspect of the present invention, the interlayer insulation film preferably has a permittivity of 4 to 8.

In the array substrate according to the first aspect of the present invention, the interlayer insulation film preferably has a refractive index of 1.55 to 1.85 at a wavelength of 633 nm.

In the array substrate according to the first aspect of the present invention, the interlayer insulation film preferably has a light transmittance equal to 85% or more than 85% at a wavelength of 400 nm.

According to a second aspect of the present invention, a liquid crystal display element includes the array substrate according to the first aspect of the present invention.

According to a third aspect of the present invention, a radiation-sensitive resin composition includes [X] an alkali-soluble resin, [Y] oxide particles of at least one metal selected from the group consisting of aluminum, zirconium, titanium, zinc, indium, tin, antimony, and cerium, and [V] a chain transfer agent. The radiation-sensitive resin composition is used for the formation of the interlayer insulation film of the array substrate according to the first aspect of the present invention.

### Advantageous Effects of Invention

According to the first embodiment of the present invention, an array substrate, with an insulation film which can easily be formed and the dielectric properties of which can be controlled, can be obtained. Especially, according to the first embodiment of the present invention, an array substrate, having an interlayer insulation film which can easily be formed and the dielectric properties of which can be controlled and being suitable for providing an FFS-mode liquid crystal display element, can be obtained.

According to the second embodiment of the present invention, a liquid crystal display element using an array substrate with an insulation film, which can easily be formed and the dielectric properties of which can be controlled, can be obtained. Especially, according to the second embodiment of the present invention an FFS-mode liquid crystal display element using an array substrate with an insulation film, which can easily be formed and the dielectric properties of which can be controlled, can be obtained.

According to the third embodiment of the present invention, a radiation-sensitive resin composition which can easily be formed and the dielectric properties of which can be controlled, and which can preferably be used for the forming an insulation film of an array substrate, can be obtained. Especially, according to the third embodiment of the present invention, a radiation-sensitive resin composition which can easily be formed and the dielectric properties of which can be controlled, and which can be preferably used for forming an insulation film of an array substrate of a FFS-mode liquid crystal display element, can be obtained.

### BRIEF DESCRIPTION OF DRAWINGS

FIG. 1 A plan view schematically illustrating a main structure of a pixel part of the array substrate according to the embodiment of the present invention.

FIG. 2

A view schematically illustrating a cross-section of a structure along A-A′ line of FIG. 1.

FIG. 3

A schematic cross-sectional view of a liquid crystal display element according to the embodiment of the present invention.

### DESCRIPTION OF EMBODIMENTS

As described above, in the conventional IPS mode liquid crystal display elements described in Patent Literature 2 or the like, an inorganic interlayer insulation film made of SiN is disposed between a solid common electrode and a comb-shaped pixel electrode. Since this inorganic interlayer insulation film made of SiN is formed by a film formation method such as CVD, a large-scale manufacturing apparatus is required. In order to substitute for the inorganic interlayer insulation film made of SiN and provide an interlayer insulation film that can be formed easily, the application of an applied type organic insulation film is preferred. If a conventional inorganic interlayer insulation film can be replaced using an applied type organic insulation film, it becomes possible to easily form an interlayer insulation film in an IPS mode liquid crystal display element including the FFS mode. Moreover, it becomes easy to apply a large-sized substrate and the productivity of an array substrate and a liquid crystal display element can be improved.

Therefore, substitution of an applied type organic insulation film for the inorganic interlayer insulation film is desired. In order to realize this, the organic insulation film is desired to excel in patterning property, light transmission property, and insulation property. Therefore, the organic insulation film is preferably one formed using a liquid resin composition capable of patterning.

The organic insulation film that can be substituted for an inorganic interlayer insulation film is preferably the same as a conventional interlayer insulation film in terms of dielectric property and refractive index property. In particular, the organic insulation film preferably can be combined with a TFT, which is a conventionally used active element for switching, to use in the same manner as an inorganic interlayer insulation film made of SiN. Therefore, the organic insulation film preferably can be controlled so that it may have an electrostatic capacitance C the same as that of an inorganic interlayer insulation film made of SiN.

At this time, the electrostatic capacitance C of a member such as an interlayer insulation film, which is taken into consideration when the member is combined with a TFT, can be expressed by C=∈×(S/d). Herein, e is the permittivity of the member constituting an interlayer insulation film or the like. S is the area of the member and, in the case of an interlayer insulation film, it is the area of an electrode. d is the thickness of the member and, in the case of an interlayer insulation film, it is the thickness of the film. ∈ is represented by ∈=∈₀×k. At this time, ∈₀ is a permittivity in a vacuum and is a constant. k is the dielectric constant of the member and is a value intrinsic to the member.

SiN has a dielectric constant k of 7.5, which is a larger value as compared with the dielectric constants of 2 to 4 which are possessed by resins such as ethylene resin and acrylic resin. Therefore, when forming an organic insulation film using a resin composition, it is necessary to perform control to increase the dielectric constants of constituents so that the electrostatic capacitance may become equivalent to that of an inorganic interlayer insulation film made of SiN. In addition, it is necessary in some cases to control the organic insulation film to be small in thickness while maintaining the insulation property thereof.

Then, the present inventors have developed an organic insulation film that can be controlled in its permittivity to have a desired value by application of a technology of increasing the dielectric constant of a constituent, for example, that can be controlled to have the same permittivity as an interlayer insulation film made of SiN.

The organic insulation film of the present invention can have a higher refractive index as compared with organic films using conventional organic materials and can have the same refractive index as that of conventional inorganic interlayer insulation films made of SiN. Since the interlayer insulation film to be used for the formation of the array substrate of the present invention has such refractive index properties, the liquid crystal display element of the present invention using it can alleviate a “skeletal structure” problem in which electrodes appear remarkable.

In addition, the organic insulation film of the present invention is cured sufficiently and can exhibit insulation property even if it is a thin film as thin as 1 μm or less, for example. Moreover, this organic insulation film can be formed simply by application using a radiation-sensitive resin composition and it can be subjected to desired patterning.

Accordingly, the organic insulation film of the present invention can substitute for conventional inorganic interlayer insulation films made of SiN and enables provision of an array substrate comprising an active element, a common electrode, a pixel electrode, and an organic insulation film of the present invention disposed between the common electrode and the pixel electrode. It further enables provision of a liquid crystal display element of the present invention using the array substrate.

The array substrate and the liquid crystal display element according to the present invention having the organic insulation film applied thereto as mentioned above, the radiation-sensitive resin composition according to the present invention used in the formation of the organic insulation film as mentioned above, and the method for producing the array substrate in which the radiation-sensitive resin composition is used, etc., will be described below.

Firstly, the array substrate, and the liquid crystal display element configured using the array substrate, according to the present embodiment, will be described.

In the present invention, the “radiation” which is applied during exposure includes visible rays, ultraviolet rays, far ultraviolet rays, X-rays, charged particle beams, and the like.

### <Liquid Crystal Display Element>

The liquid crystal display element according to the present embodiment is a color liquid crystal display element of an IPS mode configured using the array substrate according to the present embodiment. Specifically, the liquid crystal display element according to the present embodiment is a color liquid crystal display element of FFS mode configured using the array substrate of the present embodiment.

This liquid crystal display element can be used as a color liquid crystal display element in an active matrix type IPS mode, and especially, it can be used as a color liquid crystal display element in an active matrix type FFS mode.

Preferably, in the present invention, an array substrate comprising an active element, a pair of a common electrode and a pixel electrode, and interlayer insulation films disposed between the active element and the common electrode and the pixel electrode is configured to be an array substrate suitable for the production of an FFS-mode liquid crystal display element.

A liquid crystal display element may be configured to have an arrangement where an array substrate in which an active element to be used for switching, an electrode, an insulation film, and the like are formed and a color filter substrate configured to have a color pattern are opposed via a liquid crystal layer. It has a display region in which a plurality of pixels are arrayed in a dot matrix.

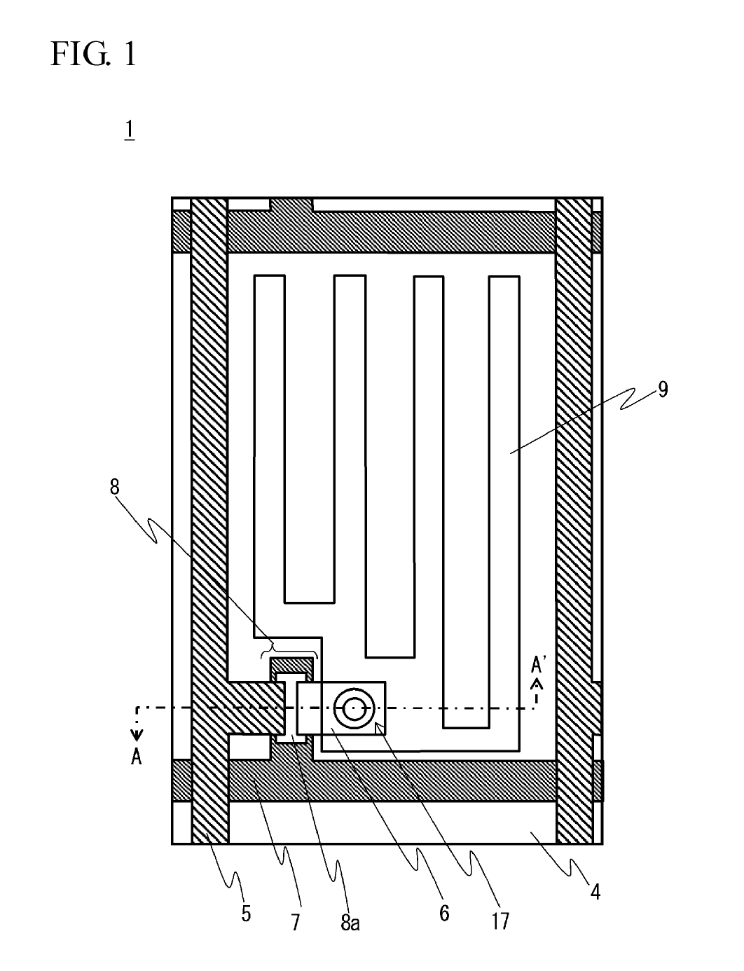

FIG. 1 is a plan view schematically illustrating a main structure of a pixel part of the array substrate according to the embodiment of the present invention.

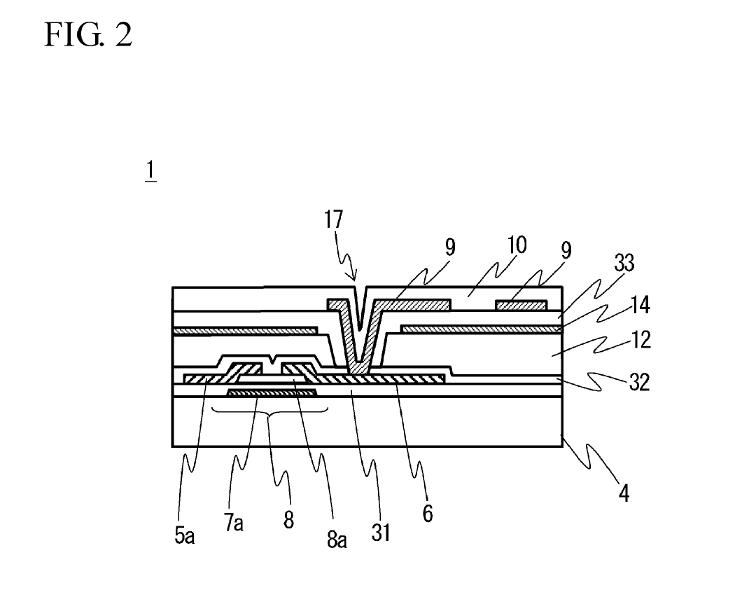

FIG. 2 is a view schematically illustrating a cross-section of a structure along A-A′ line of FIG. 1.

In addition, a planar common electrode 14 and a gate insulation film 31 that will be described below are omitted in FIG. 1.

In FIG. 1 and FIG. 2, the array substrate 1 has an arrangement in which the active element 8 is disposed on one side of the transparent substrate 4. The active element 8 comprises: a gate electrode 7a that constitutes a part of a scan signal line 7 disposed on the substrate 4, a semiconductor layer 8a disposed via a gate insulation film 31 on the gate electrode 7a, a first source-drain electrode 6 that is connected to the semiconductor layer 8a, a second source-drain electrode 5a that constitutes a part of an image signal line 5 to be connected to the semiconductor layer 8a, and it constitutes a thin film transistor (TFT: Thin Film Transistor) as a whole.

The semiconductor layer 8a can be formed, for example, by using a silicon (Si) material such as amorphous a-Si (amorphous silicon) or p-Si (polysilicon) obtained by crystallizing a-Si by excimer laser or solid phase growth.

In the case of using a-Si for the semiconductor layer 8a, the thickness of the semiconductor layer 8a is preferably adjusted to 30 nm to 500 nm. Preferably, an n+Si layer, not shown, for taking an ohmic contact is formed in a thickness of 10 nm to 150 nm at between the semiconductor layer 8a and the first source-drain electrode 6 or the second source-drain electrode 5a.

The semiconductor layer 8a can be formed using an oxide. Examples of the oxide applicable to the semiconductor layer 8a include a single crystal oxide, a polycrystal oxide, an amorphous oxide, and a mixture thereof. Examples of the polycrystal oxide include zinc oxide (ZnO).

Examples of the amorphous oxide applicable to the semiconductor layer 8a include an amorphous oxide comprising at least one element of indium (In), zinc (Zn), and tin (S

Specific examples of the amorphous oxide applicable to the semiconductor layer 8a include Sn-Tn-Zn oxide, In—Ga—Zn oxide (IGZO: indium gallium zinc oxide), In—Zn—Ga—Mg oxide, Zn—Sn oxide (ZTO: zinc tin oxide), In oxide, Ga oxide, In—Sn oxide, In—Ga oxide, In—Zn oxide (IZO: indium zinc oxide), Zn—Ga oxide, and Sn—In—Zn oxide. In the cases shown above, the compositional ratio of the constituent material is not necessarily limited to 1:1 and a compositional ratio that realizes a desired property can be chosen.

When the semiconductor layer 8a using an amorphous oxide is formed using IGZO or ZTO, for example, it is formed by performing layer formation by the sputtering method or the vapor deposition method using a IGZO target or a ZTO target, and then performing patterning by a resist process and an etching process by using a photo-lithographic method. Preferably, the thickness of the semiconductor layer 8a using the amorphous oxide is adjusted to 1 nm to 1000 nm.

A semiconductor layer 8a high in mobility can be formed at a low temperature and an active element 8 with excellent performance can be provided by using the oxides provided above as examples.

Examples of an oxide particularly favorable in order to form the semiconductor layer 8a, which is the active element 8, include zinc oxide (ZnO), indium gallium zinc oxide (IGZO), zinc tin oxide (ZTO), and indium zinc oxide (ZIO).

Use of such an oxide allows the active element 8 to have the semiconductor layer 8a excellent in mobility formed at lower temperature and enables it to exhibit a high ON/OFF ratio.

The gate insulation film 31 disposed to cover the gate electrode 7a can be formed, for example, from a metal oxide such as SiO₂ (silicon dioxide) or a metal nitride such as SiN (silicon nitride).

On the active element 8, an inorganic insulation film 32 being a third insulation film differing from the first insulation film and the second insulation film described below is provided so that it may cover the active element 8. The inorganic insulation film 32 can be formed, for example, from a metal nitride such as SiN or a metal oxide such as SiO₂. The inorganic insulation film 32 is provided in order to prevent the semiconductor layer 8a from being influenced by humidity. In the array substrate 1 of this embodiment, it is also allowed to form an arrangement in which an insulation film 12 being the first insulation film described below is disposed on the active element 8 without disposing an inorganic insulation film 32 that is the third insulation film.

On the active element 8, an insulation film 12 being the first insulation film is disposed so that it may cover the inorganic insulation film 32. The insulation film 12 is an insulation film formed using the first radiation-sensitive resin composition described below and it is an organic insulation film formed using an organic material. Preferably, the insulation film 12 possesses a function as a planarization film, and it is formed thick from this point of view. For example, in the case of an active element 8 having a common structure, the insulation film 12 can be formed in a thickness of 1 to 6 μm.

The insulation film 12, which is the first insulation film of the array substrate 1 of this embodiment, is formed by applying the first radiation-sensitive resin composition of this embodiment onto the substrate 4 on which an image signal line 5 and the like and the active element 8 are formed, performing necessary patterning such as formation of a contact hole 17, and then heat-setting.

The first radiation-sensitive resin composition to be used for the formation of the insulation film 12 may be either a positive type or a negative type. For example, in an insulation film 12 using a positive type first radiation-sensitive resin composition, when it has sensed to radiation, its solubility in a developing solution increases and a portion having sensed is removed. Therefore, when using the positive type first radiation-sensitive resin composition, a desired contact hole 17 can be formed relatively easily by irradiating a contact hole 17 forming portion of the insulation film 12 with sensitizing radiation.

In an insulation film 12 using a negative type first radiation-sensitive resin composition, when it has sensed to radiation, its solubility in a developing solution decreases and a portion not having sensed is removed. Therefore, when using the negative type first radiation-sensitive resin composition, a desired contact hole 17 can be formed by irradiating a portion other than a contact hole 17 forming portion of the insulation film 12 with sensitizing radiation. The negative type is disadvantageous in that the shape control of a contact hole 17 becomes difficult as compared with the positive type, but it is advantageous in the transparency, the heat resistance, and the like of a resulting insulation film 12.

The first radiation-sensitive resin composition, both the positive type and the negative type, contains an alkali-soluble resin, such as a polymer having a constitutional unit having a carboxyl group and a constitutional unit having a polymerizable group. In this case, a coating film formed from the first radiation-sensitive resin composition is irradiated with radiation to form a pattern, and then it is cured by further heating, so that resins having polymerizable groups are cross-linked together as a result of reacting the polymerizable groups by heating. Thus, a cured film in which a cross-linked network is formed to a high degree can be formed. Since such a cured film exhibits small shrinkage of the film even if it is further heated, it can minimize the stress added to a film formed thereon. Therefore, even if an insulation film 12 is formed and then the insulation film 12 is further subjected to heating treatment during a curing step for another film formed thereon, the variation of the size of the insulation film 12 induced by this is minimized. Thereby, stress added to the common electrode 14 and the interlayer insulation film 33 on the insulation film 12 can be reduced.

Due to only small stretch of a film caused by heating of the insulation film 12, even if an adhesion force between a common electrode 14 made of ITO or the like and an interlayer insulation film 33 disposed thereon is weak, the occurrence of delamination between the common electrode 14 and the interlayer insulation film 33 can be prevented.

The first radiation-sensitive resin composition can be optimized in its composition and it can be cured by heating at a low temperature of 200° C. or less. That is, low-temperature heating treatment during the process of the production of the array substrate 1 is possible and an insulation film 12 favorable from the perspective of energy saving is afforded.

In order to connect the pixel electrode 9 and the first source-drain electrode 6, described below, the insulation film 12 has been provided with a contact hole 17 penetrating the insulation film 12. The contact hole 17 is formed so that it may penetrate also the inorganic insulation film 32 underlying the insulation film 12. The insulation film 12 is formed using the first radiation-sensitive resin composition, which is a radiation-sensitive resin composition. Therefore, the contact hole 17 can be formed, for example, by forming a through hole by irradiating the insulation film 12 with radiation, and then applying dry etching to the inorganic insulation film 32 using the insulation film 12 as a mask. In the case of a structure where the array substrate 1 does not have the inorganic insulation film 32, a through hole formed by irradiating the insulation film 12 with radiation is a contact hole 17.

The upper surface of the insulation film 12 is flat, and a common electrode 14 (not shown in FIG. 1) has been disposed thereon. The common electrode 14 is formed planar and is formed in solid on a whole surface to avoid the contact hole 17.

The common electrode 14 is formed, for example, by forming a film made of a transparent conductive material such as ITO using the sputtering method or the like. Then, patterning is performed using the photolithographic method, or the like and thereby an opening is provided so that it may surround the contact hole 17. Thereby, a common electrode 14 having the structure of FIG. 2 can be formed.

On the insulation film 12 and the common electrode 14, an interlayer insulation film 33, which is an applied type organic insulation film, as the second insulation film, has been provided so as to cover the insulation film 12 and the common electrode 14. The interlayer insulation film 33 is an organic insulation film being a feature of the present invention and provided instead of a conventional interlayer insulation film made of SiN and it is a major constitutional element of the array substrate 1 of this embodiment.

The interlayer insulation film 33 has an opening at the same position as the contact hole 17 of the insulation film 12. For this reason, the contact hole 17 of the insulation film 12 is not closed by the interlayer insulation film 33 and that enables electric connection between the pixel electrode 9, described below, disposed on the interlayer insulation film 33 and the first source-drain electrode 6 to be connected to the semiconductor layer 8a. At this time, the contact hole 17 is required only to maintain a state that an opening opens at the top and the bottom thereof to penetrate the insulation film 12, and at least a part of the inner wall of the contact hole 17 may be coated with the interlayer insulation film 33.

The interlayer insulation film 33 being the second insulation film is a substitution for a conventional interlayer insulation film made of SiN as described above and is an applied type organic insulation film that is constituted using an organic material. The interlayer insulation film 33 is formed by performing coating film formation by application using the second radiation-sensitive resin composition of an embodiment of the present invention, and then performing prescribed patterning using the photolithographic method, or the like.

The photolithographic method comprises a step of forming a resist film by applying a resist composition to a surface of a substrate to be subjected to processing or treatment, an exposure step of forming a resist pattern latent image by exposing a prescribed resist pattern to light by applying light or an electron beam, a step of performing heat treatment if necessary, a development step of subsequently developing this, thereby forming a desired fine pattern, and a step of performing processing such as etching to a substrate using the fine pattern as a mask.

The second radiation-sensitive resin composition of an embodiment of the present invention has been optimized in its composition so that a desired permittivity and a desired refractive index can be realized in the interlayer insulation film 33 of the array substrate 1 of this embodiment. That is, the second radiation-sensitive resin composition of this embodiment is constituted by containing an oxide particle of at least one metal selected from the group consisting of aluminum, zirconium, titanium, zinc, indium, tin, antimony, and cerium as an ingredient for increasing the permittivity so that control to increase the permittivity can be performed in the interlayer insulation film 33.

Since the second radiation-sensitive resin composition of this embodiment contains the above-mentioned metal oxide particle, it is possible to increase the refractive index of an interlayer insulation film 33 to be formed using the composition. For example, the refractive index of the interlayer insulation film 33 can be controlled within the range of 1.55 to 1.85.

Moreover, the second radiation-sensitive resin composition excels in patterning property and has an optimum design with respect to other ingredients, such as containing a chain transfer agent, so that it can exhibit high curing performance and can exhibit an excellent insulation property. The second radiation-sensitive resin composition of this embodiment is described in detail below.

Accordingly, the array substrate 1 is configured in such a matter that the permittivity or the like of the interlayer insulation film 33 is adjusted and substitution for a conventional inorganic interlayer insulation film made of SiN can be performed easily.

Although the thickness of the interlayer insulation film 33 is not particularly limited, it is preferably a thickness suitable for securing the insulation property between the common electrode 14 and the pixel electrode 9 and realizing a desired electrostatic capacitance. The interlayer insulation film 33 can be adjusted in its thickness to 1 μm or less, preferably 0.1 μm to 8 μm, more preferably 0.1 μm to 6 μm, even more preferably 0.1 μm to 4 μm.

Like the insulation film 12, the common electrode 14, and the pixel electrode 9, the interlayer insulation film 33 is required to have excellent visible light transmission as a constitutional element to constitute the array substrate 1. The interlayer insulation film 33 formed from the second radiation-sensitive resin composition of this embodiment is provided with excellent transparency as being evidenced by the working examples disclosed below. Moreover, the interlayer insulation film 33 preferably has a light transmittance of 85% or more, more preferably 90% or more, at a wavelength of 400 nm.

The interlayer insulation film 33 described above is patterned so that it may not close the contact hole 17 of the insulation film 12 and is disposed in such a manner that it covers the common electrode 14.

A pixel electrode 9 is disposed on the interlayer insulation film 33. The pixel electrode 9 is a transparent electrode and it has a part formed in a comb-like shape (hereinafter referred to simply as “comb-like shape” or “comb-shaped”). The pixel electrode 9 in a comb-like shape (hereinafter sometimes referred to simply as “comb shape”.) is connected via the contact hole 17 to the first source-drain electrode 6 connected to the semiconductor layer 8a. By forming such an arrangement, the aperture ratio of a pixel can be increased and a pixel structure capable of providing a brighter display can be realized.

The array substrate 1 of this embodiment is used for the constitution of the liquid crystal display element of this embodiment and an electric field having a component parallel to the plane of the substrate 4 is formed between the comb-shaped pixel electrode 9 and the above-described solid common electrode 14, so that it makes a liquid crystal molecule of a liquid crystal layer undergo rotational movement (change in alignment) in a plane parallel to the plane of the substrate 4.

The pixel electrode 9 can be formed as follows. For example, the film comprising a transparent conductive material such as ITO (Indium Tin Oxide) is formed using a sputtering method, etc. Next, the film is patterned using a photolithographic method, etc. to form the comb-tooth shaped electrode.

On the pixel electrode 9, there can be formed an alignment film 10 to cover the pixel electrode 9. The alignment film 10 controls the alignment of the liquid crystal layer. More specifically, the alignment film 10 controls the alignment of liquid crystal molecules constituting a liquid crystal layer and consequently controls the alignment of the liquid crystal layer in the liquid crystal display element of this embodiment formed using the array substrate 1.

The alignment film 10 can be obtained using (1) a liquid crystal aligning agent comprising a radiation-sensitive polymer having a photo-alignable group, or (2) a liquid crystal aligning agent comprising a polyimide having no photo-alignable groups as described below. (1) The liquid crystal aligning agent is a resin composition that differs from the first radiation-sensitive resin composition to be used for the formation of the insulation film 12 and the second radiation-sensitive resin composition to be used for the formation of the interlayer insulation film 33, and it is cured by low-temperature heat treatment at 200° C. or less. The polyimide contained in (2) the liquid crystal aligning agent is a polyimide soluble in a solvent, and (2) the liquid crystal aligning agent is cured by heat treatment at 200° C. or less like (1). Therefore, the influence given to the insulation film 12 and the interlayer insulation film 33 by the heating during the process of the formation of the alignment film 10 can be minimized by forming the alignment film 10 using these liquid crystal aligning agents. For example, the elongation and the shrinkage of the insulation film 12 that may be caused by heating during the process of forming the alignment film 10 can be minimized. As a result of the fact that heat treatment at 200° C. or less becomes possible, a method for producing an array substrate favorable from the perspective of energy saving can be provided.

In the array substrate 1 having the above structure, an image signal line 5 and a scan signal line 7 are disposed in a matrix. Active elements 8 are disposed near intersections of image signal lines 5 and scan signal lines 7 and they constitute individual pixels divided on the array substrate 1.

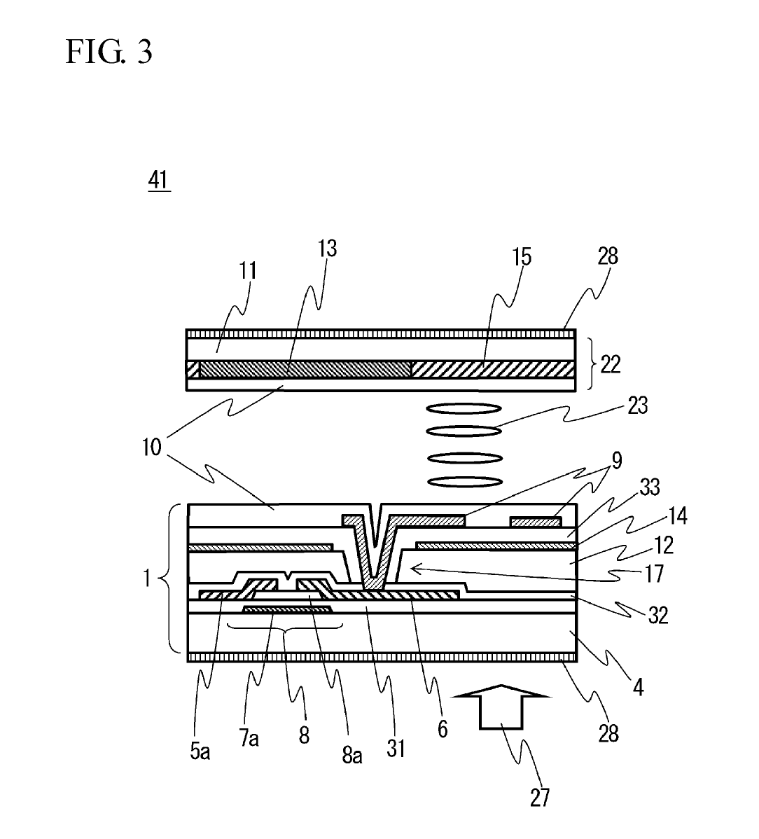

FIG. 3 is a schematic cross-sectional view of a liquid crystal display element according to the embodiment of the present invention.

As shown in FIG. 3, the liquid crystal display element 41 is an active matrix type IPS mode color liquid crystal display element composed of the array substrate 1 and the color filter substrate 22 shown in FIG. 1 and FIG. 2. In more detail, the liquid crystal display element 41 is an active matrix type FFS-mode color liquid crystal display element composed of the array substrate 1 and the color filter substrate 22 shown in FIG. 1 and FIG. 2. The liquid crystal display element 41 has an arrangement in which the array substrate 1 and the color filter substrate 22 are opposed via liquid crystal layers 23 aligned in parallel to the substrate 4 and the substrate 11.

The array substrate 1 has an active element 8 to be used for switching, on a surface of the transparent substrate 4 on a side where the liquid crystal layers 23 are located as shown in FIG. 3. As described above, the active element 8 has a gate electrode 7a, a gate insulation film 31, a semiconductor layer 8a, a first source-drain electrode 6, and a second source-drain electrode 5a, and they constitute a TFT element as a whole. On the array substrate 1, image signal lines 5 (not shown in FIG. 3) that are connected to the second source-drain electrode 5a and scan signal lines 7 (not shown in FIG. 3) that are connected to the gate electrode 7a are disposed in a matrix. Active elements 8 are disposed near intersections of the image signal lines 5 and the scan signal lines 7, and they constitute individual pixels divided thereby on the array substrate 1.

The inorganic insulation film 32 as the third insulation film can be provided on the active element 8, and the insulation film 12 as a first insulation film is provided so that the insulation film 12 covers the inorganic insulation film 32 on the active element 8. The insulation film 12 is formed using the first radiation-sensitive resin composition described below and it is formed thickly so that it has a function as a planarization film.

On the insulation film 12 is disposed a solid common electrode 14 to avoid the contact hole 17. On the common electrode 14 and the insulation film 12, an interlayer insulation film 33 being the second insulation film, is disposed. The interlayer insulation film 33 is an organic insulation film of the present invention provided instead of a conventional interlayer insulation film made of SiN as described above and it is a major constitutional element of the liquid crystal display element 41 of this embodiment.

On the interlayer insulation film 33 is disposed a pixel electrode 9 that is a transparent electrode and that has a part formed in a comb-like shape. The insulation film 12 has been provided with the contact hole 17 that penetrates the insulation film 12 and also penetrates an inorganic insulation film 32 underlying said insulation film. The pixel electrode 9 is connected to the first source-drain electrode 6 connected to the semiconductor layer 8a via the contact hole 17. On the pixel electrode 9 is disposed the alignment film 10 that controls the alignment of the liquid crystal layers 23.

The color filter substrate 22 is disposed on a surface of the transparent substrate 11 on a side where the liquid crystal layers 23 are located. The color filter substrate 22 is constituted with a coloring pattern 15 and a black matrix 13 being disposed. In the coloring pattern 15, red, green, and blue fine patterns are arranged in a regular shape, such as a lattice-like shape. The color of the coloring pattern 15 is not limited to the above-mentioned three colors of red, green, and blue, and other colors may be chosen or a yellow color may be added to form a four-color coloring pattern. A color filter substrate can be constituted by arranging patterns of the individual colors.

In the color filter substrate 22, an alignment film 10 the same as that of the array substrate 1 is disposed on a surface being in contact with the liquid crystal layers 23. A planarization film may be formed between the alignment film 10 and the color filter substrate 22 for the purpose of planarizing the irregularities on a surface of the color filter substrate 22.

As described above, in the liquid crystal display element 41 of this embodiment, alignment films 10 are disposed on surfaces of the array substrate 1 and the color filter substrate 22 to come into contact with liquid crystal layers 23. The alignment films 10 are subjected to alignment treatment, such as rubbing, in the case of necessity, and it realizes uniform parallel alignment of the liquid crystal layers 23 sandwiched between the array substrate 1 and the color filter substrate 22.

The distance between the array substrate 1 and the color filter substrate 22 opposing via the liquid crystal layers 23 is held with a spacer (not shown) at a prescribed value and is usually 2 μm to 10 μm. The array substrate 1 and the color filter substrate 22 are fixed to each other by a sealant (not shown) provided at their peripheries.

In each of the array substrate 1 and the color filter substrate 22, a polarizer 28 is disposed on the side opposite the side where each of them comes into contact with the liquid crystal layers 23.

In FIG. 3, the numeral 27 indicates backlight light directed toward the liquid crystal layers 23 from a backlight unit (not shown) that serves as a light source of the liquid crystal display element 41.

As the backlight unit, one having a structure in which a fluorescence pipe, such as a cold cathode fluorescence pipe (CCFL: Cold Cathode Fluorescent Lamp) and a scattering plate are combined together can be used, for example. A backlight unit using a white LED as a light source can also be used. Examples of the white LED include a white LED that obtains white light by color mixing by combining a red LED, a green LED, and a blue LED, a white LED that obtains white light by color mixing by combining a blue LED, a red LED, and a green phosphor, a white LED that obtains white light by color mixing by combining a blue LED, a red-emitting phosphor, and a green-emitting phosphor, a white LED that obtains white light by color mixing by combining a blue LED and a YAG phosphor, a white LED that obtains white light by color mixing by combining a blue LED, an orange-emitting phosphor, and a green-emitting phosphor, and a white LED that obtains white light by color mixing by combining an ultraviolet LED, a red-emitting phosphor, a green-emitting phosphor, and a blue-emitting phosphor.

As described above, the liquid crystal display element 41 of this embodiment has a configuration in which liquid crystal layers 23 is sandwiched by the array substrate 1 and the color filter substrate 22 of this embodiment. In the array substrate 1, electric connection of the pixel electrode 9 and the first source-drain electrode 6 is realized via the contact hole 17 provided to penetrate the insulation film 12 and the inorganic insulation film 32. A signal voltage by the image signal line 5 is applied to the pixel electrode 9, and the liquid crystal molecules of the liquid crystal layers 23 are made to undergo rotational movement (change in alignment) in a plane parallel to the planes of the substrates 4, 11 by a transverse electric field generated between the pixel electrode 9 and the common electrode 14, that is, a component of the electric field generated between the pixel electrode 9 and the common electrode 14, parallel to the substrates 4, 11. Using this, the liquid crystal display element 41 controls the light transmission property of the liquid crystal layers 23 for each pixel and form an image.

The liquid crystal display element 41 is an IPS mode element in which the liquid crystal molecules of the liquid crystal layers 23 perform rotational movement in the planes of the substrates 4, 11, and the movement of the liquid crystal molecules differs from that of the conventional TN mode and the like. That is, the liquid crystal display element 41 is small in change of the tilt angle of the liquid crystal molecules relative to the substrates 4, 11 sandwiching the liquid crystal layers. Therefore, the liquid crystal display element 41 realizes a wide viewing angle property and makes it possible to perform high quality image display.

The liquid crystal display element 41 of this embodiment has an arrangement in which the interlayer insulation film 33 is disposed on the common electrode 14 and the comb-shaped pixel electrode 9 is further disposed on the interlayer insulation film 33. With this arrangement, the aperture ratio of pixels increases and image display in a high brightness is realized.

In the liquid crystal display element 41, the interlayer insulation film 33 is an applied type interlayer insulation film made of an organic material, formed using the second radiation-sensitive resin composition of this embodiment described in detail below. That is, the interlayer insulation film 33 can be formed via the formation of a coating film by the application method or via patterning using the photolithographic method, and that makes it possible to perform high throughput film formation and it can realize high productivity. The liquid crystal display device 41 has a component design that enables control to increase the permittivity in the interlayer insulation film 33 using the organic material, and it enables excellent image display as before without using a conventional inorganic interlayer insulation film made of SiN.

Moreover, in the liquid crystal display element 41, the insulation film 12 has been formed using the first radiation-sensitive resin composition described in detail below. For this reason, the insulation film 12 has a feature that the stretchability of the film is small due to its small heat shrinkability even if after its formation by heat setting following irradiation with radiation, heating is further performed. Therefore, since change in size of the insulation film 12 caused by heating is small even if the formation of the insulation film 12 is followed by, for example, a heating step for forming another constitutional member, problems such as delamination between members can be suppressed by minimizing the stress added to the common electrode 14 or the interlayer insulation film 33 located on the insulation film 12.

As described above, the liquid crystal display element of this embodiment has high productivity, excellent image quality, and high reliability. In the realization of such performance, the array substrate of this embodiment is an important constituent, and especially, the property of the interlayer insulation film being the second insulation film of the array substrate is important. The interlayer insulation film formed using the second radiation-sensitive resin composition is constituted using an organic material and can control a permittivity so that it may have a desirable dielectric property, and it can easily substitute for a conventional inorganic interlayer insulation film made of SiN. In the array substrate of this embodiment, an insulation film formed using the first radiation-sensitive resin composition is disposed between an electrode and a wire. This interlayer insulation film and the insulation film greatly contribute to the realization of the excellent image quality and high reliability of the liquid crystal display element of this embodiment.

The second radiation-sensitive resin composition and the first radiation-sensitive resin composition for forming an interlayer insulation film and insulation film respectively will be described in detail below. Firstly, the first radiation-sensitive resin composition according to the present embodiment for forming the insulation film as the first insulation film will be described. Thereafter, the second radiation-sensitive resin composition according to the present embodiment for forming the interlayer insulation film as the second insulation film will be described.

### <First Radiation-Sensitive Resin Composition>

In the array substrate of this embodiment, the first radiation-sensitive resin composition, either positive or negative, to be used for the production of the insulation film, which is one of the constituents of the array substrate, contains [A] an alkali-soluble resin as an essential ingredient; in the case of a positive radiation-sensitive resin composition, it further contains [B] a quinone diazide compound as an essential ingredient, or in the case of a negative radiation-sensitive resin composition, it contains [C] a polymerizable compound and [D] a radiation-sensitive polymerization initiator.

The first radiation-sensitive resin composition, either positive or negative, can contain [E] a thermal acid generator, and can further contain [F] a cure accelerator, described below. Unless the effect of the present invention is impaired, other optional ingredients may be contained.

Each ingredient that is included in the first radiation-sensitive resin composition according to the present embodiment will be described below.

### <[A] Alkali-Soluble Resin>

[A] The alkali-soluble resin is not limited provided that it is a resin with alkali developability. Preferably, [A] the alkali-soluble resin is a resin comprising constitutional units having a carboxyl group and constitutional units having a polymerizable group, or a polyimide resin obtained by dehydration-cyclizing a polyamic acid to imidize.

In the following, an acrylic resin comprising constitutional units having a carboxyl group and constitutional units having a polymerizable group, which is one example of [A] the alkali-soluble resin, is explained first.

It is preferable with the acrylic resin comprising constitutional units having a carboxyl group and constitutional units having a polymerizable group that the constitutional unit having a polymerizable group is at least one constitutional unit selected from the group consisting of a constitutional unit having an epoxy group and a constitutional unit having a (meth)acryloyloxy group. Inclusion of the above-described specific constitutional unit in the [A] alkali-soluble resin makes it possible to form a cured film excellent in surface curability and deep curability, namely, the insulation film of this embodiment.

The above-mentioned constitutional unit having a (meth)acryloyloxy group can be formed by, for example, a method of reacting (meth)acrylic acid to an epoxy group in a copolymer, a method of reacting a (meth)acrylic acid ester having an epoxy group to a carboxyl group in a copolymer, a method of reacting a (meth)acrylic acid ester having an isocyanate group to a hydroxy group in a copolymer, a method of reacting (meth)acrylic acid to an acid anhydride moiety in a copolymer, or the like. Of these, especially, the method of reacting a (meth)acrylic acid ester having an epoxy group to a carboxyl group in a copolymer is preferred.

[A] The alkali-soluble resin comprising constitutional units having a carboxyl group and constitutional units having an epoxy group as a polymerizable group can be synthesized by copolymerizing (A1) at least one selected from the group consisting of unsaturated carboxylic acids and unsaturated carboxylic acid anhydrides (henceforth referred to also as “(A1) compound”) with (A2) an epoxy group-containing unsaturated compound (henceforth referred to also as “(A2) compound”). In this case, [A] the alkali-soluble resin is a copolymer comprising constitutional units formed from at least one selected from the group consisting of unsaturated carboxylic acids and an unsaturated carboxylic acid anhydrides and constitutional units formed from an epoxy group-containing unsaturated compound.

[A] The alkali-soluble resin can be produced by, for example, copolymerizing (A1) a compound that gives a carboxyl group-containing constitutional unit with (A2) a compound that gives an epoxy group-containing constitutional unit, in the presence of a polymerization initiator in a solvent. In the case of using a positive type, a copolymer may be formed by further adding (A3) a hydroxy group-containing unsaturated compound to afford a hydroxy group-containing constitutional unit (hereinafter also referred to as “(A3) compound”). Moreover, in the production of [A] the alkali-soluble resin, a copolymer can also be formed by further adding, together with the (A1) compound, (A2) compound, and (A3) compound, (A4) a compound (an unsaturated compound that affords a constitutional unit other than the constitutional units derived from the (A1) compound, (A2) compound, and (A3) compound). Hereinafter, each of the compounds is described in detail.

### [(A1) Compound]

Examples of the (A1) compound include unsaturated monocarboxylic acids, unsaturated dicarboxylic acids, anhydrides of unsaturated dicarboxylic acids, and mono[(meth)acryloyloxyalkyl]esters of polyhydric carboxylic acids.

Examples of the unsaturated monocarboxylic acids include acrylic acid, methacrylic acid, and crotonic acid.

Examples of the unsaturated dicarboxylic acids include maleic acid, fumaric acid, citraconic acid, mesaconic acid, and itaconic acid.

Examples of the anhydrides of unsaturated dicarboxylic acids include anhydrides of the compounds provided above as examples of the aforementioned dicarboxylic acids.

Examples of the mono[(meth)acryloyloxyalkyl]esters of polyhydric carboxylic acids include mono[2-(meth)acryloyloxyethyl]succinate and mono[2-(meth)acryloyloxyethyl]phthalate.

Among these (A1) the compounds, acrylic acid, methacrylic acid, and maleic anhydride are preferable, and acrylic acid, methacrylic acid and maleic anhydride are more preferable from the perspective of copolymerization reactivity, solubility in an aqueous alkali solution, and ready availability.

These (A1) compounds may be used singly or by mixing two or more thereof.

The proportion of (A1) compounds used is preferably 5% by mass to 30% by mass, more preferably 10% by mass to 25% by mass, based on the total of the (A1) compounds and the (A2) compound (and optionally the (A3) compound and (A4) compound as necessary). Adjustment of the proportion of the (A1) compound used to 5% by mass to 30% by mass optimizes the solubility of the [A] alkali-soluble resin in an aqueous alkali solution and obtains an insulation film excelling in radiation sensitivity.

### [(A2) Compound]

(A2) Compound is an epoxy group-containing unsaturated compound having a radical polymerizability. Examples of the epoxy group include an oxiranyl group (a 1,2-epoxy structure) or an oxetanyl group (a 1,3-epoxy structure).

Examples of the unsaturated compound having an oxiranyl group include glycidyl acrylate, glycidyl methacrylate, 2-methylglycidyl methacrylate, 3,4-epoxybutyl acrylate, 3,4-epoxybutyl methacrylate, 6,7-epoxyheptyl acrylate, 6,7-epoxyheptyl methacrylate, 6,7-epoxyheptyl α-ethylacrylate, o-vinylbenzyl glycidyl ether, m-vinylbenzyl glycidyl ether, or p-vinylbenzyl glycidyl ether, and 3,4-epoxycyclohexyl methacrylate. Among these, glycidyl methacrylate, 2-methylglycidyl methacrylate, 6,7-epoxyheptyl methacrylate, o-vinylbenzyl glycidyl ether, m-vinylbenzyl glycidyl ether, p-vinylbenzyl glycidyl ether, 3,4-epoxycyclohexyl methacrylate, 3,4-epoxycyclohexyl acrylate, and the like are preferred from the perspective of copolymerization reactivity and improvement in solvent resistance or the like of an insulation film.

Examples of the unsaturated compound having an oxetanyl group include acrylic acid esters such as 3-(acryloyloxymethyl)oxetane, 3-(acryloyloxymethyl)-2-methyloxetane, 3-(acryloyloxymethyl)-3-ethyloxetane, 3-(acryloyloxymethyl)-2-phenyloxetane, 3-(2-acryloyloxyethyl)oxetane, 3-(2-acryloyloxyethyl)-2-ethyloxetane, 3-(2-acryloyloxyethyl)-3-ethyloxetane, and 3-(2-acryloyloxyethyl)-2-phenyloxetane; methacrylic acid esters such as 3-(methacryloyloxymethyl)oxetane, 3-(methacryloyloxymethyl)-2-methyloxetane, 3-(methacryloyloxymethyl)-3-ethyloxetane, 3-(methacryloyloxymethyl)-2-phenyl oxetane, 3-(2-methacryloyloxyethyl)oxetane, 3-(2-methacryloyloxyethyl)-2-ethyloxetane, 3-(2-methacryloyloxyethyl)-3-ethyloxetane, 3-(2-methacryloyloxyethyl)-2-phenyloxetane, and 3-(2-methacryloyloxyethyl)-2,2-difluorooxetane, and the like.

Among these (A2) compounds, glycidyl methacrylate, and 3,4-epoxycyclohexyl methacrylate, and 3-(methacryloyloxymethyl)-3-ethyloxetane are preferable. These (A2) compounds may be used singly or by mixing two or more thereof.

The proportion of the (A2) compound used is preferably 5% by mass to 60% by mass, more preferably 10% by mass to 50% by mass, based on the total of the (A1) compound and the (A2) compound (and optionally the (A3) compound and (A4) compound as necessary). Adjustment of the proportion of the (A2) compound used to 5% by mass to 60% by mass, makes it possible to form a cured film excellent in curability, namely, the insulation film of the present embodiment.

### [(A3) Compound]

Examples of the (A3) compound include an (meth)acrylic acid ester having a hydroxy group, an (meth)acrylic acid ester having a phenolic hydroxyl group, and hydroxy styrene.

Examples of the acrylic acid ester having a hydroxy group include 2-hydroxyethyl acrylate, 3-hydroxypropyl acrylate, 4-hydroxybutyl acrylate, 5-hydroxypentyl acrylate, and 6-hydroxyhexyl acrylate.

Examples of methacrylic acid esters having a hydroxy group include 2-hydroxy ethyl methacrylate, 3-hydroxypropyl methacrylate, 4-hydroxybutyl methacrylate, 5-hydroxypentyl methacrylate, and 6-hydroxyhexyl methacrylate.

Examples of acrylic acid esters having a phenolic hydroxyl group include 2-hydroxyphenyl acrylate and 4-hydroxyphenyl acrylate. Examples of methacrylic acid esters having a phenolic hydroxyl group include 2-hydroxyphenyl methacrylate and 4-hydroxyphenyl methacrylate.

As hydroxystyrenes, o-hydroxystyrene, p-hydroxystyrene, and α-methyl-p-hydroxy styrene are preferred.

These (A3) compounds may be used singly or by mixing two or more thereof.

The proportion of the (A3) compound used is preferably 1% by mass to 30% by mass, more preferably 5% by mass to 25% by mass, based on the total of the (A1) compound, the (A2) compound, and the (A3) compound (and optionally the (A4) compounds as necessary).

### [(A4) Compound]

The (A4) compound is not particularly limited provided that if it is an unsaturated compound other than the above-described (A1) compound, (A2) compound, and (A3) compound. Examples of the (A4) compound include methacrylic acid chain alkyl esters, methacrylic acid cyclic alkyl esters, acrylic acid chain alkyl esters, acrylic acid cyclic alkyl esters, methacrylic acid aryl ester, acrylic acid aryl esters, unsaturated dicarboxylic acid diesters, maleimide compounds, unsaturated aromatic compounds, conjugate dienes, unsaturated compounds having a tetrahydrofuran skeleton or the like, and other unsaturated compounds.

Examples of the methacrylic acid chain alkyl esters include methyl methacrylate, ethyl methacrylate, n-butyl methacrylate, sec-butyl methacrylate, t-butyl methacrylate, 2-ethylhexyl methacrylate, isodecyl methacrylate, n-lauryl methacrylate, tridecyl methacrylate, and n-stearyl methacrylate.

Examples of the methacrylic acid cyclic alkyl esters include cyclohexyl methacrylate, 2-methylcyclohexyl methacrylate, tricyclo[5.2.1.0^{2,6}]decan-8-yl methacrylate, tricyclo[5.2.1.0^{2,6}]decan-8-yloxyethyl methacrylate, and isoboronyl methacrylate.

Examples of the acrylic acid chain alkyl esters include methyl acrylate, ethyl acrylate, n-butyl acrylate, sec-butyl acrylate, t-butyl acrylate, 2-ethylhexyl acrylate, isodecyl acrylate, n-lauryl acrylate, tridecyl acrylate, and n-stearyl acrylate.

Examples of the acrylic acid cyclic alkyl esters include cyclohexyl acrylate, 2-methylcyclohexyl acrylate, tricyclo[5.2.1.0^{2,6}]decan-8-yl acrylate, tricyclo[5.2.1.0^{2,6}]decan-8-yloxyethyl acrylate, and isoboronyl acrylate.

Examples of the methacrylic acid aryl esters include phenyl methacrylate and benzyl methacrylate.

Examples of the acrylic acid aryl esters include phenyl acrylate and benzyl acrylate.

Examples of the unsaturated dicarboxylic acid diesters include diethyl maleate, diethyl fumarate, and diethyl itaconate.

Examples of the maleimide compounds include N-phenylmaleimide, N-cyclohexylmaleimide, N-benzylmaleimide, N-(4-hydroxyphenyl)maleimide, N-(4-hydroxybenzyl)maleimide, N-succinimidyl-3-maleimidebenzoate, N-succinimidyl-4-maleimidebutyrate, N-succinimidyl-6-maleimidecaproate, N-succinimidyl-3-maleimidepropionate, and N-(9-acridinyl)maleimide.

Examples of the unsaturated aromatic compounds include styrene, α-methylstyrene, m-methylstyrene, p-methylstyrene, vinyltoluene, and p-methoxystyrene.

Examples of the conjugate dienes include 1,3-butadiene, isoprene, and 2,3-dimethyl-1,3-butadiene.

Examples of the unsaturated compounds containing a tetrahydrofuran skeleton include tetrahydrofurfuryl methacrylate, 2-methacryloyloxy-propionic acid tetrahydrofurfuryl ester, and 3-(meth)acryloyloxytetrahydrofuran-2-one.

Examples of other unsaturated compounds include acrylonitrile, methacrylonotrile, vinyl chloride, vinylidene chloride, acrylamide, methacrylamide, and vinyl acetate.

Among these (A4) compounds, methacrylic acid chain alkyl esters, methacrylic acid cyclic alkyl esters, methacrylic acid aryl ester, maleimide compounds, tetrahydrofuran skeleton, unsaturated aromatic compounds, acrylic acid cyclic alkyl esters, are preferable. Among these, specifically, styrene, methyl methacrylate, t-butyl methacrylate, n-lauryl methacrylate, benzyl methacrylate, tricyclo[5.2.1.0^{2,6}]decan-8-yl methacrylate, p-methoxystyrene, 2-methylcyclohexyl acrylate, N-phenylmaleimide, N-cyclohexylmaleimide, tetrahydrofurfuryl methacrylate, are preferred from the perspective of copolymerization reactivity and solubility in an aqueous alkali solution.

These (A4) compounds may be used singly or by mixing two or more thereof.

The proportion of the (A4) compound used is preferably 10% by mass to 80% by mass, based on the total of the (A1) compound, the (A2) compound, and the (A4) compound (and optionally the (A3) compounds as necessary).

### <Synthetic Method 1 of [A] Alkali-Soluble Resin Containing Constitutional Unit Including Carboxyl Group and Constitutional Unit Including Epoxy Group as Polymerizable Group>

[A] The alkali-soluble resin can be produced by copolymerizing the above-described (A1) compound and (A2) compound (and optionally the (A3) compound and (A4) compound) in the presence of a polymerization initiator in a solvent, for example. In accordance with such a synthesis method, a copolymer comprising at least an epoxy group-containing constitutional unit can be synthesized.

Examples of the solvent to be used in the polymerization reaction for producing the [A] alkali-soluble resin include alcohols, glycol ethers, ethylene glycol alkyl ether acetates, diethylene glycol monoalkyl ethers, diethylene glycol dialkyl ethers, dipropylene glycol dialkyl ethers, propylene glycol monoalkyl ethers, propylene glycol alkyl ether acetates, propylene glycol monoalkyl ether propionates, ketones, and esters.

As the polymerization initiator to be used in the polymerization reaction for producing the [A] alkali-soluble resin, compounds which are commonly known as a radical polymerization initiator can be used. Examples of the radical polymerization initiator include azo compounds such as 2,2′-azobisisobutyronitrile (AIBN), 2,2′-azobis(2,4-dimethylvaleronitrile), and 2,2′-azobis(4-methoxy-2,4-dimethylvaleronitrile).

In the polymerization reaction for producing the [A] alkali-soluble resin, a molecular weight regulator can be used for the purpose of regulating a molecular weight.

Examples of the molecular weight regulator include halogenated hydrocarbons such as chloroform and carbon tetrabromide; mercaptans such as n-hexylmercaptan, n-octylmercaptan, n-dodecylmercaptan, t-dodecylmercaptan, and thioglycolic acid; xanthogens such as dimethyl xanthogen sulfide and diisopropyl xanthogen disulfide; terpinolenes, and an α-methylstyrene dimer.

The weight average molecular weight (Mw) of the [A] alkali-soluble resin is preferably 1000 to 30000, more preferably 5000 to 20000. Adjustment of the Mw of the [A] alkali-soluble resin to within the above range can enhance the sensitivity and the developability to radiation of the first radiation-sensitive resin composition. The Mw and the number average molecular weight (Mn) of a polymer referred to herein were measured by gel permeation chromatography (GPC) under the following conditions:

instrument: GPC-101 (manufactured by Showa Denko K.K.)
column: combination of GPC-KF-801, GPC-KF-802, GPC-KF-803, and GPC-KF-804.
mobile phase: tetrahydrofuran
column temperature: 40° C.
flow rate: 1.0 mL/minute
sample concentration: 1.0% by mass
sample injection: 100 μL
detector: differential refractometer
standard substance: monodisperse polystyrene.

### <Synthetic Method 2 of [A] Alkali-Soluble Resin Containing Constitutional Unit Including Carboxyl Group and Constitutional Unit Including (Meth)Acrylic Group as Polymerizable Group>

The [A] alkali-soluble resin can be synthesized by, for example, reacting a copolymer capable of being synthesized using one or more of the above-described (A1) compound (hereinafter also referred to as “specific copolymer”) with the above-described (A2) compound. In accordance with this synthesis method, a copolymer containing at least constitutional units having a (meth)acryloyloxy group can be synthesized.

The constitutional unit having a (meth)acryloyloxy group which the [A] alkali-soluble resin contains is obtained by reacting a (meth)acrylic acid ester having an epoxy group with a carboxyl group in the copolymer, and the constitutional unit having a (meth)acrylic group after the reaction is represented by the following formula (1). This constitutional unit is obtained by forming an ester linkage by reacting a carboxyl group in a specific copolymer derived from the (A1) compound with an epoxy group of the (A2) compound.

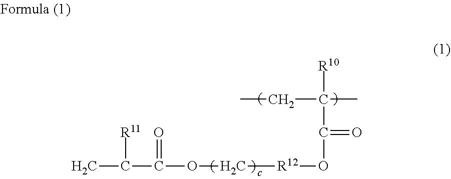

In the above formula (1), R¹⁰ and R¹¹ are each independently a hydrogen atom or a methyl group. c is an integer of 1 to 6. R¹² is a divalent group represented by the following formula (2-1) or the following formula (2-2).

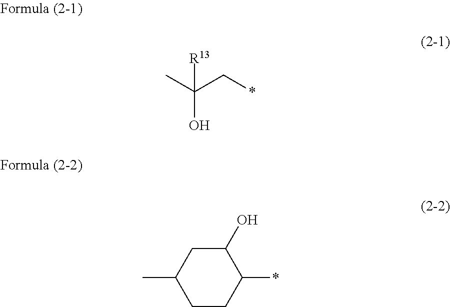

In the above formula (2-1), R¹³ is a hydrogen atom or a methyl group. In the above formula (2-1) or the above formula (2-2), * represents a site of combination with an oxygen atom.

Regarding the constitutional unit represented by the above formula (1), when, for example, a compound such as glycidyl methacrylate and 2-methylglycidyl methacrylate is reacted as the (A2) compound with a copolymer having a carboxyl group, R¹² in the above formula (1) is the above formula (2-1). On the other hand, when a compound such as 3,4-epoxycyclohexylmethyl methacrylate is reacted as the (A2) compound, R¹² in the above formula (1) is the above formula (2-2).

In synthesis of the specific copolymer, a compound other than the (A1) compound, such as the above-mentioned (A3) compound and the above-mentioned (A4) compound, may be used as a copolymerization ingredient. As these compounds, methyl methacrylate, n-butyl methacrylate, benzyl methacrylate, 2-hydroxyethyl methacrylate, tricyclo[5.2.1.0^{2,6}]decan-8-ylmethacrylate, styrene, p-methoxystyrene, tetrahydrofuran-2-yl methacrylate, and 1,3-butadiene are preferable from the perspective of copolymerization reactivity.

Examples of the method of copolymerization to form the specific copolymer include a method of polymerizing the (A1) compound and, as necessary, the (A3) compound and the like using a radical polymerization initiator in a solvent.

Examples of the radical polymerization initiator include those provided as examples in the section of the above-described [A] alkali-soluble resin. The amount of the radical polymerization initiator used is 0.1% by mass to 50% by mass, preferably 0.1% by mass to 20% by mass, relative to 100% by mass of the polymerizable unsaturated compounds.

The specific copolymer may be used in the form of its original polymerization reaction solution for the production of the [A] alkali-soluble resin or alternatively may be used for the production of the [A] alkali-soluble resin after separating the copolymer from the solution.

The molecular weight distribution (Mw/Mn) of the specific copolymer is preferably 5.0 or less, more preferably 3.0 or less.

Adjustment of the molecular weight distribution (Mw/Mn) to 5.0 or less makes it possible to maintain the shape of the resulting pattern good. An insulation film containing a specific copolymer having a molecular weight distribution (Mw/Mn) within the above-described specific range has a high degree of developability. That is, in the development step, a prescribed pattern can be formed easily without producing any undeveloped residue.

The content of the constitutional units derived from the (A1) compound of the specific copolymer is preferably 5% by mass to 60% by mass, more preferably 7% by mass to 50% by mass, particularly preferably 8% by mass to 40% by mass.

The content of the constitutional units derived from the (A3) compound and the (A4) compound, etc., except the (A1) compound of the specific copolymer is 10% by mass to 90% by mass, 20% by mass to 80% by mass.

In the reaction of the specific copolymer with the (A2) compound, an unsaturated compound having an epoxy group is added to a copolymer solution preferably containing a polymerization inhibitor in the presence of an appropriate catalyst according to necessity, followed by stirring for a prescribed time under heating. Examples of the catalyst include tetrabutylammonium bromide. Examples of the polymerization inhibitor include p-methoxyphenol. Preferably, the reaction temperature is 70° C. to 100° C. Preferably, the reaction time is 8 hours to 12 hours.

The ratio of use of the (A2) compound is preferably 5% by mass to 99% by mass, more preferably 10% by mass to 97% by mass, relative to the carboxyl groups derived from the (A1) compound in the copolymer. Adjustment of the ratio of use of the (A2) compound to within the above-mentioned range improves the reactivity with the copolymer, the curability of an insulation film, and the like. Regarding the (A2) compound, species thereof may be used singly or alternatively two or more species thereof may be used in combination.

Next, description is made to a polyimide resin (hereinafter also referred to as “polyimide”), which is [A] the alkali-soluble resin.

The polyimide is obtained by imidizing a polyamic acid by dehydration-cyclizing it. Such a polyamic acid can be obtained, for example, by reacting tetracarboxylic dianhydride with a diamine, and specifically, it can be obtained by the method mentioned in Japanese Patent Application Laid-Open No. 2010-97188.

The polyimide being the [A] alkali-soluble resin may be a completely imidized product obtained by dehydration-cyclizing all the amic acid structure possessed by the polyamic acid, which is the precursor to the polyimide, or alternatively may be a partially imidized product in which amic acid structures and imide ring structures are present together due to dehydration-cyclization of only part of amic acid structures.

The imidization ratio of the polyimide, which is [A] the alkali-soluble resin, is preferably 30% or more, more preferably 50% to 99%, even more preferably 65% to 99%. It is noted that the imidization ratio in this case is a ratio, expressed in percentage, of the number of the imide ring structure to the sum total of the number of the amic acid structure and the number of the imide ring structure of the polyimide. In this case, a part of the imide ring may be an isoimide ring. This alkali-soluble resin including the isoimide ring can be obtained according to the method mentioned in Japanese Patent Application Laid-Open No. 2010-97188, as one example.

### <[B] Quinonediazide Compound>

The first radiation-sensitive resin composition of this embodiment may contain [A] the alkali-soluble resin as an essential ingredient and also contain [B] a quinonediazide compound. This enables use of a first radiation-sensitive resin composition as a positive type first radiation-sensitive resin composition.

[B] The quinonediazide compound is a quinonediazide compound that generates a carboxylic acid by the application of radiation. As [B] the quinonediazide compound, a condensate of a phenolic compound or an alcoholic compound (hereinafter referred to as “scaffold”) and a 1,2-naphthoquinonediazide sulfonic acid halide can be used.

Examples of the aforementioned scaffold include trihydroxybenzophenones, tetrahydroxybenzophenones, pentahydroxybenzophenones, hexahydroxybenzophenones, (polyhydroxyphenyl)alkanes, and other scaffolds.

Examples of the trihydroxybenzophenones include 2,3,4-trihydroxybenzophenone and 2,4,6-trihydroxybenzophenone.

Examples of the tetrahydroxybenzophenones include 2,2′,4,4′-tetrahydroxybenzophenone, 2,3,4,3′-tetrahydroxybenzophenone, 2,3,4,4′-tetrahydroxybenzophenone, 2,3,4,2′-tetrahydroxy-4′-methylbenzophenone, and 2,3,4,4′-tetrahydroxy-3′-methoxybenzophenone.

Examples of the pentahydroxybenzophenones include 2,3,4,2′,6′-pentahydroxybenzophenone.

Examples of the hexahydroxybenzophenones include 2,4,6,3′,4′,5′-hexahydroxybenzophenone and 3,4,5,3′,4′,5′-hexahydroxybenzophenone.

Examples of the (polyhydroxyphenyl)alkanes include bis(2,4-dihydroxyphenyl)methane, bis(p-hydroxyphenyl)methane, tris(p-hydroxyphenyl)methane, 1,1,1-tris(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenyl propane, 4,4′-[1-[4-{1-(4-hydroxyphenyl)-1-methylethyl}phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, and 2,2,4-trimethyl-7,2′,4′-trihydroxyflavan.

Examples of other scaffolds include 2-methyl-2-(2,4-dihydroxyphenyl)-4-(4-hydroxyphenyl)-7-hydroxychroman, 1-[1-[3-{1-(4-hydroxyphenyl)-1-methylethyl}-4,6-dihydroxyphenyl]-1-methylethyl]-3-[1-[3-{1-(4-hydroxyphenyl)-1-methylethyl}-4,6-dihydroxyphenyl]-1-methylethyl]benzene, and 4,6-bis{1-(4-hydroxyphenyl)-1-methylethyl}-1,3-dihydroxybenzene.

Among these scaffolds, 2,3,4,4′-tetrahydroxybenzophenone, and 1,1,1-tris(p-hydroxyphenyl)ethane, and 4,4′-[1-[4-{1-(4-hydroxyphenyl)-1-methylethyl}phenyl]ethylidene]bisphenol, are preferably used.

As the 1,2-naphthoquinonediazide sulfonic acid halides, 1,2-naphthoquinonediazide sulfonic acid chlorides are preferable. Examples of the 1,2-naphthoquinonediazide sulfonic acid chlorides include 1,2-naphthoquinonediazide-4-sulfonic acid chloride and 1,2-naphthoquinonediazide-5-sulfonic acid chloride. Among these, 1,2-naphthoquinonediazide-5-sulfonic acid chloride is more preferable.

In a condensation reaction of a phenolic compound or alcoholic compound (scaffold) and a 1,2-naphthoquinonediazide sulfonic acid halide, the 1,2-naphthoquinonediazide sulfonic acid halide corresponding to preferably 30 mol % to 85 mol %, more preferably 50 mol % to 70 mol % relative to the number of the OH groups in the phenolic compound or alcoholic compound can be used. The condensation reaction can be performed by a method known in the art.

Furthermore, as [B] the quinonediazide compound, 1,2-naphthoquinonediazide sulfonic acid amides in which the ester linkages in the scaffolds provided above as examples have been changed to amide linkages such as 2,3,4-triaminobenzophenone-1,2-naphthoquinonediazide-4-sulfonic acid amide are also preferably used.

These [B] quinonediazide compounds can be used singly or by mixing two or more thereof. The ratio of use of the quinonediazide compound in the first radiation-sensitive resin composition of the present exemplary embodiment is preferably 5 parts by mass to 100 parts by mass, more preferably 10 parts by mass to 50 parts by mass with respect to 100 parts by mass of the [A] alkali-soluble resin. Adjustment of the ratio of use of the quinonediazide compound to within the above-mentioned range can improve the patterning performance by enlarging the difference in solubility in an aqueous alkali solution as a developer between a part irradiated with radiation and an unirradiated part. Furthermore, it also can improve the solvent resistance of an insulation film obtained by using this radiation-sensitive resin composition.

### <[C] Polymerizable Compound>

The first radiation-sensitive resin composition according to the present embodiment contains the [A] alkali-soluble resin as an essential ingredient, and may also contain the [C] polymerizable compound and the [D] radiation-sensitive polymerization initiator that will be described below, instead of the [B] quinonediazide compound as mentioned above. This enables use of a first radiation-sensitive resin composition as a negative type first radiation-sensitive resin composition.

Examples of the [C] polymerizable compound contained in the first radiation-sensitive resin composition of this embodiment include ω-carboxypolycaprolactone mono(meth)acrylate, ethylene glycol (meth)acrylate, 1,6-hexanediol di(meth)acrylate, 1,9-nonanediol di(meth)acrylate, tetraethylene glycol di(meth)acrylate, polyethylene glycol di(meth)acrylate, polypropylene glycol di(meth)acrylate, bisphenoxyethanol fluorene di(meth)acrylate, dimethylol tricyclodecane di(meth)acrylate, 2-hydroxy-3-(meth)acryloyloxypropyl methacrylate, 2-(2′-vinyloxyethoxy)ethyl (meth)acrylate, trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, tri{2-(meth)acryloyloxyethyl}phosphate, ethylene oxide-modified dipentaerythritol hexaacrylate, succinic acid-modified pentaerythritol triacrylate, and the like, and a urethane (meth)acrylate compound obtained by reacting a compound having a linear alkylene group and an alicyclic structure and having two or more isocyanate groups with a compound having one or more hydroxy groups and 3 to 5 (meth)acryloyloxy groups in its molecule, and the like.

The [C] polymerizable compounds may be used singly or by mixing two or more thereof.

The ratio of use of the [C] polymerizable compound in the first radiation-sensitive resin composition is preferably 20 parts by mass to 200 parts by mass, more preferably 40 parts by mass to 160 parts by mass with respect to 100 parts by mass of [A] alkali-soluble resin. Adjustment of the ratio of use of the [C] polymerizable compound to within the above-mentioned range makes it possible to form a cured film, excellent in adhesion and hardness even under low exposure, namely the insulation film.

### <[D] Radiation-Sensitive Polymerization Initiator>

[D] The radiation-sensitive polymerization initiator contained together with [C] the polymerizable compound in the first radiation-sensitive resin composition of this embodiment is an ingredient that senses radiation to generate an active species capable of initiating the polymerization of the [C] polymerizable compound. Examples of [D] radiation-sensitive polymerization initiator include an O-acyloxime compound, an acetophenone compound, and a biimidazole compound. These compounds may be used singly or may be used in combination of two or more thereof.

Examples of the O-acyloxime compound include 1,2-octanedione 1-[4-(phenylthio)-2-(O-benzoyloxime)], ethanone-1-[9-ethyl-6-(2-methylbenzoyl)-9H-carbazol-3-yl]-1-(O-acetyloxime), 1-[9-ethyl-6-benzoyl-9.H.-carbazol-3-yl]-octan-1-oneoxime-O-acetate, 1-[9-ethyl-6-(2-methylbenzoyl)-9.H.-carbazol-3-yl]-ethan-1-oneoxime-O-benzoate, 1-[9-n-butyl-6-(2-ethylbenzoyl)-9.H.-carbazol-3-yl]-ethan-1-oneoxime-O-benzoate, ethanone-1-[9-ethyl-6-(2-methyl-4-tetrahydrofuranylbenzoyl)-9.H.-carbazol-3-yl]-1-(O-acetyloxime), ethanone-1-[9-ethyl-6-(2-methyl-4-tetrahydropyranylbenzoyl)-9.H.-carbazol-3-yl]-1-(O-acetyloxime), ethanone-1-[9-ethyl-6-(2-methyl 5-tetrahydrofuranylbenzoyl)-9.H.-carbazol-3-yl]-1-(O-acetyloxime), and ethanone-1-[9-ethyl-6-{2-methyl-4-(2,2-dimethyl-1,3-dioxoranyl)methoxybenzoyl}-9.H.-carbazol-3-yl]-1-(O-acetyloxime).

Among these, 1,2-octanedione 1-[4-(phenylthio)-2-(O-benzoyloxime)]ethanone-1-[9-ethyl-6-(2-methylbenzoyl)-9H-carbazol-yl]-1-(O-acetyl oxime), ethanone-1-[9-ethyl-6-(2-methyl-4-tetrahydrofuranylmethoxybenzoyl)-9.H.-carbazol-3-yl]-1-(O-acetyl oxime), or ethanone-1-[9-ethyl-6-{2-methyl-4-(2,2-dimethyl-1,3-dioxoranyl)methoxybenzoyl}-9.H.-carbazol-3-yl]-1-(O-acetyloxime), are preferable.

Examples of the acetophenone compound include an α-aminoketone compound and an α-hydroxyketone compound.

Examples of the α-aminoketone compound include 2-benzyl-2-dimethylamino-1-(4-morpholinophenyl)-butan-1-one, 2-dimethylamino-2-(4-methylbenzyl)-1-(4-morpholin-4-yl-phenyl)-butan-1-one, and 2-methyl-1-(4-methylthiophenyl)-2-morpholinopropan-1-one.

Examples of the α-hydroxyketone compound include 1-phenyl-2-hydroxy-2-methylpropan-1-one, 1-(4-i-propylphenyl)-2-hydroxy-2-methylpropan-1-one, 4-(2-hydroxyethoxy)phenyl-(2-hydroxy-2-propyl)ketone, and 1-hydroxycyclohexyl phenyl ketone.

As the acetophenone compound, an α-aminoketone compound is preferred, and especially, 2-benzyl-2-dimethylamino-1-(4-morpholinophenyl)-butan-1-one, 2-dimethylamino-2-(4-methylbenzyl)-1-(4-morpholin-4-yl-phenyl)-butan-1-one, and 2-methyl-1-(4-methylthiophenyl)-2-morpholinopropan-1-one are preferred.

As the biimidazole compound, for example, 2,2′-bis(2-chlorophenyl)-4,4′,5,5′-tetraphenyl-1,2′-biimidazole, 2,2′-bis(2,4-dichlorophenyl)-4,4′,5,5′-tetraphenyl-1,2′-biimidazole, or 2,2′-bis(2,4,6-trichlorophenyl)-4,4′,5,5′-tetraphenyl-1,2′-biimidazole is preferred, and among these, 2,2′-bis(2,4-dichlorophenyl)-4,4′,5,5′-tetraphenyl-1,2′-biimidazole is more preferred.

[D] These radiation-sensitive polymerization initiator can be used singly or by mixing two or more thereof. The ratio of use of [D] the radiation-sensitive polymerization initiator is preferably 1 parts by mass to 40 parts by mass, more preferably 5 parts by mass to 30 parts by mass with respect to 100 parts by mass of [A] the alkali-soluble resin. Adjustment of the ratio of use of [D] the radiation-sensitive polymerization initiator to 1 parts by mass to 40 parts by mass, allows the first radiation-sensitive resin composition to form an insulation film, excellent in solvent resistance, hardness, and adhesion, even under low exposure.

### <Thermal Acid Generator [E]>

The first radiation-sensitive resin composition according to the present embodiment may contain [E] a thermal acid generator. Here, the thermal acid generator is defined to be a compound that releases, upon application of heat, an acidic active substance that acts as a catalyst in curing [A] the alkali-soluble resin. Use of such an [E] thermal acid generator is favorable especially from the perspective of enabling use of a curing temperature as low as 200° C. or less. That is, use of the [E] thermal acid generator promotes the curing reaction of the [A] alkali-soluble resin in a heating step after the development of the first radiation-sensitive resin composition and makes it possible to form a cured film excelling in surface hardness and heat resistance, i.e., the insulation film of this embodiment. Consequently, it becomes possible to reduce the stretchability of a film even if the film receives heat history during a subsequent step. Such an effect becomes more likely to develop due to combination with a [F] cure accelerator described below.

[E] The thermal acid generator includes an ionic compound and a nonionic compound.

As the ionic compound, one containing neither a heavy metal nor a halogen ion is preferred.

Examples of an ionic thermal acid generator include triphenylsulfonium, 1-dimethylthionaphthalene, 1-dimethylthio-4-hydroxynaphthalene, 1-dimethylthio-4,7-dihydroxynaphthalene, 4-hydroxyphenyldimethylsulfonium, benzyl-4-hydroxyphenylmethylsulfonium, 2-methylbenzyl-4-hydroxyphenylmethylsulfonium, 2-methylbenzyl-4-acetylphenylmethylsulfonium, and 2-methylbenzyl-4-benzoyloxyphenylmethylsulfonium; and their methanesulfonic acid salts, trifluoromethanesulfonic acid salts, camphorsulfonic acid salts, p-toluenesulfonic acid salts, and hexafluorophosphonic acid salts.

Examples of the nonionic [E] thermal acid generator include a halogen-containing compound, a diazomethane compound, a sulfone compound, a sulfonic acid ester compound, a carboxylic acid ester compound, a phosphoric acid ester compound, a sulfonimide compound, and a sulfone benzotriazole compound. Of these, especially, a sulfonimide compound is preferred.

Examples of the sulfonimide compound include N-(trifluoromethylsulfonyloxy)succinimide (trade name “SI-105”, Midori Kagaku Co., Ltd.), N-(camphorsulfonyloxy)succinimide (trade name “SI-106” Midori Kagaku Co., Ltd.), N-(4-methylphenylsulfonyloxy)succinimide (trade name “SI-101”, Midori Kagaku Co., Ltd.), N-(2-trifluoromethylphenylsulfonyloxy)succinimide, N-(4-fluorophenylsulfonyloxy)succinimide, N-(trifluoromethylsulfonyloxy)phthalimide, N-(camphorsulfonyloxy)phthalimide, N-(2-trifluoromethyl phenylsulfonyloxy)phthalimide, N-(2-fluorophenylsulfonyloxy)phthalimide, N-(trifluoromethylsulfonyloxy)diphenylmaleimide (trade name “PI-105”, Midori Kagaku Co., Ltd.), N-(camphorsulfonyloxy)diphenylmaleimide, 4-methylphenylsulfonyloxy)diphenylmaleimide, N-(2-trifluoromethylphenylsulfonyloxy)diphenylmaleimide, N-(4-fluorophenylsulfonyloxy)diphenylmaleimide, N-(4-fluorophenylsulfonyloxy)diphenylmaleimide, N-(phenylsulfonyloxy)bicyclo[2.2.1]hept-5-ene-2,3-dicarboxylimide (trade name “NDI-100”, Midori Kagaku Co., Ltd.), N-(4-methylphenylsulfonyloxy)bicyclo[2.2.1]hept-5-ene-2,3-dicarboxylimide (trade name “NDI-101”, Midori Kagaku Co., Ltd.), N-(trifluoromethanesulfonyloxy)bicyclo[2.2.1]hept-5-ene-2,3-dicarboxylimide (trade name “NDI-105”, Midori Kagaku Co., Ltd.), N-(nonafluorobutanesulfonyloxy)bicyclo[2.2.1]hept-5-ene-2,3-dicarboxylimide (trade name “NDI-109”, Midori Kagaku Co., Ltd.), N-(camphorsulfonyloxy)bicyclo[2.2.1]hept-5-ene-2,3-dicarboxylimide (trade name “NDI-106”, Midori Kagaku Co., Ltd.), N-(camphorsulfonyloxy)-7-oxabicyclo[2.2.1]hept-5-ene-2,3-dicarboxylimide, N-(trifluoromethylsulfonyloxy)-7-oxabicyclo[2.2.1]hept-5-ene-2,3-dicarboxylimide, N-(4-methylphenylsulfonyloxy)bicyclo[2.2.1]hept-5-ene-2,3-dicarboxylimide, N-(4-methylphenylsulfonyloxy)-7-oxabicyclo[2.2.1]hept-5-ene-2,3-dicarboxylimide, N-(2-trifluoromethylphenylsulfonyloxy)bicyclo[2.2.1]hept-5-ene-2,3-dicarboxylimide N-(2-trifluoromethylphenylsulfonyloxy)-7-oxabicyclo[2.2.1]hept-5-ene-2,3-dicarboxylimide, N-(4-fluorophenylsulfonyloxy)bicyclo[2.2.1]hept-5-ene-2,3-dicarboxylimide, N-(4-fluorophenylsulfonyloxy)-7-oxabicyclo[2.2.1]hept-5-ene-2,3-dicarboxylimide, N-(trifluoromethyl sulfonyloxy)bicyclo[2.2.1]heptane-5,6-oxy-2,3-dicarboxylimide, N-(camphorsulfonyloxy)bicyclo[2.2.1]heptane-5,6-oxy-2,3-dicarboxylimide, N-(4-methylphenylsulfonyloxy)bicyclo[2.2.1]heptane-5,6-oxy-2,3-dicarboxylimide, N-(2-trifluoromethylphenylsulfonyloxy)bicyclo[2.2.1]heptane-5,6-oxy-2,3-dicarboxylimide, N-(4-fluoro phenylsulfonyloxy)bicyclo[2.2.1]heptane-5,6-oxy-2,3-dicarboxylimide, N-(trifluoromethylsulfonyloxy)naphthyldicarboxylimide (trade name “NAI-105”, Midori Kagaku Co., Ltd.), N-(camphorsulfonyloxy)naphthyldicarboxylimide (trade name “NAI-106”, Midori Kagaku Co., Ltd.), N-(4-methylphenylsulfonyloxy)naphthyldicarboxylimide (trade name “NAI-101”, Midori Kagaku Co., Ltd.), N-(phenyl sulfonyl oxy)naphthyldicarboxylimide (trade name “NAI-100”, Midori Kagaku Co., Ltd.), N-(2-trifluoromethylphenylsulfonyloxy)naphthyldicarboxylimide, N-(4-fluorophenylsulfonyloxy)naphthyldicarboxylimide, N-(pentafluoroethylsulfonyloxy)naphthyldicarboxylimide, N-(heptafluoropropylsulfonyloxy)naphthyldicarboxylimide, N-(nonafluorobutylsulfonyloxy)naphthyldicarboxylimide (trade name “NAI-109”, Midori Kagaku Co., Ltd.), N-(ethyl sulfonyloxy)naphthyldicarboxylimide, N-(propylsulfonyloxy)naphthyldicarboxylimide, N-(butylsulfonyloxy)naphthyldicarboxylimide (trade name “NAI-1004”, Midori Kagaku Co., Ltd.), N-(pentyl sulfonyloxy)naphthyldicarboxylimide, N-(hexylsulfonyloxy)naphthyldicarboxylimide, N-(heptylsulfonyloxy)naphthyldicarboxylimide, N-(octylsulfonyloxy)naphthyldicarboxylimide, and N-(nonylsulfonyloxy)naphthyldicarboxylimide

Examples of other [E] thermal acid generators include tetrahydrothiophenium salts such as 1-(4-n-butoxynaphthalen-1-yl)tetrahydrothiophenium trifluoromethanesulfonate and 1-(4,7-dibutoxy-1-naphthalenyl)tetrahydrothiophenium trifluoromethanesulfonate.

Among these [E] thermal acid generators, benzyl-4-hydroxyphenylmethylsulfoniumhexafluorophosphate, 1-(4,7-dibutoxy-1-naphthalenyl)tetrahydrothiophenium trifluoromethanesulfonate, N-(trifluoromethylsulfonyloxy)naphthyldicarboxylimide, are preferable from the perspective of catalysis of the curing reaction of the [A] alkali-soluble resin,

The ratio of used amount of the [E] thermal acid generators is preferably 0.1 parts by mass to 10 parts by mass, more preferably 1 parts by mass to 5 parts by mass with respect to 100 parts by mass of the [A] alkali-soluble resin. Adjustment of the ratio of use of the used amount of the [E] thermal acid generators to within the above-mentioned range makes it possible to optimize the sensitivity of the first radiation-sensitive resin composition, and form a cured film excellent in surface hardness while maintaining transparency, namely, the insulation film.

### <[F] Cure Accelerator>

The first radiation-sensitive resin composition according to the present embodiment may contain [F] a cure accelerator. Use of a [F] cure accelerator is favorable especially from the perspective of enabling use of a curing temperature as low as 200° C. or less.

[F] The cure accelerator is at least one compound selected from the group consisting of compounds each having an electron withdrawing group and an amino group in the molecule thereof, such as 4,4′-diaminodiphenylsulfone, 2,2-bis(4-aminophenyl)hexafluoropropane, 2,2′-bis(trifluoromethyl)benzidine, ethyl 3-aminobenzenesulfonate, 3,5-bistrifluoromethyl-1,2-diaminobenzene, 4-aminonitrobenzene, and N,N-dimethyl-4-nitroaniline, tertiary amine compounds, amide compounds, thiol compounds, block isocyanate compounds, and imidazole ring-containing compounds.

Inclusion of [F] a cure accelerator selected from the specific compound group in the first radiation-sensitive resin composition promotes the cure of the first radiation-sensitive resin composition and, as a result, low temperature cure of an insulation film, specifically, cure at a temperature of 200° C. or less can be realized. Consequently, it becomes possible to reduce the stretchability of a film even if the film receives heat history during a subsequent step. Such an effect becomes more likely to develop in combination with a [E] thermal acid generator. Moreover, use of [F] the cure accelerator also can improve the storage stability of the first radiation-sensitive resin composition.

### <Other Ingredients>

The first radiation-sensitive resin composition of this embodiment may contain, in addition to [A] the alkali-soluble resin and [B] the quinonediazide compound or [A] the alkali-soluble resin and [C] the polymerizable compound and [D] the radiation-sensitive polymerization initiator and also in addition to [E] the thermal acid generator or [F] the cure accelerator, other optional ingredients such as a surfactant, a storage stabilizer, an adhesion promoter, and a heat resistance improver, according to necessity as long as the effect of the present invention is not adversely affected. These ingredients may be used singly or by mixing two or more thereof. Each ingredient will be described below.

### [Surfactant]

The surfactant may be used for the purpose of further improving the coating film formability of the first radiation-sensitive resin composition. Examples of the surfactant include a fluorine-based surfactant, a silicone-based surfactant, and the like which can be used for the second radiation-sensitive resin composition described below.

### [Storage Stabilizer]

Examples of the storage stabilizer include sulfur, quinones, hydroquinones, polyoxy compounds, amines, and nitronitroso compounds and more specifically include 4-methoxyphenol, N-nitroso-N-phenylhydroxylamine aluminum, and the like.

### [Adhesion Promoter]

The adhesion promoter may be used for the purpose of further improving the adhesion of an insulation film obtained from the first radiation-sensitive resin composition with an underlying layer, a substrate, or the like. As the adhesion promoter, a functional silane coupling agent having a reactive functional group, such as a carboxyl group, a methacryloyl group, a vinyl group, an isocyanate group, and an oxiranyl group, is preferably used, and examples thereof include trimethoxysilylbenzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, and β-(3,4-epoxycyclohexyl)ethyltrimethoxysilane.

### <Adjusting Method for First Radiation-Sensitive Resin Composition>

The first radiation-sensitive resin composition according to the present embodiment may contain, by uniformly mixing, in addition to [A] the alkali-soluble resin and [B] the quinonediazide compound or [A] the alkali-soluble resin and [C] the polymerizable compound and [D] the radiation-sensitive polymerization initiator and also in addition to [E] the thermal acid generator or [F] the cure accelerator, other optional ingredients which are optionally added. The first radiation-sensitive resin composition is preferably used by dissolving the composition in an appropriate solvent. The solvent may be used singly or by mixing two or more solvents.

As the solvent to be used for the preparation of the first radiation-sensitive resin composition of this embodiment, a solvent that homogeneously dissolves the essential ingredients and optional ingredients and that does not react with the individual ingredients is used. Examples of such a solvent include the same solvents as those enumerated as examples of a solvent usable for producing the above-described [A] alkali-soluble resin.

The content of the solvent is not particularly limited, but from the perspective of the spreadability, the stability, and the like of a first radiation-sensitive resin composition to be obtained, it is preferably an amount at which the total concentration of the individual ingredients, excluding the solvent, of the first radiation-sensitive resin composition becomes 5% by mass to 50% by mass, more preferably 10% by mass to 40% by mass. When preparing a solution of the first radiation-sensitive resin composition, in actuality, a concentration of solid (the ingredients other than the solvent occupying the composition solution) according to the intended purpose of use, the value of the desired film thickness, and the like is set within the above concentration range. More preferably, it is set according to a method of forming a coating film on a substrate, and this is described below.

Preferably, a solution-form composition thus prepared is filtered using a millipore filter with a pore diameter of approximately 0.5 μm or the like and then is used for the formation of an insulation film.

By means of the first radiation-sensitive resin composition obtained using the above-mentioned ingredients and preparation method, an insulation film being small in stretchability after heat history can be formed. This first radiation-sensitive resin composition has a low temperature effect; specifically, such an insulation film can be formed at a cure temperature of 200° C. or less. Moreover, in some cases, it is possible to form an insulation film even at a cure temperature of 180° C. or less, which is more suitable for the formation on a resin substrate.

Next, a detailed description is made to a second radiation-sensitive resin composition of an embodiment of the present invention that is to substitute for a conventional interlayer insulation film made of SiN and to form an interlayer insulation film being a major constituent of the array substrate and the liquid crystal display element of this embodiment.

### <Second Radiation-Sensitive Resin Composition>

As described above, the interlayer insulation film of the array substrate of an embodiment of the present invention is an applied type interlayer insulation film made of an organic material and it is disposed between a common electrode and a pixel electrode. The second radiation-sensitive resin composition of an embodiment of the present invention is a radiation-sensitive resin composition suitable for the formation of this interlayer insulation film.

The second radiation-sensitive resin composition of an embodiment of the present invention comprises [X] an alkali-soluble resin, [Y] an oxide particle of at least one metal selected from the group consisting of aluminum, zirconium, titanium, zinc, indium, tin, antimony, and cerium, and [V] a chain transfer agent. The second radiation-sensitive resin composition can further comprise [Z] a polyfunctional acrylate and [W] a radiation-sensitive polymerization initiator.

[X] The alkali-soluble resin is not limited provided that it is a resin having alkali developability. In the case of the second radiation-sensitive resin composition, [X] the alkali-soluble resin is hereinafter also referred to simply as [X] polymer.

As the [X] polymer, the acrylic resin or the polyimide disclosed for the above-described first radiation-sensitive resin composition can be used. Among these, [X] polymer may especially be a polymer comprising (X1) a constitutional unit having an aromatic ring and (X2) a constitutional unit having a (meth)acryloyloxy group.

Further, the second radiation-sensitive resin composition of the present embodiment of the present invention may contain other optional ingredients as long as these ingredients do not ruin the effect of the present invention.

Each ingredient that can be contained in the second radiation-sensitive resin composition according to the present embodiment will be described below.

### <[X] Polymer>

As described above, the [X] polymer may be a polymer comprising (X1) a constitutional unit having an aromatic ring and (X2) a constitutional unit having a (meth)acryloyloxy group. The [X] polymer is an alkali-soluble resin, which can be dissolved in alkali. Here is described especially the [X] polymer, which is a polymer comprising (X1) a constitutional unit having an aromatic ring and (X2) a constitutional unit having a (meth)acryloyloxy group.

(X1) The constitutional unit having an aromatic ring is a constitutional unit represented by the following formula (3). Inclusion of (X1) the constitutional unit having an aromatic ring can improve the dielectric property of a resulting cured film, and can improve the refractive index property of the cured film, and further can improve the heat resistance of the cured film.

### Formula (3)

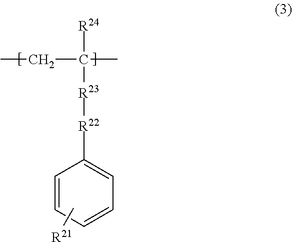

In the above formula (3), R²¹ represents an alkyl group having 1 to 12 carbon atoms, a hydroxy group, an alkoxyl group having 1 to 12 carbon atoms, or halogen. R²² represents a single bond, a methylene group, or an alkylene group having 2 to 6 carbon atoms. R²³ represents a single bond or an ester linkage. R²⁴ represents a hydrogen atom or a methyl group.

Examples of specific polymerizable compounds for forming the (X1) constitutional unit having an aromatic ring are as follows:

Styrene, p-hydroxy styrene, α-methyl styrene, m-methylstyrene, p-methylstyrene, p-chlorostyrene, p-methoxy styrene, p-(t-butoxy)styrene; phenyl acrylate, phenyl methacrylate, 4-hydroxyphenyl acrylate, 4-hydroxyphenyl methacrylate, benzyl acrylate, benzyl methacrylate, phenethyl acrylate, and phenethyl methacrylate.

Among these, especially styrene, benzyl acrylate, and benzyl methacrylate, are preferable from the perspective of polymerization.

The content of the constitutional unit having an aromatic ring (X1) in [X] the polymer is preferably 20 mol % to 90 mol %, more preferably 50 mol % to 80 mol %, of all the ingredients of the [X] polymer.

In the case of a content being small than 20 mol %, it is difficult to sufficiently improve the dielectric property or the refractive index property of a resulting cured film and the heat resistance is also insufficient. A content exceeding 90 mol % will cause defective development at the time of development and an undeveloped residue tends to remain.

(X2) The constitutional unit having a (meth)acryloyloxy group is obtained by reacting a (meth)acrylic acid ester having an epoxy group with a carboxyl group in a polymer. Desirably, the constitutional unit having a (meth)acryl group after the reaction is the same constitutional unit as a constitutional unit having a (meth)acryloyloxy group that can be possessed by [A] the alkali-soluble resin contained in the first radiation-sensitive resin composition of this embodiment and that is represented by the above formula (1).

In the above-described reaction of a carboxyl group in a polymer with an unsaturated compound such as a (meth)acrylic acid ester having an epoxy group, an unsaturated compound having an epoxy group is added to a polymer solution preferably containing a polymerization inhibitor in the presence of an appropriate catalyst according to necessity, followed by stirring for a prescribed time under heating. Examples of the catalyst include tetrabutylammonium bromide. Examples of the polymerization inhibitor include p-methoxyphenol. Preferably, the reaction temperature is 70° C. to 100° C. Preferably, the reaction time is 8 hours to 12 hours.

The content of the (X2) constitutional unit having a (meth)acryloyloxy group in the [X] polymer is preferably 10 mol % to 70 mol %, more preferably 20 mol % to 50 mol %, of all the ingredients of the [X] polymer.

In the case of a content of the (X2) constitutional unit having a (meth)acryloyloxy group being smaller than 10 mol %, the sensitivity of the second radiation-sensitive resin composition to the radiation tends to decrease, and the heat resistance of the obtained cured film is also insufficient. In the case where the (X2) constitutional unit of the (meth)acryloyloxy group contains more than 70 mol %, the constitutional unit will cause defective development at the time of development and an undeveloped residue tends to remain.

The carboxyl group in the polymer can be introduced by polymerizing an unsaturated monomer having a carboxyl group shown below.

Examples of such an unsaturated monomer include unsaturated monocarboxylic acids, unsaturated dicarboxylic acids, anhydrides of unsaturated dicarboxylic acids, and mono[(meth)acryloyloxyalkyl] esters of polyvalent carboxylic acids.

Examples of the unsaturated monocarboxylic acids include acrylic acid, methacrylic acid, and crotonic acid. Examples of the unsaturated dicarboxylic acids include maleic acid, fumaric acid, citraconic acid, mesaconic acid, and itaconic acid. Examples of the anhydrides of unsaturated dicarboxylic acids include anhydrides of the compounds provided above as examples of the aforementioned dicarboxylic acids.

Examples of the mono[(meth)acryloyloxyalkyl]esters of polyhydric carboxylic acids include mono[2-(meth)acryloyloxyethyl]succinate and mono[2-(meth)acryloyloxyethyl]phthalate.

Among these, acrylic acid, methacrylic acid, and maleic anhydride, are preferable. Acrylic acid, methacrylic acid, and maleic anhydride, are more preferable from the perspective of copolymerization reactivity, solubility in an aqueous alkali solution, and easy availability. These compounds may be used singly or by mixing two or more thereof.

Desirably, the ratio of use is more than the ratio of use of the (X2) constitutional unit having a (meth)acryloyloxy group by 5 mol % to 20 mol %. This is because the developability to an alkali developing solution is impaired if all carboxyl groups are reacted with a (meth)acrylic acid ester having an epoxy group. Therefore, the use rate is preferably within the range of 5 mol % to 90 mol %, more preferably within the range of 15 mol % to 70 mol %.

The [X] polymer may have, in addition to a (X1) constitutional unit having an aromatic ring (hereinafter also referred to simply as “(X1) constitutional unit”), a (X2) constitutional unit having a (meth)acryloyloxy group (hereinafter also referred to simply as “(X2) constitutional unit”), and the above-mentioned constitutional unit having an carboxyl group (hereinafter referred to as “(X3) constitutional unit”), the following constitutional unit derived from an unsaturated monomer (hereinafter referred to as “(X4) constitutional unit”).

Examples of (X4) the constitutional unit include the following constitutional units having an oxetanyl group.

Examples of an unsaturated monomer to form the constitutional unit having an oxetanyl group include

acrylic acid esters such as 3-(acryloyloxymethyl)oxetane, 3-(acryloyloxymethyl)-2-methyloxetane, 3-(acryloyloxymethyl)-3-ethyloxetane, 3-(acryloyloxymethyl)-2-phenyloxetane, 3-(2-acryloyloxyethyl)oxetane, 3-(2-acryloyloxyethyl)-2-ethyloxetane, 3-(2-acryloyloxyethyl)-3-ethyloxetane, and 3-(2-acryloyloxyethyl)-2-phenyloxetane, and

methacrylic acid esters such as 3-(methacryloyloxymethyl)oxetane, 3-(methacryloyloxymethyl)-2-methyl oxetane, 3-(methacryloyloxymethyl)-3-ethyloxetane, 3-(methacryloyloxymethyl)-2-phenyloxetane, 3-(2-methacryloyloxyethyl)oxetane, 3-(2-methacryloyloxyethyl)-2-ethyloxetane, 3-(2-methacryloyloxyethyl)-3-ethyloxetane, 3-(2-methacryloyloxyethyl)-2-phenyl oxetane, and 3-(2-methacryloyloxyethyl)-2,2-difluorooxetane.

Examples of an unsaturated monomer to form a constitutional unit having an alkyl group, which is a (X4) constitutional unit, include

methacrylic acid chain alkyl esters, such as methyl methacrylate, ethyl methacrylate, n-butyl methacrylate, sec-butyl methacrylate, t-butyl methacrylate, 2-ethylhexyl methacrylate, isodecyl methacrylate, n-lauryl methacrylate, tridecyl methacrylate, and n-stearyl methacrylate.

Examples of methacrylic acid cyclic alkyl esters include cyclohexyl methacrylate, 2-methylcyclohexyl methacrylate, tricyclo[5.2.1.0^{2,6}]decan-8-yl methacrylate, tricyclo[5.2.1.0^{2,6}]decan-8-yloxyethyl methacrylate, isoboronyl methacrylate, methyl acrylate, ethyl acrylate, n-butyl acrylate, sec-butyl acrylate, t-butyl acrylate, 2-ethylhexyl acrylate, isodecyl acrylate, n-lauryl acrylate, tridecyl acrylate, n-stearyl acrylate, cyclohexyl acrylate, 2-methylcyclohexyl acrylate, tricyclo[5.2.1.0^{2,6}]decan-8-yl acrylate, tricyclo[5.2.1.0^{2,6}]decan-8-yloxy ethyl acrylate, and isoboronyl acrylate.

Examples of the unsaturated monomer to form a constitutional unit having a maleimide skeleton, which is a (X4) constitutional unit, include

maleimide compounds, such as N-phenylmaleimide, N-cyclohexylmaleimide, N-benzylmaleimide, N-(4-hydroxyphenyl)maleimide, N-(4-hydroxybenzyl)maleimide, N-succinimidyl-3-maleimide benzoate, N-succinimidyl-4-maleimide butyrate, N-succinimidyl-6-maleimide caproate, N-succinimidyl-3-maleimide propionate and N-(9-acridinyl)maleimide.

Examples of the unsaturated monomer to form a constitutional unit containing a tetrahydrofuran skeleton include tetrahydrofurfuryl methacrylate, tetrahydrofurfuryl-2-methacryloyloxy-propionate, and 3-(meth)acryloyloxy tetrahydrofuran-2-one.

Of unsaturated monomers to constitute the (X4) constitutional unit, methyl methacrylate, t-butyl methacrylate, n-lauryl methacrylate, tricyclo[5.2.1.0^{2,6}]decan-8-yl methacrylate, 2-methylcyclohexyl acrylate, N-phenylmaleimide, N-cyclohexylmaleimide, and tetrahydrofurfuryl methacrylate are preferable from the perspective of copolymerization reactivity and solubility in an aqueous alkali solution.

These compounds may be used singly or by mixing two or more thereof.

The ratio of use is preferably 10% by mass to 80% by mass based on the total of the (X1) constitutional unit, the (X2) constitutional unit, the constitutional unit having a carboxyl group ((X3) constitutional unit), and the (X4) constitutional unit.

The [X] polymer can be produced, for example, by copolymerizing, in a solvent in the presence of a polymerization initiator, a compound for forming the above (X1) constitutional unit (hereinafter referred to also as “(X1) compound”) and a compound for forming the above (X2) constitutional unit (hereinafter referred to also as “(X2) compound”) (a compound for forming an (X3) optional constitutional unit (hereinafter referred to also as “(X3) compound”) and an unsaturated monomer for forming a (X4) constitutional unit (hereinafter referred to also as “(X4) compound”).

Examples of the solvent to be used for a polymerization reaction for producing the [X] polymer include alcohols, glycol ethers, ethylene glycol alkyl ether acetates, diethylene glycol monoalkyl ethers, diethylene glycol dialkyl ethers, dipropylene glycol dialkyl ethers, propylene glycol monoalkyl ethers, propylene glycol alkyl ether acetates, propylene glycol monoalkyl ether propionates, methyl-3-methoxy propionate, ketones, and esters.

As the polymerization initiator to be used in the polymerization reaction for producing the [X] polymer, compounds which are commonly known as a radical polymerization initiator can be used. Examples of the radical polymerization initiator include azo compounds such as 2,2′-azobisisobutyronitrile (AIBN), 2,2′-azobis(2,4-dimethylvaleronitrile), and 2,2′-azobis(4-methoxy-2,4-dimethylvaleronitrile)

In the polymerization reaction for producing the [X] polymer, a molecular weight regulator can be used for the purpose of regulating a molecular weight.

Examples of the molecular weight regulator include halogenated hydrocarbons such as chloroform and carbon tetrabromide; mercaptans such as n-hexylmercaptan, n-octylmercaptan, n-dodecylmercaptan, t-dodecylmercaptan, and thioglycolic acid; xanthogens such as dimethyl xanthogen sulfide and diisopropyl xanthogen disulfide; terpinolenes, and an α-methylstyrene dimer.

The weight average molecular weight (Mw) of the [X] polymer is preferably 1000 to 30000, more preferably 5000 to 20000. Adjustment of the Mw of the [X] polymer to within the above range can enhance the sensitivity and the developability to radiation of the second radiation-sensitive resin composition. The Mw and the number average molecular weight (Mn) of the [X] polymer were measured by gel permeation chromatography (GPC) under the above-described conditions.

### <[Y] Metal Oxide Particle>

The [Y] oxide particle of a metal (hereinafter also referred to simply as “metal oxide particle”) is contained in the second radiation-sensitive resin composition of this embodiment, enabling control to increase the permittivity and the refractive index of a resulting interlayer insulation film.

The [Y] metal oxide particle is an oxide particle of at least one metal selected from the group consisting of aluminum, zirconium, titanium, zinc, indium, tin, antimony, and cerium, of these, an oxide particle of zirconium, titanium, or zinc is preferred, and an oxide particle of zirconium or titanium is more preferred. A titanic acid salt can also be used.

These metal oxide particles may be used singly or by mixing two or more thereof. The [Y] metal oxide particle may be a mixed oxide particle of the metals provided above as examples. Examples of the mixed oxide particle include ATO (Antimony-Tin Oxide), ITO, and IZO (Indium-Zinc Oxide). Commercially available products can be used as such metal oxide particles. For example, NanoTek (registered trademark) produced by C. I. Kasei Company, Limited can be used. A particle of a titanic acid salt also can be used.

The shape of the [Y] metal oxide particle is not particularly limited: a spherical particle and an irregular-shaped particle are available, and a hollow particle, a porous particle, a core-shell type particle, etc. are also available.

The number average particle diameter of the [Y] metal oxide particle determined by a dynamic light scattering method is preferably 5 nm to 200 nm, more preferably 5 nm to 100 nm, even more preferably 10 nm to 80 nm. If the number average particle diameter of the [Y] metal oxide particle is smaller than 5 nm, the hardness of a cured film may decrease, whereas if it exceeds 200 nm, the haze of a cured film may become high.

Use of an oxide of a more favorable metal, zirconium or titanium, in the [Y] metal oxide particle can realize a high permittivity and makes it easier to perform control of the permittivity of an interlayer insulation film. Moreover, it can realize a high refractive index in an interlayer insulation film. Possible reasons for the favorable use of zirconium or titanium include the presence of high polarization in a particle due to low electronegativity of these metals. Therefore, as the [Y] metal oxide particle, an oxide particle of a metal having an electronegativity of 1.7 or less is preferred, and an oxide particle of a metal having an electronegativity of 1.6 or less is more preferred.

When a particle of a titanic acid salt is used, the titanic acid salt is favorable because it can achieve increase in permittivity and refractive index. Examples of such a titanic acid salt include potassium titanate, barium titanate, strontium titanate, calcium titanate, magnesium titanate, lead titanate, aluminum titanate, and lithium titanate. Of these, especially, barium titanate and strontium titanate are preferred from the perspective of achieving an increased permittivity.

Preferably, the [Y] metal oxide particle is dispersed together with a dispersing agent in a dispersing medium and is used in the form of a metal oxide particle dispersion liquid for the second radiation-sensitive resin composition. Thus, inclusion of the dispersing agent allows the [Y] metal oxide particle to disperse more uniformly, successfully enhancing the spreadability, and it enhances the adhesion of a resulting cured film and can evenly and uniformly increase the permittivity and the refractive index.

Examples of the dispersing agent include a nonionic dispersing agent, a cationic dispersing agent, and an anionic dispersing agent; a nonionic dispersing agent is preferred from the perspective of improving the positive radiation-sensitive property and the patterning property. Preferably, the nonionic dispersing agent is a polyoxyethylene alkylphosphate ester, an amide amine salt of a high-molecular-weight polycarboxylic acid, an ethylenediamine PO-EO condensate, a polyoxyethylene alkyl ether, a polyoxyethylene alkylphenol ether, an alkyl glucoside, a polyoxyethylene fatty acid ester, a sucrose fatty acid ester, a sorbitan fatty acid ester, a polyoxyethylene sorbitan fatty acid ester, or a fatty acid alkanolamide.

The dispersing medium is not particularly limited provided that it can disperse the [Y] metal oxide particle uniformly. The dispersing medium allows a dispersing agent to function effectively and can disperse the [Y] metal oxide particle uniformly.

As the dispersing medium, there can be used alcohols such as methanol, ethanol, isopropanol, butanol, and octanol; esters such as ethyl acetate, butyl acetate, ethyl lactate, γ-butyrolactone, propylene glycol monomethyl ether acetate, and propylene glycol monoethyl ether acetate; ethers such as ethylene glycol monomethyl ether, propylene glycol monomethyl ether, diethylene glycol monobutyl ether, and diethylene glycol methyl ethyl ether; esters such as propylene glycol monomethyl ether acetate and methyl-3-methoxypropionate; amides such as dimethylformamide, N,N-dimethylacetacetamide, and N-methylpyrrolidone; ketones such as acetone, methyl ethyl ketone, methyl isobutyl ketone, and cyclohexanone; aromatic hydrocarbons such as benzene, toluene, xylene, and ethylbenzene. Of these, acetone, methyl ethyl ketone, methyl isobutyl ketone, benzene, toluene, xylene, methanol, isopropyl alcohol, propylene glycol monomethyl ether are preferred, and methyl ethyl ketone, propylene glycol monomethyl ether, diethylene glycol methyl ethyl ether, propylene glycol monomethyl ether acetate, and methyl-3-methoxypropionate are more preferred. Regarding the dispersing medium, one species thereof may be used, or alternatively two or more species thereof may be used in combination.

Metal oxide particle of the dispersion liquid is preferably 5% to 50%, more preferably 10% to 40%.

The amount of [Y] metal oxide particles are not limited but is preferably 0.1 parts by mass to 1500 parts by mass, more preferably 1 parts by mass to 1000 parts by mass with respect to 100 parts by mass of the [X] polymer. If the loading of the [Y] metal oxide particle is less than 0.1 parts by mass, an effect of increasing the permittivity of a resulting cured film is not achieved to a sufficient extent. On the contrary, if the loading of the metal oxide particle exceeds 1500 parts by mass, the spreadability of the second radiation-sensitive resin composition deteriorates and the haze of a resulting cured film may be high.

Preferably, the specific surface area (determined by the BET specific surface area method using nitrogen) of the [Y] metal oxide particle is 10 m²/g to 1000 m²/g, more preferably 100 m²/g to 500 m²/g. When a polymerizable group high in cationic polymerizability such as an oxiranyl group is present in the [X] polymer, use of the above-mentioned as the [Y] metal oxide particle allows the surface of the [Y] metal oxide particle to act photocatalytically upon application of radiation such as ultraviolet rays and, in some case, it catalytically promotes a cross-linking reaction of the [X] polymer. In this case, due to the fact that the specific surface area of the [Y] metal oxide particle is within the above range, the above-mentioned photocatalytic action develops effectively and a desired radiation-sensitive property is exerted to a higher extent.

### <[Z] Polyfunctional Acrylate>

The second radiation-sensitive resin composition of this embodiment can contain a polyfunctional acrylate; as the polyfunctional acrylate, it can contain a polymerizable compound having a plurality of (meth)acryloyl groups in its molecule. One of the functions of this polymerizable compound is to polymerize, thereby increasing the molecular weight or forming a cross-linked structure, when the second radiation-sensitive resin composition is irradiated with light, which is radiation. Inclusion of such a polymerizable compound allows the whole coating film of the second radiation-sensitive resin composition to be cured. Moreover, it improves contrast between a portion irradiated with light and an unirradiated portion, and it can prevent delamination during development and can suppress the formation of a residue.

The “(meth)acryloyl group” as used herein refers to an acryloyl group or a methacryloyl group, and “having a plurality of (meth)acryloyl groups in its molecule” means that the total number of acryloyl groups and methacryloyl groups existing in the molecule is 2 or more. In this case, it is required only that the total number of these groups be 2 or more, and one or both of an acryloyl group and a methacryloyl group may be nonexistent.

The following are examples of the polymerizable compound having a plurality of (meth)acryloyl groups in its molecule.

Examples of the polymerizable compound having two (meth)acryloyl groups in its molecule include 1,3-butanediol di(meth)acrylate, 1,4-butanediol di(meth)acrylate, 1,6-hexanediol di(meth)acrylate, 1,10-decanediol di(meth)acrylate, neopentylglycol di(meth)acrylate, 2,4-dimethyl-1,5-pentanediol di(meth)acrylate, butylethylpropanediol (meth)acrylate, ethoxylated cyclohexanemethanol di(meth)acrylate, ethylene glycol di(meth)acrylate, diethylene glycol di(meth)acrylate, triethylene glycol di(meth)acrylate, polyethylene glycol di(meth)acrylate, oligoethylene glycol di(meth)acrylate, dipropylene glycol di(meth)acrylate, polypropylene glycol di(meth)acrylate, 2-ethyl-2-butyl-butanediol di(meth)acrylate, fluorene di(meth)acrylate, hydroxypivalic acid neopentyl glycol di(meth)acrylate, EO-modified bisphenol A di(meth)acrylate, bisphenol F polyethoxydi(meth)acrylate, oligopropylene glycol di(meth)acrylate, 2-ethyl-2-butyl-propanediol di(meth)acrylate, 1,9-nonanediol di(meth)acrylate, propoxylated ethoxylated bisphenol A di(meth)acrylate, tricyclodecane di(meth)acrylate, and bis(2-hydroxyethyl)isocyanurate di(meth)acrylate.

Examples of the polymerizable compound having three (meth)acryloyl groups in its molecule include trimethylolpropane tri(meth)acrylate, trimethylolethane tri(meth)acrylate, alkylene oxide-modified tri(meth)acrylate of trimethylolpropane, pentaerythritol tri(meth)acrylate, dipentaerythritol tri(meth)acrylate, trimethylolpropane tri{(meth)acryloyloxypropyl}ether, glycerol tri(meth)acrylate, tris(2-hydroxyethyl)isocyanurate tri(meth)acrylate, isocyanuric acid alkylene oxide-modified tri(meth)acrylate, propionic acid dipentaerythritol tri(meth)acrylate, tri{(meth)acryloyloxyethyl}isocyanurate, hydroxypivalaldehyde-modified dimethylol propane tri(meth)acrylate, sorbitol tri(meth)acrylate, propoxylated trimethylolpropane tri(meth)acrylate, and ethoxylated glyceryl triacrylate.

Examples of the polymerizable compound having four (meth)acryloyl groups in its molecule include pentaerythritol tetra(meth)acrylate, sorbitol tetra(meth)acrylate, ditrimethylolpropane tetra(meth)acrylate, propionic acid dipentaerythritol tetra(meth)acrylate, ethoxylated pentaerythritol tetra(meth)acrylate, and succinic acid-modified pentaerythritol triacrylate.

Examples of the polymerizable compound having five (meth)acryloyl groups in its molecule include sorbitol penta(meth)acrylate and dipentaerythritol penta(meth)acrylate.

Examples of the polymerizable compound having six (meth)acryloyl groups in its molecule include dipentaerythritol hexa(meth)acrylate, sorbitol hexa(meth)acrylate, alkylene oxide-modified hexa(meth)acrylate of phosphazene, and caprolactone-modified dipentaerythritol hexa(meth)acrylate.

The [Z] polyfunctional acrylate may be a polymerizable compound having seven or more (meth)acryloyl groups. The [Z] polyfunctional acrylate may be, of the above-described polymerizable compounds, (meth)acrylates having hydroxy groups or poly(meth)acrylates that are ethylene oxide- or propylene oxide-adducts to the hydroxy groups. Moreover, as the [Z] polyfunctional acrylate, an oligoester (meth)acrylate, an oligoether (meth)acrylate, an oligoepoxy (meth)acrylate, or the like can be used, provided that it is a compound having two or more (meth)acryloyl groups.

As the [Z] polyfunctional acrylate, among these, pentaerythritol tri(meth)acrylate, fluorene di(meth)acrylate, and oligoester (meth)acrylate{dendrimer (meth)acrylate}, are preferable from the perspective of excellence in polymerization.

Examples of commercially available products of the polymerizable compounds provided above as the [Z] polyfunctional acrylate include ARONIX (registered trademark) M-400, M-404, M-408, M-450, M-305, M-309, M-310, M-313, M-315, M-320, M-350, M-360, M-208, M-210, M-215, M-220, M-225, M-233, M-240, M-245, M-260, M-270, M-1100, M-1200, M-1210, M-1310, M-1600, M-221, M-203, TO-924, TO-1270, TO-1231, TO-595, TO-756, TO-1343, TO-902, TO-904, TO-905, TO-1330, TO-1450, and TO-1382 produced by Toagosei Co., Ltd., KAYARAD (registered trademark) D-310, D-330, DPHA, DPCA-20, DPCA-30, DPCA-60, DPCA-120, DN-0075, DN-2475, SR-295, SR-355, SR-399E, SR-494, SR-9041, SR-368, SR-415, SR-444, SR-454, SR-492, SR-499, SR-502, SR-9020, SR-9035, SR-111, SR-212, SR-213, SR-230, SR-259, SR-268, SR-272, SR-344, SR-349, SR-601, SR-602, SR-610, SR-9003, PET-30, T-1420, GPO-303, TC-120S, HDDA, NPGDA, TPGDA, PEG400DA, MANDA, HX-220, HX-620, R-551, R-712, R-167, R-526, R-551, R-712, R-604, R-684, TMPTA, THE-330, TPA-320, TPA-330, KS-HDDA, KS-TPGDA, and KS-TMPTA produced by Nippon Kayaku Co., Ltd., LIGHT ACRYLATE PE-4A, DPE-6A, and DTMP-4A produced by Kyoeisha Chemical Co., Ltd., VISCOAT #802 produced by Osaka Organic Chemical Industry Ltd.; and mixtures of tripentaerythritol octaacrylate and tripentaerythritol heptaacrylate.

Preferably, the content of the [Z] polyfunctional acrylate in the second radiation-sensitive resin composition of this embodiment is 1% by mass to 20% by mass relative to the whole second radiation-sensitive resin composition. When the second radiation-sensitive resin composition of this embodiment contains an organic solvent, the content of the [Z] polyfunctional acrylate polymerizable compound in the second radiation-sensitive resin composition of this embodiment is preferably adjusted to within the range of 5% by mass to 50% by mass relative to the total of the ingredients excluding the organic solvent, and more preferably is within the range of 10% by mass to 40% by mass. Due to inclusion of the [Z] polyfunctional acrylate in a content within the above range, a cured film with high hardness can be obtained from the second radiation-sensitive resin composition.

### <[V] Chain Transfer Agent>

As described above, due to use of a radiation-sensitive resin composition, a cured film can be formed and an applied type organic insulation film suitable as an interlayer insulation film can be obtained. However, when the organic insulation film is, for example, a film as thin as approximately 1 μm or less and is radically curable, it is prone to be cured insufficiently. If an interlayer insulation film has been cured insufficiently, it tends to suffer from development delamination during patterning or its insulation properties after film formation, especially, its leakage current properties tend to deteriorate.

Thus, the present inventors performed research for improving the curing performance of the second radiation-sensitive resin composition of this embodiment and have found that a chain transfer agent is effective for improving curing properties. That is, the second radiation-sensitive resin composition of this embodiment comprises a [V] chain transfer agent as an [V] ingredient. A chain transfer reaction is a reaction in which a radical of a growing polymer chain moves to another molecule during radical polymerization, and a chain transfer agent is an agent that causes a chain transfer reaction. The second radiation-sensitive resin composition of this embodiment comprises the [V] chain transfer agent and thereby can provide a thin interlayer insulation film with sufficiently high curing properties even if the film is as thin as 1 μm or less.

The [V] chain transfer agent contained in the second radiation-sensitive resin composition of this embodiment is not particularly limited, provided that it is a compound that functions as a chain transfer agent during a radical polymerization reaction. Examples of a [V] chain transfer agent preferably contained in the second radiation-sensitive resin composition of this embodiment include agents containing pyrazol derivatives and agents containing alkylthiols.

Examples of preferable [V] chain transfer agents include agents containing a compound having a mercapto group (thiol group), and the like, and examples of more preferable [V] chain transfer agents include compounds having two or more mercapto groups in one molecule, and the like.

The compound having two or more mercapto groups in one molecule that is preferably contained in the [V] chain transfer agent is not particularly limited, provided that it has two or more mercapto groups in one molecule. Examples thereof include at least one selected from the group consisting of compounds represented by the following formula (4).

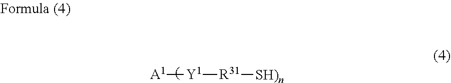

In the above formula (4), R³¹ is a methylene group or an alkylene group having 2 to 10 carbon atoms. It is noted that in these groups, some or all of the hydrogen atoms may have been replaced by alkyl groups. Y¹ is a single bond, —CO—, or —O—CO-*. It is noted that the bond with * is attached to R³¹. n is an integer of 2 to 10. A¹ is an n-valent hydrocarbon group having 2 to 70 carbon atoms and optionally having one ether linkage or a plurality of ether linkages or, when n is 3, a group represented by the following formula (5).

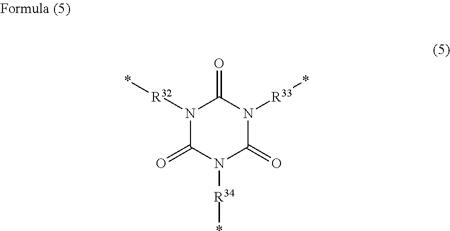

In the above formula (5), R³² to R³⁴ are each independently a methylene group or an alkylene group having 2 to 6 carbon atoms. “*” each represents a bond.

As the compound represented by the above formula (4), an esterified product of a mercaptocarboxylic acid with a polyhydric alcohol, and the like can typically be used. Examples of the mercaptocarboxylic acid to constitute the esterified product include thioglycolic acid, 3-mercaptopropionic acid, 3-mercaptobutanoic acid, and 3-mercaptopentanoic acid. Examples of the polyhydric alcohol to constitute the esterified product included ethylene glycol, propylene glycol, trimethylolpropane, pentaerythritol, tetraethylene glycol, dipentaerythritol, 1,4-butanediol, and pentaerythritol.

As the compound represented by the above formula (4), trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), pentaerythritol tetrakis(thioglycolate), 1,4-bis(3-mercaptobutyryloxy)butane, pentaerythritol tetrakis(3-mercaptobutyrate), pentaerythritol tetrakis(3-mercaptopentylate), and 1,3,5-tris(3-mercaptobutyloxyethyl)-1,3,5-triazine-2,4,6(1H,3H,5H)-trione are preferable.

As a thiol compound having two or more mercapto groups in one molecule, compounds represented by the following formula (6) to the following formula (8) can also be used.

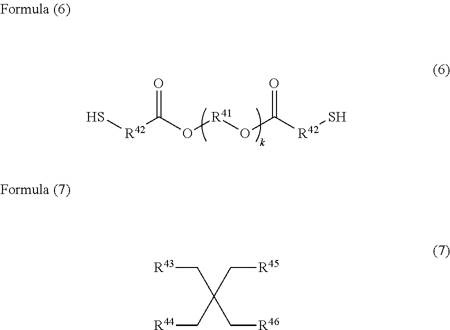

In the above formula (6), R⁴¹ is a methylene group or an alkylene group having 2 to 20 carbon atoms. R⁴² is a methylene group or a straight or branched alkylene group having 2 to 6 carbon atoms. k is an integer of 1 to 20.

In the above formula (7), R⁴³ to R⁴⁶ each independently represent a hydrogen atom, a hydroxy group, or a group represented by the following formula (8). At least one of R⁴³ to R⁴⁶ is a group represented by the following formula (8).

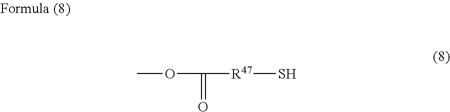

In the above formula (8), R⁴⁷ is a methylene group or a straight or branched alkylene group having 2 to 6 carbon atoms.

The [V] chain transfer agent may be used singly or by mixing two or more compounds. The content ratio of the [V] chain transfer agent in the second radiation-sensitive resin composition is preferably 0.5 parts by mass to 20 parts by mass, more preferably 1 parts by mass to 15 parts by mass with respect to 100 parts by mass of the [A] alkali-soluble resin. When the used amount of the [V] chain transfer agent is less than 0.5 parts by mass, an effect of increasing the hardenability is not sufficiently achieved, further, when the used amount of the [V] chain transfer agent is more than 20 parts by mass, because the sensitivity is too high the hardenability is increased by light leakage and thereby the pattern shape may be damaged.

### <[W] Radiation-Sensitive Polymerization Initiator>

The second radiation-sensitive resin composition of this embodiment may contain [W] a radiation-sensitive polymerization initiator together with [Z] the polyfunctional acrylate. The [W] radiation-sensitive polymerization initiator is a ingredient that senses radiation to generate an active species capable of initiating the polymerization of the [Z] polyfunctional acrylate. The [W] radiation-sensitive polymerization initiator is a photoradical polymerization initiator, for example. Examples of the [W] radiation-sensitive polymerization initiator include an O-acyloxime compound, an acetophenone compound, and a biimidazole compound, or the like, and further include those provided as the [D] radiation-sensitive polymerization initiator contained together with the [C] polymerizable compound in the above-mentioned first radiation-sensitive resin composition. These compounds may be used singly or by mixing two or more thereof.

The [W] radiation-sensitive polymerization initiator may be used singly or by mixing two or more thereof.

The amount of the [W] radiation-sensitive polymerization initiator is preferably 1 parts by mass to 40 parts by mass, more preferably 5 parts by mass to 30 parts by mass with respect to 100 parts by mass of the [X] polymer. Adjustment of the amount of the [W] radiation-sensitive polymerization initiator to 1 parts by mass to 40 parts by mass, allows the second radiation-sensitive resin composition to form an interlayer insulation film, excellent in solvent resistance, hardness, and adhesion, even under low exposure.

### <Optional Ingredients>

The second radiation-sensitive resin composition of this embodiment can contain [Z] a polyfunctional acrylate and [W] a radiation-sensitive polymerization initiator in addition to [X] a polymer, [Y] a metal oxide particle, and [V] a chain transfer agent, and it can further contain a dispersing agent and a dispersing medium to be used together with [Y] the metal oxide particle as well as other optional ingredients such as a surfactant according to necessity as long as the effect of the present invention is not adversely affected. Regarding the optional ingredients, two or more species thereof may be used in combination. In the following, individual ingredients are described.

### <Surfactant>

The surfactant contained in the second radiation-sensitive resin composition of this embodiment can be added for the purposes of improving the spreadability of the second radiation-sensitive resin composition, reducing uneven application, and improving the developability of a portion irradiated with radiation. Example of preferable surfactants include a fluorine-based surfactant and a silicone-based surfactant.

Examples of the fluorine-based surfactant include fluoroethers, such as 1,1,2,2-tetrafluorooctyl (1,1,2,2-tetrafluoropropyl) ether, 1,1,2,2-tetrafluorooctyl hexyl ether, octaethylene glycol di(1,1,2,2-tetrafluorobutyl) ether, hexaethylene glycol (1,1,2,2,3,3-hexafluoropentyl) ether, octapropylene glycol di(1,1,2,2-tetrafluorobutyl) ether, and hexapropylene glycol di(1,1,2,2,3,3-hexafluoropentyl) ether; sodium perfluorododecylsulfonate; fluoroalkanes, such as 1,1,2,2,8,8,9,9,10,10-decafluorododecane and 1,1,2,2,3,3-hexafluorodecane, sodium fluoroalkylbenzenesulfonates; fluoroalkyloxyethylene ethers; fluoroalkyl ammonium iodides; fluoroalkyl polyoxyethylene ethers; perfluoroalkylpolyoxyethanols, perfluoroalkyl alkoxylates; and fluorine-containing alkyl esters.

Examples of commercially available products of these fluorine-based surfactants include EFTOP (registered trademark) EF301, 303, 352 (produced by Shin-Akita Kasei Co., Ltd.), MEGAFAC (registered trademark) F171, 172, 173 (produced by DIC Corporation), FLUORAD FC430, 431 (produced by Sumitomo 3M Limited), Asahi Guard AG(registered trademark) 710 (produced by Asahi Glass Co., Ltd.), SURFLON (registered trademark) S-382, SC-101, 102, 103, 104, 105, and 106 (produced by AGC SEIMI CHEMICAL CO., LTD.), and FTX-218 (produced by NEOS Company Limited).

Examples of the silicone-based surfactant include SH200-100cs, SH28PA, SH30PA, ST89PA, SH190, SH 8400 FLUID (produced by Dow Corning Toray Silicone), and organosiloxane polymer KP341 (produced by Shin-Etsu Chemical Co., Ltd.), expressed by the names of commercially available products.

When using a surfactant as an optional ingredient, the content thereof is preferably 0.01 parts by mass to 10 parts by mass, more preferably 0.05 parts by mass to 5 parts by mass, relative to 100 parts by mass of the [X] polymer. Adjustment of the amount of the surfactant used to 0.01 parts by mass to 10 parts by mass can optimize the spreadability of the second radiation-sensitive resin composition.

### <Preparation of Second Radiation-Sensitive Resin Composition>

The second radiation-sensitive resin composition according to the present embodiment is prepared by mixing [X] the polymer, [Y] the metal oxide particle, and [V] the chain transfer agent, and by further mixing a surfactant according to necessity. In this case, an organic solvent can be used to prepare the second radiation-sensitive resin composition in a dispersion liquid state. The organic solvent may be used singly or by mixing two or more solvents.

Examples of the functions of the organic solvent include regulating the viscosity and the like of the second radiation-sensitive resin composition, thereby, for example, improving the spreadability to a substrate, and the like, or improving the operativity and the shapability. The viscosity of the second radiation-sensitive resin composition realized by inclusion of an organic solvent and the like is preferably 0.1 mPa·s to 50000 mPa·s (25° C.), for example, and more preferably 0.5 mPa·s to 10000 mPa·s (25° C.).

Examples of an organic solvent usable for the second radiation-sensitive resin composition include one that dissolves or disperses other ingredients and does not react with such other ingredients.

Examples thereof include alcohols such as methanol, ethanol, isopropanol, butanol, and octanol; ketones such as acetone, methyl ethyl ketone, methyl isobutyl ketone, and cyclohexanone; esters such as ethyl acetate, butyl acetate, ethyl lactate, γ-butyrolactone, propylene glycol monomethyl ether acetate, propylene glycol monoethyl ether acetate, and methyl-3-methoxypropionate; ethers such as polyoxyethylene lauryl ether, ethylene glycol monomethyl ether, diethylene glycol monobutyl ether, propylene glycol monomethyl ether, and diethylene glycol methyl ethyl ether; aromatic hydrocarbons such as benzene, toluene, and xylene; and amides such as dimethylformamide, dimethyl acetamide, and N-methylpyrrolidone.

The content of the organic solvent to be used in the second radiation-sensitive resin composition of this embodiment can be determined as appropriate in consideration of viscosity, etc.

The dispersion method preferably performed at the time of preparing the second radiation-sensitive resin composition in a dispersion liquid state may be a method in which dispersion is continued until no further decrease in particle diameter can be observed, using a paint shaker, an SC mill, an annular type mill, a pin type mill, or the like, usually at a peripheral speed of 5 m/s to 15 m/s. The continuation time is usually several hours. Preferably, dispersion beads such as glass beads and zirconia beads are used at the time of the dispersion. The bead diameter is not particularly limited and it is preferably 0.05 mm to 0.5 mm, more preferably 0.08 mm to 0.5 mm, even more preferably 0.08 mm to 0.2 mm.

Next, an alignment film applicable to the array substrate of this embodiment is described. The alignment film of this embodiment is formed using the liquid crystal aligning agent of this embodiment. Then, regarding the liquid crystal aligning agent of this embodiment, especially main ingredients are described below.

### <Liquid Crystal Aligning Agent>

The liquid crystal aligning agent of this embodiment comprises [L] a radiation-sensitive polymer having a photo-alignable group, or [M] a polyimide not having a photo-alignable group as a main ingredient. These can be cured, for example, by low temperature heating at 200° C. or less, or the like. Especially, a liquid crystal aligning agent containing the [L] radiation-sensitive polymer having a photo-alignable group enables formation of an alignment film at lower temperatures.

Thus, since the liquid crystal aligning agent of this embodiment enables alignment film formation by low temperature heating, it is possible to avoid application of heat history at high temperatures to an underlying insulation film or an interlayer insulation film.

The liquid crystal aligning agent according to the present embodiment can contain [N] other ingredients unless the effect of the present invention is impaired. In the following, these other ingredients are described.

### <[L] Radiation-Sensitive Polymer>

The [L] radiation-sensitive polymer is a polymer having a photo-alignable group and it can be contained in the liquid crystal aligning agent of this embodiment. The photo-alignable group of the [L] radiation-sensitive polymer is a functional group that gives anisotropy to a film upon irradiation with light, and especially in this embodiment, it is a group that gives anisotropy to a film by inducing at least one of a photoisomerization reaction and a photodimerization reaction.

Specifically, the photo-alignable group of a [L] radiation-sensitive polymer is a group having a structure derived from at least one compound selected from the group consisting of azobenzene, stilbene, α-imino-β-ketoester, spiropyran, spirooxazine, cinnamic acid, chalcone, stilbazole, benzylidenephthalimidine, coumarin, diphenylacetylene, and anthracene. Of these, a group having a structure derived from cinnamic acid is particularly preferable as the photo-alignable group.

Preferably, the [L] radiation-sensitive polymer is preferred is a polymer to which the above-mentioned photo-alignable group is attached directly or via a linking group. Examples of such a polymer include one in which the above-mentioned photo-alignable group is attached to at least either one of polyamic acid and polyimide, and one in which the above-mentioned photo-alignable group is attached to a polymer other than polyamic acid and polyimide. In the latter case, examples of the backbone of the polymer having the photo-alignable group include a poly(meth)acrylic acid ester, poly(meth)acrylamide, polyvinyl ether, polyolefin, and polyorganosiloxane.

Preferably, [L] the radiation-sensitive polymer is one in which polyamic acid, polyimide, or polyorganosiloxane is its backbone. Above all, polyorganosiloxane is particularly preferable and it can be obtained by the method disclosed in International Publication (WO) 2009/025386 pamphlet, for example.

### [[M] Polyimide]

The [M] polyimide is a polyimide having no photo-alignable groups. The liquid crystal aligning agent of this embodiment can contain the [M] polyimide.

[M] The polyimide is obtained by dehydration-cyclizing thereby imidizing a polyamic acid not having a photo-alignable group. Such a polyamic acid can be obtained, for example, by reacting

tetracarboxylic dianhydride with a diamine, and specifically, it can be obtained according to the method mentioned in Japanese Patent Application Laid-Open No. 2010-97188.

The [M] polyimide may be a completely imidized product obtained by dehydration-cyclizing all the amic acid structure possessed by the polyamic acid, which is the precursor to the polyimide, or alternatively may be a partially imidized product in which amic acid structures and imide ring structures are present together due to dehydration-cyclization of only part of amic acid structures.

The imidization ratio of the [M] polyimide is preferably 30% or more, more preferably 50% to 99%, even more preferably 65% to 99%. It is noted that the imidization ratio in this case is a ratio, expressed in percentage, of the number of the imide ring structure to the sum total of the number of the amic acid structure and the number of the imide ring structure of the polyimide. In this case, a part of the imide ring may be an isoimide ring. This alkali-soluble resin including the isoimide ring can be obtained, for example, according to the method mentioned in Japanese Patent Application Laid-Open No. 2010-97188.

### [[N] Other Ingredients]

The liquid crystal aligning agent of this embodiment can comprise [N] other ingredients other than the [L] radiation-sensitive polymer having a photo-alignable group and [M] the polyimide not having a photo-alignable group. Examples of such [N] other ingredients include polymers other than the [L] radiation-sensitive polymer having a photo-alignable group and the [M] polyimide not having a photo-alignable group, a curing agent, a curing catalyst, a cure promoter, an epoxy compound, a functional silane compound, a surfactant, and a photosensitizer.

Next, a method for producing an insulation film, an alignment film, and an array substrate will be described.

### <Method for Producing Interlayer Insulation Film, Insulation Film, Alignment Film, and Array Substrate>

In the process for producing the array substrate of this embodiment, a step of forming an interlayer insulation film being the second insulation film using the second radiation-sensitive resin composition of this embodiment is contained as a main step. The process can contain a step of forming an insulation film being the first insulation film using first radiation-sensitive resin composition of this embodiment.

Moreover, the process for producing the array substrate of this embodiment can contain a step of forming an alignment film from the above-described liquid crystal aligning agent of this embodiment in order to form an alignment film on the array substrate.

In the process for producing the array substrate of this embodiment, an insulation film, an interlayer insulation film, and an alignment film are formed in order; first, the insulation film is formed on a substrate. Therefore, the process for producing the array substrate of this embodiment preferably contains the following step [1] to step [4] in this sequence. Next, the process preferably contains the following step [5] to step [7] in this sequence so that an interlayer insulation film disposed between a common electrode and a pixel electrode may be formed on the substrate on which the insulation film has been formed. Moreover, the process preferably contains step [8] so that an alignment film may be formed on the array substrate on which the insulation film, an interlayer insulation film, and the like have been formed.

The step [1] to the step [8] included in the method for producing the array substrate according to the present embodiment, are as follows.

[1] Step of forming a coating film of the first radiation-sensitive resin composition comprising a polymer comprising a constitutional unit having a carboxyl group and a constitutional unit having a polymerizable group on a substrate on which an active element to be used for switching has been formed (hereinafter sometimes referred to as “step [1]”). An electrode or the like may have been formed on the substrate. In the following, the active element, the electrodes, and the like, namely, the semiconductor layer, the gate electrode, the gate insulation film, the source-drain electrode, the image signal line, the scan signal line, etc., which have already been described, may be collectively called “active elements.”

[2] Step of irradiating at least a part of the coating film of the first radiation-sensitive resin composition formed in step [1] with radiation (hereinafter sometimes referred to as “step [2]”).

[3] Step of developing the coating film on which the radiation was irradiated in step [2] (hereinafter sometimes referred to as “step [3]”)

[4] Step of forming an insulation film by curing the coating film developed in step [3] (hereinafter sometimes referred to as “step [4]”).

[5] Step of forming the coating film of the second radiation-sensitive resin composition on the substrate according to the embodiment of the present invention including the insulation film formed through Step [1] to Step [4] (hereinafter sometimes referred to as “step [5]”).

[6] Step of irradiating at least a part of the coating film formed in Step [5] with radiation (hereinafter sometimes referred to as “step [6]”).

[7] Step of developing the coating film irradiated with radiation in Step [6] (hereinafter sometimes referred to as “step [7]”).

[8] Step of forming a coating film of the liquid crystal aligning agent on the substrate including the insulation film formed through Step [1] to Step [4], and the insulation film formed through Step [5] to Step [7], thereafter forming an alignment film by heating the coating film at 200° C. or less (hereinafter sometimes referred to as “step [8]”).

Preferably, the process has, between step [4] and step [5] described above, a step of providing a common electrode on the insulation film formed in step [4]. Preferably, the process has, between step [7] and step [8] described above, a step of providing a comb-shaped pixel electrode on the interlayer insulation film formed in step [7]. In each of the steps between step [4] and step [5] described above and step [7] and step [8] described above, a common electrode and a pixel electrode are formed using a publicly known technology.

By means of step [1] to step [4], it is possible to form an insulation film on the substrate on which active elements have been formed, by using the first radiation-sensitive resin composition of this embodiment excelling in patterning property. The insulation film formed on the substrate has a contact hole. This insulation film has been reduced in the stretchability of the film to be induced by subsequent heating treatment.

By means of step [5] to step [7], it is possible to form an interlayer insulation film on the substrate on which active elements, an insulation film, a common electrode, and the like have been formed, by using the second radiation-sensitive resin composition of this embodiment. As described above, a comb-shaped pixel electrode is formed on the interlayer insulation film and thereby the interlayer insulation film disposed between the common electrode and the pixel electrode can be obtained.

The interlayer insulation film formed is an applied type interlayer insulation film capable of being formed and patterned simply by an application method or the like, and it is constituted using an organic material and exhibits excellent adhesion to a common electrode made of ITO or the like. The interlayer insulation film is excellent in curability even though it is a thin film, so that it exhibits excellent insulation properties. Moreover, since its permittivity has been controlled to a desired value and its electrostatic capacitance has been controlled, it can be used favorably instead of an interlayer insulation film made of conventional SiN.

By means of step [8], it is possible to form an alignment film on the substrate by low temperature cure using the liquid crystal aligning agent of this embodiment.

Consequently, by means of step [1] to step [8], there is produced the array substrate of this embodiment having a highly reliable insulation film provided with a contact hole at a prescribed position and an applied type interlayer insulation film having a desired permittivity and excellent insulation properties.

In the method for producing the array substrate of this embodiment, an insulation film and an interlayer insulation film can be formed by heating at a relatively lower temperature than before by using the first radiation-sensitive resin composition and the second radiation-sensitive resin composition of this embodiment, and so on. An alignment film also can be formed by heating at a relatively lower temperature than before. Therefore, it is suitable for a case where it is desired, from the perspective of energy saving, to lower the temperature of a heating step in a process for producing a liquid crystal display element or the like.

In the following, the above-mentioned Step [1] to Step [4], Step [5] to Step [7], and Step [8] will be described in detail.

### <Step [1]>

In this step, a coating film of the first radiation-sensitive resin composition of this embodiment is formed on a substrate. On this substrate have been formed an active element to be used for switching, electrodes, and the like. These active elements have been formed in accordance with a known method, for example, by repeating ordinary semiconductor film formation, known insulation layer formation, and so on, and etching by a photolithographic method, on the substrate. As the substrate, it is also possible to use one in which, for example, an inorganic insulation film made of a metal oxide such as SiO₂ or a metal nitride such as SiN has been formed on a switching active element or the like.

In the above-mentioned substrate, a coating film is formed by applying the first radiation-sensitive resin composition to a surface on which active elements have been formed, and then evaporating a solvent by performing prebaking.

Examples of the material of the substrate include substrates of glass, such as soda lime glass and alkali-free glass, substrates of silicon, or substrates of resin, such as polyethylene terephthalate, polybutylene terephthalate, polyethersulfone, polycarbonate, aromatic polyamide, polyamide-imide, and polyimide. These substrates may, if desired, have been subjected to pre-treatment, such as chemical treatment with a silane coupling agent or the like, plasma treatment, ion plating, sputtering, a gas phase reaction method, and vacuum deposition.

As for a coating method for the first radiation-sensitive resin composition, for example, a spray method, a roll coating method, a rotary coating method (sometimes referred to as a spin coating method or a spinner method), a slit coating method (a slit die coating method), a bar coating method, an inkjet coating method or the like can be adequately adopted. Among these, the spin coating method or the slit coating method is preferable from the perspective that a film having a uniform thickness can be formed.

Although the conditions for the above-mentioned prebaking may vary depending upon the type, the compounded ratio, and the like of the individual ingredients constituting the first radiation-sensitive resin composition, the prebaking is preferably performed at a temperature of 70° C. to 120° C., and the time, which may vary depending upon a heating apparatus such as a hot plate and an oven, is approximately 1 minute to 15 minutes. The thickness of the coating film after prebaking is preferably 0.5 μm to 10 μm, more preferably 1.0 μm to approximately 7.0 μm.

### [Step [2]]

Subsequently, at least a part of the coating film formed in step [1] is irradiated with radiation. At this time, a part of the coating film is irradiated, for example, through a photomask of a pattern corresponding to the formation of a desired contact hole.

Examples of the radiation to be used for irradiation include visible light, ultraviolet rays, and far ultraviolet rays. Of these, a radiation with a wavelength within the range of 200 nm to 550 nm is preferred, and a radiation containing an ultraviolet ray of 365 nm is more preferred.

The dose of radiation (also called light exposure), expressed by a value of the intensity of the radiation to be applied at a wavelength of 365 nm measured with a photometer (OAI model 356, manufactured by Optical Associates Inc.), may be adjusted to 10 J/m² to 10000 J/m², preferably 100 J/m² to 5000 J/m², more preferably 200 J/m² to 3000 J/m².

The first radiation-sensitive resin composition of this embodiment is higher in radiation sensitivity as compared with conventionally known compositions for insulation film formation. For example, an insulation film having a desired thickness, a good shape, excellent adhesion, and high hardness can be obtained even if the above-mentioned dose of radiation is 700 J/m² or less, or 600 J/m² or less.

### [Step [3]]

Next, the coating film after the irradiation of radiation in step [2] is developed and an unnecessary portion is removed, so that a coating film in which a contact hole in a predetermined shape has been formed is obtained.

As the developing solution to be used for the development, there can be used, for example, an aqueous solution of an inorganic alkali such as sodium hydroxide, potassium hydroxide, and sodium carbonate; a quaternary ammonium salt such as tetramethylammonium hydroxide and tetraethylammonium hydroxide; and an alkaline compound such as choline, 1,8-diazabicyclo-[5.4.0]-7-undecene, and 1,5-diazabicyclo-[4.3.0]-5-nonene. The above-mentioned aqueous solution of an alkaline compound may be used with addition of an appropriate amount of a water-soluble organic solvent such as methanol and ethanol. Moreover, the aqueous solution of an alkaline compound may be used with addition of an appropriate amount of a surfactant only or along with the addition of the above-mentioned water-soluble organic solvent.

The development method may be any method, such as puddle development, dipping development, shower development, and spray development, and the development time may be adjusted to 5 seconds to 300 seconds at ambient temperature, preferably approximately 10 seconds to approximately 180 seconds at ambient temperature. Subsequent to the development treatment, running water rinsing is performed for 30 seconds to 90 seconds, followed by blown dry with compressed air or compressed nitrogen, so that a desired pattern is obtained.

### [Step [4]]

Subsequently, the coating film obtained in step [3] is subjected to cure (also referred to as post-bake) with a suitable heating apparatus, such as a hot plate and an oven. Thus, an insulation film of this embodiment as a cured film is obtained. Preferably, the thickness of the insulation film after curing is 1 μm to 5 μm. In the insulation film, a contact hole disposed at a desired position has been formed in step [3].

By means of the first radiation-sensitive resin composition of this embodiment, the curing temperature can be adjusted to 200° C. or less. Moreover, an insulation film with sufficient properties can be obtained even at a temperature of 180° C. or less, which is more suitable for formation on a resin substrate. Specifically, the curing temperature is preferably adjusted to 100° C. to 200° C., when attempting to achieve both low temperature cure and heat resistance at a high level, it is more preferable to adjust the curing temperature to 150° C. to 180° C. Preferably, the curing time is adjusted to 5 minutes to 30 minutes on a hot plate or it is adjusted to 30 minutes to 180 minutes in an oven.

The first radiation-sensitive resin composition can promote the above-described low temperature cure by inclusion of [E] the thermal acid generator and [F] the cure accelerator, both described above. This is effective also in reduction of expansion and contraction of a film that occur when heating treatment is applied to a cured film. Moreover, due to inclusion of these compounds, storage stability is improved and sufficiently high radiation sensitivity and resolution are attained.

After forming the insulation film in step [4], it is preferred to provide a step of forming a common electrode being a transparent electrode as a first electrode, on the insulation film. For example, a transparent conductive layer made of ITO can be formed on the insulation film using a sputtering method or the like. Subsequently, a solid common electrode can be formed as a transparent electrode on the insulation film in a region where no contact hole is located, by etching that transparent conductive layer using a photolithographic method.

### [Step [5]]

In this step, using the substrate with the insulation film obtained in step [4], the second radiation-sensitive resin composition of this embodiment is applied to the substrate. Subsequently, when a solvent is contained in the coating film, the coated surface is preferably heated (prebaked) to remove the solvent, so that a coating film is formed.

A method for coating the second radiation-sensitive resin composition is not limited thereto. For example, a spray method, a roll coating method, a rotary coating method (a spin coating method), a slit die coating method, a bar coating method, an inkjet coating method or the like can be adequately adopted. Among these coating methods, the spin coating method or the slit die coating method is especially preferable. Although the conditions for the prebaking may vary depending upon the type, the compounded ratio, and the like of the individual ingredients, the prebaking is preferably performed approximately 1 minute to 10 minutes at 70° C. to 120° C.

### <Step [6]>

Subsequently, in the present step, at least a part of the coating film formed on the substrate in step [5] is irradiated with radiation. In this case, a part of the coating film is preferably irradiated with radiation through a photomask having a predetermined pattern. Examples of the radiation to be used for irradiation include, for example, a visible light, an ultraviolet ray, a far ultraviolet ray, an electron beam, an X-ray, or the like. Among these radiations, a radiation with a wavelength within the range of 190 nm to 450 nm is preferred, and a radiation containing an ultraviolet ray of 365 nm is especially preferred.

The dose of radiation in Step [6], expressed by a value of the intensity of the radiation to be applied at a wavelength of 365 nm measured with a photometer (OAI model 356, manufactured by Optical Associates Inc.), is preferably 100 J/m² to 10000 J/m², more preferably 500 J/m² to 6000 J/m²

### <Step [7]>

Next, in the present step, by developing the coating film obtained in step [6], after the irradiation of radiation an unnecessary portion (a radiation non-irradiated portion in the case where the coating film of the second radiation-sensitive resin composition is a negative type) is removed, thereafter a predetermined pattern is formed.

As the developing solution to be used for the developing step of Step [7], an alkali developer comprising an aqueous solution of an alkali (a basic compound) is preferably used. Examples of the alkali include sodium hydroxide, potassium hydroxide, sodium carbonate, sodium silicate, sodium metasilicate, inorganic alkali such as ammonia or the like; and quaternary ammonium salts, such as tetramethylammonium hydroxide and tetraethylammonium hydroxide or the like.

Such an alkali developing solution can be used with addition of an adequate amount of a water-soluble organic solvent, such as methanol and ethanol, or a surfactant. The concentration of the alkali in the alkali developing solution can preferably be adjusted to 0.1% by mass to 5% by mass from the perspective of obtaining suitable developability. As for the development method, for example, a puddle development method, a dipping development method, a swing and dipping development method, or a shower development method can adequately be used. Although the development time may vary depending upon the composition of the second radiation-sensitive resin composition, the time is preferably approximately 10 seconds to approximately 180 seconds. Subsequent to such development treatment, for example, running water rinsing is performed for 30 seconds to 90 seconds, followed by being blown dry with compressed air or compressed nitrogen, so that a desired pattern can be formed.

As mentioned above, the interlayer insulation film formed on the substrate by step [5] to step [7] is high in transparency and can exhibit a permittivity as high as approximately 5 to approximately 200. Since it has excellent curing properties, it can be reduced in thickness. Therefore, adjustment of film thickness such as reduction in film thickness may also be performed, and such adjustment can be controlled so that the film may have the same electrostatic capacitance property as that attained using a conventional interlayer insulation film made of SiN.

Moreover, the interlayer insulation film has a higher refractive index as compared with ordinary organic films. An interlayer insulation film formed from the second radiation-sensitive resin composition of this embodiment has a high refractive index of 1.50 or more, or 1.55 or more, which may vary depending upon the compounded ratios of the individual ingredients. For this reason, the refractive index difference from ITO or the like to constitute a pixel electrode described later can be reduced, so that deterioration in display quality caused by the refractive index difference can be suppressed.

The thickness of the interlayer insulation film is preferably 0.1 μm to 8 μm, more preferably 0.1 μm to 6 μm, even more preferably 0.1 μm to 4 μm. The interlayer insulation film of this embodiment is formed using the second radiation-sensitive resin composition of this embodiment and it can exhibit excellent curing properties even if it has a thickness of 1 μm or less, for example. Therefore, the thickness of a particularly favorable interlayer insulation film may be 0.1 μm to 1 μm.

As described above, after forming the interlayer insulation film, it is preferred to provide a step of forming a comb-shaped pixel electrode as a second electrode on the interlayer insulation film. For example, a transparent conductive layer made of ITO can be formed on the interlayer insulation film using a sputtering method or the like. Subsequently, a comb-shaped pixel electrode can be formed as a transparent electrode on the above-described interlayer insulation film, by etching that transparent conductive layer using a photolithographic method. The pixel electrode enables electrical connection with the switching active element on the substrate through the contact hole of the insulation film.

The common electrode and the pixel electrode can be constituted using ITO or a transparent material having a high transmittance to visible light and electrical conductivity. For example, they can be constituted using IZO (Indium Zinc Oxide), ZnO (zinc oxide), tin oxide, or the like.

### <Step [8]>

After forming the pixel electrode on the interlayer insulation film on the common electrode as described above using the substrate with the insulation film and the interlayer insulation film obtained in step [7], a liquid crystal aligning agent of this embodiment is applied onto the pixel electrode. Examples of the application method include a roll coater method, a spinner method, a printing method, and an inkjet method.

Subsequently, the substrate coated with the liquid crystal aligning agent is prebaked and then is post-baked, so that a coating film is formed.

The conditions for the prebaking are performed for 0.1 minutes to 5 minutes at 40° C. to 120° C., for example. Under these conditions, the temperature of the post-bake is preferably 120° C. to 230° C., more preferably 150° C. to 200° C., even more preferably 150° C. to 180° C. The time for the post-bake, which may vary depending upon a heating apparatus such as a hot plate and an oven, is usually preferably 5 minutes to 200 minutes, more preferably 10 minutes to 100 minutes. The thickness of the coating film after post-bake is preferably 0.001 μm to 1 μm, more preferably 0.005 μm to 0.5 μm.

The solid concentration of the liquid crystal aligning agent to be used when applying the liquid crystal aligning agent (the ratio of the total weight of the ingredients of the liquid crystal aligning agent excluding a solvent to the whole weight of the liquid crystal aligning agent) is chosen appropriately in consideration of viscosity, volatility, and the like, and it is preferably 1% by weight to 10% by weight.

When using a liquid crystal aligning agent containing [L] a radiation-sensitive polymer having a photo-alignable group as the liquid crystal aligning agent, a liquid crystal alignability is imparted to the above-described coating film by irradiating it with a linearly polarized or partially polarized radiation or an unpolarized radiation. Irradiation of such a polarization radiation corresponds to the alignment treatment for the alignment film.

As the radiation, an ultraviolet ray and a visible light containing a light having a wavelength of 150 nm to 800 nm can be used, for example. Especially, it is preferred to use an ultraviolet ray containing a light having a wavelength of 300 nm to 400 nm as the radiation. When the radiation to be used is linearly polarized or partially polarized, the irradiation may be performed either from the direction perpendicular to the surface of the substrate or from an oblique direction in order to provide a pretilt angle, or alternatively it may be performed by combining them. When irradiating with an unpolarized radiation, the direction of irradiation is required to be an oblique direction.

The dose of the radiation is preferably not less than 1 J/m² but less than 10000 J/m², more preferably 10 J/m² to 3000 J/m².

When using a liquid crystal aligning agent containing [M] a polyimide not having a photo-alignable group as the liquid crystal aligning agent, it is also possible to use the coating film after post-bake as the alignment film. Moreover, it is possible, according to necessity, to impart a liquid crystal alignability to the post-baked coating film by applying thereto treatment of rubbing in a certain direction with a roll around which a cloth made of fiber such as nylon, rayon, and cotton is wound (rubbing treatment).

When forming an alignment film on an array substrate as described above, it is possible to form an alignment film using the above-described liquid crystal aligning agent at a heating temperature of 200° C. or less, or according to the occasion at a heating temperature of 180° C. or less, which is more suitable for film formation on a resin substrate. Adjustment of the curing temperature in the alignment film formation step to such a low temperature enables the insulation film formed via step [1] to step [4] and the interlayer insulation film formed via step [5] to step [7] to avoid being exposed to a high temperature state during the step of forming an alignment film.

### EXAMPLES

Hereinafter, embodiments of the present invention are described in detail based on examples, but the present invention is not interpreted to be limited by the examples.

### <Preparation of First Radiation-Sensitive Resin Composition>

### Synthesis Example 1

### [A] Synthesis of Alkali-Soluble Resin (A-I)

A flask equipped with a cooling tube and a stirrer was charged with 8 parts by mass of 2,2′-azobis(2,4-dimethylvaleronitrile) and 220 parts by mass of diethylene glycol ethyl methyl ether. Subsequently, 13 parts by mass of methacrylic acid, 40 parts by mass of glycidyl methacrylate, 10 parts by mass of α-methyl-p-hydroxystyrene, 10 parts by mass of styrene, 12 parts by mass of tetrahydrofurfuryl methacrylate, 15 parts by mass of N-cyclohexylmaleimide, and 10 parts by mass of n-lauryl methacrylate were charged. After replacing with nitrogen, the temperature of the solution was raised to 70° C. and this temperature was held for 5 hours while gently stirring. Thus, polymerization was performed, so that a solution containing a copolymer (A-I) was obtained. The solid concentration of the resulting polymer solution was 31.9% by mass, and the copolymer (A-I) had an Mw of 8000 and a molecular weight distribution (Mw/Mn) of 2.3. The solid concentration means the ratio of the mass of the copolymer to the total mass of the polymer solution.

### Synthesis Example 2

### [A] Synthesis of Alkali-Soluble Resin (A-II)

A flask equipped with a cooling tube and a stirrer was charged with 4 parts by mass of 2,2′-azobisisobutyronitrile and 300 parts by mass of diethylene glycol methyl ethyl ether, and subsequently charged with 23 parts by mass of methacrylic acid, 10 parts by mass of styrene, 32 parts by mass of benzyl methacrylate, 35 parts by mass of methyl methacrylate, and 2.7 parts by mass of α-methylstyrene dimers as a molecular weight regulator. While gently stirring, the temperature of the solution was raised to 80° C. and this temperature was held for 4 hours, and then the temperature was raised to 100° C. and this temperature was held for 1 hour. Thus, polymerization was conducted, so that a solution containing a copolymer was obtained (solid concentration=24.9%). The Mw of the resulting copolymer was 12500. Subsequently, to the solution containing this copolymer were added 1.1 parts by mass of tetrabutylammonium bromide and 0.05 parts by mass of 4-methoxy phenol as a polymerization inhibitor, which were then stirred at 90° C. for 30 minutes under an air atmosphere. Then, 16 parts by mass of glycidyl methacrylate was added and a reaction was performed at 90° C. for 10 hours. Thus, a copolymer (A-II) was obtained (solid concentration=29.0%). The Mw of the copolymer (A-II) was 14200.

### Preparation of First Radiation-Sensitive Resin Composition

### [Preparation of Positive Type First Radiation-Sensitive Resin Composition]

The solution containing the copolymer (A-I) of Synthesis Example 1 in an amount corresponding to 100 parts by mass (solid content) of the copolymer as [A] the ingredient (alkali-soluble resin), 30 parts by mass of 4,4′-[1-[4-{1-(4-hydroxyphenyl)-1-methylethyl}phenyl]ethylidene]bisphenol (1.0 mol) as [B] the ingredient (quinonediazide compound), and 2 parts by mass of benzyl-4-hydroxyphenylmethylsulfonium hexafluorophosphate as [E] the ingredient (thermal acid generator) were mixed together, dissolved in diethylene glycol ethyl methyl ether so that the solid concentration might be 30% by mass, and then filtered through a membrane filter having a pore diameter of 0.2 μm. Thus, a first radiation-sensitive resin composition was prepared.

### Preparation of Negative Type First Radiation-Sensitive Resin Composition

The solution containing (A-I) the copolymer of Synthesis Example 1 in an amount corresponding to 10 parts by mass (solid content) of the copolymer and the solution containing (A-II) the copolymer of Synthesis Example 2 in an amount corresponding to 100 parts by mass (solid content) of the copolymer as [A] the ingredient, 100 parts by mass of a mixture of dipentaerythritol pentaacrylate and dipentaerythritol hexaacrylate (KAYARAD (registered trademark) DPHA (Nippon Kayaku Co., Ltd.)) as [C] the ingredient (polymerizable compound), 5 parts by mass of ethanone-1-[9-ethyl-6-(2-methylbenzoyl)-9H-carbazol-3-yl]-1-(O-acetyloxime) (Irgacure (registered trademark) OXE02, produced by BASF A.G) as [D] the ingredient, and 4,4′-diaminodiphenylsulfone as [F] the cure accelerator were mixed, propylene glycol monomethyl ether acetate was added so that the solid concentration might be 30% by mass, and then filtered through a millipore filter with a pore diameter of approximately 0.5 μm. Thus, a first radiation-sensitive resin composition was prepared.

### Preparation of Second Radiation-Sensitive Resin Composition

### Synthesis Example 3

### Synthesis of a Copolymer (α)

Synthesis of a copolymer (α), which is a [X] polymer to become an ingredient of a second radiation-sensitive resin composition, was performed according to the following.

A flask equipped with a cooling tube and a stirrer was charged with 4 parts by mass of 2,2′-azobisisobutyronitrile and 190 parts by mass of propylene glycol monomethyl ether acetate, and subsequently charged with 55 parts by mass of methacrylic acid, 45 parts by mass of benzyl methacrylate, and 2 parts by mass of α-methylstyrene dimers as a molecular weight regulator. While gently stirring, the temperature of the solution was raised to 80° C. and this temperature was held for 4 hours, and then the temperature was raised to 100° C. and this temperature was held for 1 hour. Thus, polymerization was conducted, so that a solution containing a copolymer was obtained. Subsequently, to the solution containing this copolymer were added 1.1 parts by mass of tetrabutylammonium bromide and 0.05 parts by mass of 4-methoxy phenol as a polymerization inhibitor, which were then stirred at 90° C. for 30 minutes under an air atmosphere. Then, 74 parts by mass of glycidyl methacrylate was added and a reaction was performed at 90° C. for 10 hours. Thus, a copolymer (α) was obtained (solid concentration=35.0%). The Mw of the copolymer (α) was 9000.

At this time, the content of the above-described (X1) structural unit in the copolymer (α) determined by ¹H-NMR and FT-IR was 37.5 mol %.

### Synthesis Example 4

### Synthesis of Copolymer (β)

Synthesis of a copolymer (β), which is [X] a polymer, was performed according to the following.

A flask equipped with a cooling tube and a stirrer was charged with 4 parts by mass of 2,2′-azobisisobutyronitrile and 190 parts by mass of propylene glycol monomethyl ether acetate, and subsequently charged with 85 parts by mass of methacrylic acid, 15 parts by mass of benzyl methacrylate, and 2 parts by mass of α-methylstyrene dimers as a molecular weight regulator. While gently stirring, the temperature of the solution was raised to 80° C. and this temperature was held for 4 hours, and then the temperature was raised to 100° C. and this temperature was held for 1 hour. Thus, polymerization was conducted, so that a solution containing a copolymer was obtained. Subsequently, to the solution containing this copolymer were added 1.1 parts by mass of tetrabutylammonium bromide and 0.05 parts by mass of 4-methoxy phenol as a polymerization inhibitor, which were then stirred at 90° C. for 30 minutes under an air atmosphere. Then, 74 parts by mass of glycidyl methacrylate was added and a reaction was performed at 90° C. for 10 hours. Thus, a copolymer ((3) was obtained (solid concentration=35.5%). The Mw of the copolymer (β) was 10000.

At this time, the content of (X1) the structural unit in the copolymer (β) determined by ¹H-NMR and FT-IR was 8.5 mol %.

### Synthesis Example 5

### Synthesis of Resin (γ) Including Epoxy Group

As a comparative example, synthesis of a copolymer (γ), which is a polymer including an epoxy group, was performed according to the following.

A flask equipped with a cooling tube and a stirrer was charged with 8 parts by mass of 2,2′-azobis(2,4-dimethylvaleronitrile) and 220 parts by mass of diethylene glycol methyl ethyl ether. Subsequently, 10 parts by mass of methacrylic acid, 40 parts by mass of glycidyl methacrylate, and 50 parts by mass of methyl methacrylate were charged. After replacing with nitrogen, the temperature of the solution was raised to 70° C. and this temperature was held for 5 hours while gently stirring. Thus, polymerization was performed, so that a solution containing a copolymer (γ) was obtained. The solid concentration of the resulting polymer solution was 31.9% by mass, and the copolymer (γ) had an Mw of 9000 and a molecular weight distribution (Mw/Mn) of 2.3.

### Example 1

### Preparation of Second Radiation-Sensitive Resin Composition 1

Three parts by mass of polyoxyethylene alkyl phosphate as a dispersing agent and 90 parts by mass of methyl ethyl ketone as a dispersing medium were mixed, and then 7 parts by mass of a zirconium oxide particle (ZrO₂ particle) as [Y] the ingredient (metal oxide particle) was added slowly over approximately 10 minutes while stirring with a homogenizer. After the addition of the zirconium oxide particle, stirring was continued for approximately 15 minutes. The resulting slurry was dispersed using an SC mill to obtain a ZrO₂ particle dispersion liquid.

To a solution of the copolymer (α) synthesized in Synthesis Example 3 as [X] the polymer (in an amount corresponding to 100 parts by mass (solid content) of the copolymer), 415 parts by mass of the above-described ZrO₂ particle dispersion liquid, 100 parts by mass of succinic acid-modified pentaerythritol triacrylate (“ARONIX (registered trademark) TO-756” produced by Toagosei Co, Ltd.) as the polyfunctional acrylate 1 that is [Z] the ingredient (polyfunctional acrylate), 10 parts by mass of pentaerythritol tetrakis(3-mercaptopropionate), which is a compound having a mercapto group (trade name: PEMPII-20P, produced by Sakai Chemical Industry Co., Ltd.) (hereinafter referred to as PEMP) as [V] the ingredient (chain transfer agent), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin composition was prepared.

### Example 2

### Preparation of Second Radiation-Sensitive Resin Composition 2

In Example 2, a TiO₂ particle dispersion liquid was prepared in the same manner as Example 1 except that a TiO₂ particle, a titanium oxide particle, was used as [Y] the ingredient (metal oxide particle) instead of the zirconium oxide particle (ZrO₂ particle). Subsequently, a second radiation-sensitive resin composition was prepared in the same manner as Example 1 except that the TiO₂ particle dispersion liquid was used and MAX-3510 (produced by Nippon Kayaku Co., Ltd.), which is a polyfunctional acrylate 2, was used as [Z] the ingredient (polyfunctional acrylate).

### Example 3

### Preparation of Second Radiation-Sensitive Resin Composition 3

In Example 3, a barium titanate particle dispersion liquid was prepared in the same manner as Example 1 except that a barium titanate particle that is a titanic acid salt, was used as [Y] the ingredient (metal oxide particle) instead of the zirconium oxide particle (ZrO₂ particle). Subsequently, using the barium titanate particle dispersion liquid, a second radiation-sensitive resin composition was prepared in the same manner as Example 1 except that the TiO₂ particle dispersion liquid was used and MAX-3510 (produced by Nippon Kayaku Co, Ltd.), which is a polyfunctional acrylate 2, was used as [Z] the ingredient (polyfunctional acrylate).

### Example 4

### Preparation of Second Radiation-Sensitive Resin Composition 4

In Example 4, a ZrO₂ particle dispersion liquid obtained in the same manner as Example 1, was used.

To a solution containing the copolymer (β) synthesized in Synthesis Example 4 as [X] the polymer (in an amount corresponding to 100 parts by mass (solid content) of the copolymer), 415 parts by mass of the above-described ZrO₂ particle dispersion liquid, 100 parts by mass of MAX-3510 (produced by Nippon Kayaku Co., Ltd.) as the polyfunctional acrylate 2 that is [Z] the ingredient (polyfunctional acrylate), 30 parts by mass of dipentaerythritol hexakis(3-mercaptopropionate), which is a compound having a mercapto group (produced by SC Organic Chemical Co., Ltd.) (hereinafter referred to as DPMP) as [V] the ingredient (chain transfer agent), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin composition was prepared.

### Example 5

### Preparation of Second Radiation-Sensitive Resin Composition 5

In Example 5, the second radiation-sensitive resin composition was prepared in the same manner as Example 1 except that 700 parts by mass of the above-mentioned ZrO₂ particle dispersion liquid as [X] the polymer is added, relative to the solution containing the copolymer (α) synthesized in Synthesis Example 3 (in an amount corresponding to 100 parts by mass (solid content) of the copolymer).

### Comparative Example 1

### Preparation of Radiation-Sensitive Resin Composition 1

In Comparative Example 1, the ZrO₂ particle dispersion liquid obtained in the same manner as Example 1, was used.

To a solution containing the copolymer (γ) synthesized in Synthesis Example 5 as [X] the polymer (in an amount corresponding to 100 parts by mass (solid content) of the copolymer), 415 parts by mass of the above-described ZrO₂ particle dispersion liquid, 100 parts by mass of succinic acid-modified pentaerythritol triacrylate (“ARONIX (registered trademark) TO-756” produced by Toagosei Co., Ltd.) as the polyfunctional acrylate 1 that is [Z] the ingredient (polyfunctional acrylate), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin composition was prepared.

### Comparative Example 2

### Preparation of Radiation-Sensitive Resin Composition 2

In Comparative Example 2, a radiation-sensitive resin composition was prepared without incorporating [Y] the ingredient (metal oxide particle).

To a solution containing the copolymer (α) synthesized in Synthesis Example 3 as [X] the polymer (in an amount corresponding to 100 parts by mass (solid content) of the copolymer), 100 parts by mass of MAX-3510 (produced by Nippon Kayaku Co., Ltd.), which is a polyfunctional acrylate 2 as [Z] the ingredient (polyfunctional acrylate), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin as a second comparative example, composition was prepared.

### Comparative Example 3

### Preparation of Radiation-Sensitive Resin Composition 3

In Comparative Example 3, the ZrO₂ particle dispersion liquid obtained in the same manner as Example 1, was used.

To a solution containing the copolymer (γ) synthesized in Synthesis Example 5 as [X] the polymer (in an amount corresponding to 100 parts by mass (solid content) of the copolymer), 140 parts by mass of the above-described ZrO₂ particle dispersion liquid, 100 parts by mass of succinic acid-modified pentaerythritol triacrylate (“ARONIX (registered trademark) TO-756” produced by Toagosei Co., Ltd.) as the polyfunctional acrylate 1 that is [Z] the ingredient (polyfunctional acrylate), 10 parts by mass of PEMP which is a compound having a mercapto group as [V] the ingredient (chain transfer agent), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin composition as a third comparative example, was prepared.

### Comparative Example 4

### Preparation of Second Radiation-Sensitive Resin Composition 4

In Comparative Example 4, the ZrO₂ particle dispersion liquid obtained in the same manner as Example 1, was used.

To a solution containing the copolymer (γ) synthesized in Synthesis Example 5 as [X] the polymer (in an amount corresponding to 100 parts by mass (solid content) of the copolymer), 1300 parts by mass of the above-described ZrO₂ particle dispersion liquid, 100 parts by mass of succinic acid-modified pentaerythritol triacrylate (“ARONIX (registered trademark) TO-756” produced by Toagosei Co., Ltd.) as the polyfunctional acrylate 1 that is [Z] the ingredient (polyfunctional acrylate), 10 parts by mass of PEMP which is a compound having a mercapto group as [V] the ingredient (chain transfer agent), 3 parts by mass of 2-methyl-1-(4-methylthiophenyl)-2-morpholinopropan-1-one (Irgacure (registered trademark) 907, produced by Ciba Specialty Chemicals) as [W] the ingredient (radiation-sensitive polymerization initiator), 0.3 parts by mass of SH8400 FLUID (produced by Dow Corning Toray Silicone) as a silicon-based surfactant, were added. Thus, a second radiation-sensitive resin composition as a fourth comparative example, was prepared.

### Example 6

### Evaluation of Cured Film

Using the second radiation-sensitive resin compositions prepared in Example 1 to Example 5 and the radiation-sensitive resin compositions prepared in Comparative Example 1 to Comparative Example 4, cured films were formed as follows and their properties were evaluated.

### (Evaluation of Thicknesses)

In order to evaluate the properties, 0.3 μm was taken as a target value of thickness for each of the cured films to be formed using the second radiation-sensitive resin compositions prepared in Example 1 to Example 4. 0.5 μm was taken as a target value of thickness for each of the cured films to be formed using the second radiation-sensitive resin composition prepared in Example 5. 0.3 μm was taken as a target value of thickness for each of the cured films to be formed using the radiation-sensitive resin compositions prepared in Comparative Example 1 to Comparative Example 2. 0.1 μm was taken as a target value of thickness for the cured films to be formed using the radiation-sensitive resin composition prepared in Comparative Example 3. 0.9 μm was taken as a target value of thickness for the cured films to be formed using the radiation-sensitive resin composition prepared in Comparative Example 4. The thicknesses (vim) used as the target values of the individual cured films are collectively shown in Table 1 given below.

As described below, cured films for evaluation were able to be formed in the cases where the second radiation-sensitive resin compositions prepared in Example 1 to Example 5 and the radiation-sensitive resin compositions prepared in Comparative Example 1 to Comparative Example 2 were used excluding the cases where the radiation-sensitive resin compositions prepared in Comparative Example 3 to Comparative Example 4 were used. In these cases, the thickness of the individual cured films formed was measured using a feeler type thickness meter (α Step) to confirm that the thickness shown as a target value was realized in the actual cured film. It is revealed that a desirable thickness of a cured film is 0.2 vim to 0.8 μm.

### (Evaluation of Patterning Property)

Each of the second radiation-sensitive resin compositions prepared in Example 1 to Example 5 and the radiation-sensitive resin compositions prepared in Comparative Example 1 to Comparative Example 4 was applied to a glass substrate (“Corning (registered trademark) 7059” produced by Corning Inc.) using a spinner and then was prebaked on a hot plate at 90° C. for 2 minutes to form a coating film.

Subsequently, the resulting coating films on glass substrates were subjected to exposure to light through a mask with a 5 cm×8 cm pattern by using a PLA (registered trademark)-501F exposure tool (ultrahigh pressure mercury lamp) manufactured by Canon Inc. Then, development was performed at 25° C. for 60 seconds using a 2.38% by mass aqueous solution of tetramethylammonium hydroxide. Subsequently, running water rinsing was performed with ultrapure water for 1 minute, and thereby patterned cured films were formed.

Edge parts of each patterned cured film were observed by an optical microscope, the patterning property was judged to be good when there was no development residue and a pattern was formed in a straight line.

On the other hand, the patterning property was judged to be poor when there was a development residue at an edge of a pattern. The evaluated results are collectively shown as “patterning property” in Table 1 given below. In Table 1, a case where the patterning property was judged to be good was indicated by a circular marker and a case where the patterning property was judged to be poor was indicated by a cross marker.

An evaluation “film formation impossible” was made for a case where a cured film was not able to be formed due to the occurrence of delamination of a coating film during a development stage like the radiation-sensitive resin compositions prepared in Comparative Example 3 and Comparative Example 4.

### (Evaluation of Transmittance)

Each of the second radiation-sensitive resin compositions prepared in Example 1 to Example 5 and the radiation-sensitive resin compositions prepared in Comparative Example 1 to Comparative Example 4 was applied to a glass substrate (“Corning (registered trademark) 7059” produced by Corning Inc.) using a spinner and then was prebaked on a hot plate at 90° C. for 2 minutes to form a coating film. Subsequently, irradiation with radiation (hereinafter also referred to as “exposure to light”) was performed by using a PLA (registered trademark)-501F exposure tool (ultrahigh pressure mercury lamp) manufactured by Canon Inc. and then development was performed using a 2.38% by mass aqueous solution of tetramethylammonium hydroxide. After drying, a light transmittance within a wavelength range of 400 nm to 800 nm was measured for the glass substrate with the cured film formed thereon by using a spectrophotometer “150-20 Type Double Beam” (manufactured by Hitachi, Ltd.), and for each glass substrate, the minimum value of the light transmittance (hereinafter referred to also as “minimum light transmittance”) within a wavelength range of 400 nm to 800 nm was evaluated. The light transmittance at a wavelength of 400 nm was used as the standard of evaluation, and when the light transmittance at a wavelength of 400 nm was 85% or more, the light transmittance property was judged to be particularly good. The evaluated results are collectively shown as “transmittance of the cured film (%)” in Table 1 given below.

The cured films obtained using the second radiation-sensitive resin compositions prepared in Example 1 to Example 5 and the radiation-sensitive resin compositions prepared in Comparative Example 1 to Comparative Example 2 all exhibited a light transmittance of 90% or more at a wavelength of 400 nm, and therefore the light transmittance property was particularly good. However, in a case where the radiation-sensitive resin compositions prepared in Comparative Example 3 and Comparative Example 4 were used, a cured film was not able to be formed due to the occurrence of delamination of a coating film during a development stage, thereby an evaluation of the transmittance was not able to be performed. In Table 1, it is shown as “evaluation impossible”.

### (Evaluation of Refractive Index)

The refractive index with a 633 nm light beam at 25° C. was measured by using an Abbe refractometer for the cured films obtained by the method described above (evaluation of transmittance) using the second radiation-sensitive resin compositions prepared in Example 1 to Example 5 and the radiation-sensitive resin compositions prepared in Comparative Example 1 to Comparative Example 4. The evaluated results are collectively shown as “refractive of the cured film (633 nm)” in Table 1 given below.

Further, in a case where the radiation-sensitive resin compositions prepared in Comparative Example 3 and Comparative Example 4 are used, a cured film was not able to be formed due to the occurrence of delamination of a coating film during a development stage, thereby an evaluation of the refractive index was not able to be performed. In Table 1, it is shown as “evaluation impossible”.

### (Evaluation of Permittivity)

Cured films were prepared on SUS substrates by the method described above (evaluation of transmittance) using the second radiation-sensitive resin compositions prepared in Example 1 to Example 5 and the radiation-sensitive resin compositions prepared in Comparative Example 3 to Comparative Example 4, and then electrodes were prepared thereon by aluminum vapor deposition. Using the substrates with electrodes, a permittivity was measured with an LCR meter. The evaluated results are collectively shown as “permittivity of the cured film (1 kHz)” in Table 1 given below.

Further, in a case where the radiation-sensitive resin compositions prepared in Comparative Example 3 and Comparative Example 4 are used, a cured film was not able to be formed due to the occurrence of delamination of a coating film during a development stage, thereby an evaluation of the refractive index was not able to be performed. In Table 1, it is shown as “evaluation impossible”.

### (Evaluation of Leakage Current)

In order to evaluate the insulation property of cured films formed using the second radiation-sensitive resin compositions prepared in Example 1 to Example 5 and the radiation-sensitive resin compositions prepared in Comparative Example 3 to Comparative Example 4, a leakage current was measured.

Like the (evaluation of permittivity) described above, cured films were prepared on SUS substrates by the method described above (evaluation of transmittance) using the second radiation-sensitive resin compositions prepared in Example 1 to Example 5 and the radiation-sensitive resin compositions prepared in Comparative Example 3 to Comparative Example 4, and then electrodes were prepared thereon by aluminum vapor deposition. Using the substrates with electrodes, a current value at the time of applying a voltage of 100 V was measured as a leakage current by using an electrometer 6517A (manufactured by Keithley Instruments Inc.). The evaluated results are collectively shown as “leakage current (A/m)” in Table 1 given below.

Further, in a case where the radiation-sensitive resin compositions prepared in Comparative Example 3 and Comparative Example 4 are used, a cured film was not able to be formed due to the occurrence of delamination of a coating film during a development stage, thereby measurement of the leakage current was not able to be performed. In Table 1, it is shown as “evaluation impossible”.

TABLE 1

| | | | | | | | | Compara- | Compara- | Compara- | Compara- |
|---|---|---|---|---|---|---|---|---|---|---|---|
| | | | Exam- | Exam- | Exam- | Exam- | | tive | tive | tive | tive |
| | | | ple 1 | ple 2 | ple 3 | ple 4 | Example 5 | Example 1 | Example 2 | Example 3 | Example 4 |
| Compositions/ | [X] | Copolymer α | 100 | 100 | 100 | — | 100 | — | 100 | — | — |
| Parts by Mass | Polymer | Copolymer β | — | — | — | 100 | — | — | — | — | — |
| | | Copolymer γ | — | — | — | — | — | 100 | — | 100 | 100 |
| | [Y] | ZrO₂ Dispersion | 415 | — | — | 415 | 700 | 415 | — | 140 | 1300 |
| | Metal Oxide | Liquid | | | | | | | | | |
| | Particle | TiO₂ Dispersion | — | 415 | — | — | — | — | — | — | — |
| | | Liquid | | | | | | | | | |
| | | Barium Titacate | — | — | 415 | — | — | — | — | — | — |
| | | Dispersion Liquid | | | | | | | | | |
| | [Z] | Polyfunctional | 100 | — | — | — | 100 | 100 | — | 100 | 100 |
| | Polyfunctional | Acrylate 1 | | | | | | | | | |
| | | Polyfunctional | — | 100 | 100 | 100 | — | — | 100 | — | — |
| | Acrylate | Acrylate 2 | | | | | | | | | |
| | [V] | PEMP | 10 | 10 | 10 | — | 10 | — | — | 10 | 10 |
| | Chain Transfer | DPMP | — | — | — | 30 | — | — | — | — | — |
| | Agent | | | | | | | | | | |

| | | | | | | | | | | |
|---|---|---|---|---|---|---|---|---|---|---|
| | [W] | 3 | 3 | 3 | 3 | 3 | 3 | 3 | 3 | 3 |
| | Radiation sencitive | | | | | | | | | |
| | Polymerization Initiator | | | | | | | | | |
| | Surfactors | 0.3 | 0.3 | 0.3 | 0.3 | 0.3 | 0.3 | 0.3 | 0.3 | 0.3 |
| Evaluation | Thickness (μm) | 0.3 | 0.3 | 0.3 | 0.3 | 0.5 | 0.3 | 0.3 | 0.1 | 0.9 |
| | Paterning Property | ∘ | ∘ | ∘ | ∘ | ∘ | x | ∘ | Film | Film |
| | | | | | | | | | Formation | Formation |
| | | | | | | | | | Impossible | Impossible |
| | Light Transmittance | 99 | 99 | 98 | 99 | 97 | 98 | 99 | Evaluation | Evaluation |
| | of the Cured Films (%) | | | | | | | | Impossible | Impossible |
| | Refractive Index of the | 1.65 | 1.75 | 1.69 | 1.64 | 1.74 | 1.61 | 1.33 | Evaluation | Evaluation |
| | Cured Films (633 mm) | | | | | | | | Impossible | Impossible |
| | Permittivity of the | 5.9 | 15.2 | 160 | 5.9 | 11.4 | 6.1 | 3.7 | Evaluation | Evaluation |
| | Cured Films (1 kHz) | | | | | | | | Impossible | Impossible |
| | Leakage Current (A/m) | 1 × | 2 × | 2 × | 7 × | 8 × 10⁻¹⁰ | 6 × 10⁻³ | 3 × 10⁻⁴ | Evaluation | Evaluation |
| | | 10⁻⁹ | 10⁻⁹ | 10⁻⁹ | 10⁻¹⁰ | | | | Impossible | Impossible |

In Table 1 as shown above, the compositions of the second radiation-sensitive resin compositions prepared in Example 1 to Example 5 and the radiation-sensitive resin compositions prepared in Comparative Example 1 to Comparative Example 4 are shown and the evaluated results of the cured films produced using those compositions are collectively shown. The marker “-” in the composition column of Table 1 means that the corresponding component was not used.

As shown in Table 1, the cured films produced using the second radiation-sensitive resin compositions prepared in Example 1 to Example 5 and the radiation-sensitive resin composition prepared in Comparative Example 4 each have good patterning property. The cured film produced using the radiation-sensitive resin composition prepared in Comparative Example 2 was poor in patterning property. Regarding the radiation-sensitive resin compositions prepared in Comparative Example 3 and Comparative Example 4, a coating film peeled during a development stage and no cured film was able to be formed.

The cured films produced using the radiation-sensitive resin compositions prepared using the second radiation-sensitive resin compositions prepared in Example 1 to Example 5 all exhibited high transmittance.

Further, the cured films produced using the second radiation-sensitive resin compositions prepared in Example 1 to Example 5 and the radiation-sensitive resin composition prepared in Comparative Example 1 each have high permittivity equal to 5 or more. The cured film produced using the radiation-sensitive resin composition prepared in Comparative Example 2 does not have permittivity more than 5.

Further, the cured films produced using the second radiation-sensitive resin compositions prepared in Example 1 to Example 5 and the radiation-sensitive resin composition prepared in Comparative Example 1 each have high refractive index of 1.6 or more. The cured film produced using the radiation-sensitive resin composition prepared in Comparative Example 2 does not have refractive index more than 1.55.

Further, the cured films produced using the radiation-sensitive resin composition prepared by the second radiation-sensitive resin compositions prepared in Example 1 to Example 5 each have lower leakage current and higher insulating property than the cured film produced using the radiation-sensitive resin composition prepared in Comparative Example 1 and Comparative Example 2.

The above reveals that the cured films produced using the second radiation-sensitive resin compositions prepared in Example 1 to Example 5 can be used suitably as an interlayer insulation film of an array substrate of a liquid crystal display element.

### <Production of Array Substrate>

### Example 7

The first radiation-sensitive resin composition obtained by the “preparation of a positive type first radiation-sensitive resin composition” described above was applied with a slit die coater onto a substrate on which an active element, electrodes, and the like had been formed.

In this substrate, active elements (a semiconductor layer, a gate electrode, a gate insulation film, a source-drain electrode, an image signal line, a scan signal line, etc.) have been formed. These active elements have been formed in accordance with a known method, for example, by repeating ordinary semiconductor film formation, known insulation layer formation, and so on, and etching by a photolithographic method, on the substrate.

Next, this substrate was heated on a hot plate at 100° C. and prebaked for 2 minutes to form a 4.0 μm thick coating film. Subsequently, the resulting coating film irradiated with radiation at an exposure of 1000 J/m² through a photomask with a prescribed pattern by using a high-pressure mercury lamp, and then was developed at 25° C. for 80 seconds using a 2.38% by mass aqueous solution of tetramethylammonium hydroxide. Subsequently, it was post-baked in an oven at a curing temperature of 230° C. for a curing time of 30 minutes, and thereby an insulation film in which a desired contact hole had been formed was formed.

Next, to the substrate on which the insulation film had been formed, a transparent conductive layer made of ITO was formed on the insulation film using a sputtering method. Subsequently, a solid common electrode was formed on the insulation film, by etching the transparent conductive layer using a photolithographic method.

Then, using the second radiation-sensitive resin composition prepared in Example 1, a coating film was formed on a surface of a substrate on which a solid common electrode had been formed, according to the same method as that described above for (evaluation of transmittance of) the cured film of Example 6. Subsequently, the resulting coating film on substrate were subjected to exposure to light through a mask with a predetermined pattern by using a PLA (registered trademark)-501F exposure tool (ultrahigh pressure mercury lamp) manufactured by Canon Inc. Then, development was performed at 25° C. for 60 seconds using a 2.38% by mass aqueous solution of tetramethylammonium hydroxide. Subsequently, running water rinsing was performed with ultrapure water for 1 minute, and thereby patterned interlayer insulation film was formed on the surface of the substrate on which the common electrode had been formed.

Next, a transparent conductive layer made of ITO was formed on the interlayer insulation film using a sputtering method. Subsequently, a comb-shaped pixel electrode was formed on the interlayer insulation film, by etching this transparent conductive layer using a photolithographic method.

As described above, the array substrate of this example was produced. In the resulting array substrate of this example, a contact hole having a desired size had been formed at a desired position of the insulation film, and electrical connection between the pixel electrode and the source-drain electrode of the active element had been realized.

### Example 8

Using the first radiation-sensitive resin composition obtained by the “preparation of a negative type first radiation-sensitive resin composition” described above, the first radiation-sensitive resin composition was applied by a slit die coater onto a substrate on which an active element, like in Example 7, electrodes, and the like had been formed.

Next, this substrate was heated on a hot plate at 90° C. and prebaked for 2 minutes, and then a coating film having thickness of 4.0 μm was formed. Subsequently, the resulting coating film was irradiated with radiation at an exposure of 700 J/m² through a photomask with a prescribed pattern by using a high-pressure mercury lamp, and then was developed at 23° C. using a 0.40% by mass potassium hydroxide solution as a developer. Subsequently, it was post-baked in an oven at a curing temperature of 180° C. for a curing time of 30 minutes, and thereby an insulation film in which a desired contact hole had been formed was formed.

Next, to the substrate on which the insulation film had been formed, a transparent conductive layer made of ITO was formed on the insulation film using a sputtering method. Subsequently, a solid common electrode was formed on the insulation film, by etching the transparent conductive layer using a photolithographic method.

Thereafter, using the second radiation-sensitive resin composition prepared in Example 1, a coating film was formed on a surface of a substrate on which a solid common electrode had been formed on the insulation film, according to the same method as that described above for (evaluation of transmittance of) the cured film of Example 6. Subsequently, to the resulting coating film on substrate, exposure processing was performed through a mask with a predetermined pattern by using a PLA (registered trademark)-501F exposure tool (ultrahigh pressure mercury lamp) manufactured by Canon Inc. Thereafter, development was performed at 25° C. for 60 seconds using a 0.05% by mass aqueous solution of potassium hydroxide. Subsequently, running water rinsing was performed with ultrapure water for 1 minute, and thereby a patterned interlayer insulation film was formed on the surface of the substrate on which the common electrode had been formed.

Next, a transparent conductive layer made of ITO was formed on the interlayer insulation film using a sputtering method. Subsequently, a comb-shaped pixel electrode was formed on the interlayer insulation film, by etching this transparent conductive layer using a photolithographic method.

As described above, the array substrate of the present example was produced. In the resulting array substrate of the present example, a contact hole having a desired size was formed at a desired position of the insulation film, and electrical connection between the pixel electrode and the source-drain electrode of the active element was achieved.

### Example 9

A substrate, like in Example 7, on which an active element, electrodes, and the like had been formed, was used. Further, using the first radiation-sensitive resin composition obtained by the “preparation of a positive type first radiation-sensitive resin composition” described above, an array substrate according to this example was produced using the second radiation-sensitive resin composition prepared in Example 2 in the same manner as Example 7. In the resulting array substrate of this example, a contact hole having a desired size was formed at a desired position of the insulation film, and electrical connection between the pixel electrode and the source-drain electrode of the active element was achieved.

### Example 10

A substrate, like in Example 7, on which an active element, electrodes, and the like had been formed, was used. Further, using the first radiation-sensitive resin composition obtained by the “preparation of a positive type first radiation-sensitive resin composition” described above, an array substrate according to this example was produced using the second radiation-sensitive resin composition prepared in Example 3 in the same manner as Example 7. In the resulting array substrate of this example, a contact hole having a desired size was formed at a desired position of the insulation film, and electrical connection between the pixel electrode and the source-drain electrode of the active element was achieved.

### Example 11

A substrate, like in Example 7, on which an active element, electrodes, and the like had been formed, was used. Further, using the first radiation-sensitive resin composition obtained by the “preparation of a positive type first radiation-sensitive resin composition” described above, an array substrate according to this example was produced using the second radiation-sensitive resin composition prepared in Example 4 in the same manner as Example 7. In the resulting array substrate of this example, a contact hole having a desired size was formed at a desired position of the insulation film, and electrical connection between the pixel electrode and the source-drain electrode of the active element was achieved.

### Example 12

A substrate, like in Example 7, on which an active element, electrodes, and the like had been formed, was used. Further, using the first radiation-sensitive resin composition obtained by the “preparation of a positive type first radiation-sensitive resin composition” described above, an array substrate according to this example was produced using the second radiation-sensitive resin composition prepared in Example 5 in the same manner as Example 7. In the resulting array substrate of this example, a contact hole having a desired size was formed at a desired position of the insulation film, and electrical connection between the pixel electrode and the source-drain electrode of the active element was achieved.

### Example 13

### Production of Array Substrate Having Photo-Alignable Film (1)

Using the array substrate obtained in Example 7, a photo-alignment film was formed using a liquid crystal aligning agent containing a radiation-sensitive polymer having a photo-alignable group.

First, the liquid crystal aligning agent A-1 disclosed in Example 6 of International Publication (WO) 2009/025386 pamphlet as a liquid crystal aligning agent containing a radiation-sensitive polymer having a photo-alignable group was applied with a spinner onto the transparent electrode of the array substrate of Example 7. Subsequently, an 80 nm thick coating film was formed by performing prebake for 1 minute on a hot plate at 80° C., and then heating at 180° C. for one hour in a nitrogen-replaced oven. Subsequently, a polarized ultraviolet ray 200 J/m² containing a bright line of 313 nm was applied to the surface of the coating film from a direction tilting at 40° with respect to the direction perpendicular to the surface of the substrate by using a Hg—Xe lamp and a Glan-Taylor prism. Thus, an array substrate having a photo-alignment film was produced.

### Example 14

### Production of Array Substrate Having Photo-Alignable Film (2)

The array substrate obtained in Example 10 was used. Further, a photo-alignment film was formed using a liquid crystal aligning agent containing a radiation-sensitive polymer having a photo-alignable group, like in Example 13, and then an array substrate having the photo-alignment film was produced.

### <Production of Liquid Crystal Display Element>

### Example 15

A liquid crystal display element was produced using a color filter substrate produced by a known method and the array substrate (Example 7) having the photo-alignment film of Example 13 the interlayer insulation film of which had a permittivity of approximately 6.

First, there was prepared a color filter substrate produced by a known method. In this color filter substrate, fine coloring patterns of three colors, red, green and blue, and a black matrix are arranged in a grid on a transparent substrate.

Subsequently, a photo-alignment film the same as that formed on the array substrate in Example 13 was formed on the coloring patterns and the black matrix of the color filter substrate. A color liquid crystal display element was produced by sandwiching a liquid crystal layer between the resulting color filter substrate with a photo-alignment film and the array substrate (Example 7) obtained in Example 13. As the liquid crystal layer, there was used one made of a nematic liquid crystal and alignable in parallel with a substrates surface. This liquid crystal display element has the same structure as that of the above-described liquid crystal display element 41 shown in FIG. 3. The liquid crystal display element produced exhibited excellent operating characteristic, display characteristics, and reliability.

### Example 16

A liquid crystal display element was produced using a color filter substrate produced by a known method and the array substrate (Example 10) having the photo-alignment film of Example 14 in which the permittivity of the interlayer insulation film is approximately 6.

Firstly, a color filter substrate, like in Example 15, was prepared. Subsequently, a photo-alignment film the same as that formed on the array substrate in Example 15 was formed on the coloring patterns and the black matrix of the color filter substrate. A color liquid crystal display element was produced by sandwiching a liquid crystal layer between the resulting color filter substrate with a photo-alignment film and the array substrate obtained in Example 14, in the same manner as Example 15. This liquid crystal display element has the same structure as that of the above-described liquid crystal display element 41 shown in FIG. 3, like in Example 15. The liquid crystal display element produced exhibited excellent operating characteristic, display characteristics, and reliability.

The present invention is not limited to the above embodiments, and it may be performed with various modifications within a range not departing from the gist of the present invention.

For example, although the array substrate of this embodiment uses a bottom gate type TFT as an active element, it is not limited to the bottom gate type TFT, and a top gate type (forward stagger structure) TFT can be applied and used.

In this case, the active element of the array substrate of this embodiment is constituted by providing a semiconductor layer, a pair of a first source-drain electrodes and a second source-drain electrode each connected to the semiconductor layer on a substrate, and then disposing a gate electrode to overlap the semiconductor layer via a gate insulation film. At this time, as the semiconductor layer of the top gate type TFT, one using p-Si can suitably be applied. Moreover, it is preferred to dope a semiconductor layer using p-Si with an impurity such as phosphorus (P) or boron (B) to form a source region and a drain region sandwiching a channel region of the semiconductor layer. Moreover, it is preferred to form LDD (Lightly Doped Drain) layers between the channel region and the source region and the drain region of the semiconductor layer.

### INDUSTRIAL APPLICABILITY

The array substrate of the present invention can be produced by low temperature heating treatment and a liquid crystal display element produced using this array substrate has high reliability. Therefore, the array substrate and the liquid crystal display element of the present invention are suitable for such applications as large-sized liquid crystal television with which excellent image quality and reliability are required.

### REFERENCE SIGNS LIST

1 array substrate
4,11 substrate
5 image signal line
5a second source-drain electrode
6 first source-drain electrode
7 scan signal line
7a gate electrode
8 active element
8a semiconductor layer
9 pixel electrode
10 alignment film
12 insulation film
13 black matrix
14 common electrode
15 coloring pattern
17 contact hole
22 color filter substrate
23 liquid crystal layers
27 backlight unit
28 polarizer
31 gate insulation film
32 inorganic insulation film
33 interlayer insulation film
41 liquid crystal display element

1. An array substrate for an FFS-mode liquid crystal display element comprising:
a common electrode;
a pixel electrode; and
an interlayer insulation film disposed between the common electrode and the pixel electrode,
wherein the interlayer insulation film is formed using a radiation-sensitive resin composition containing:
[X] an alkali-soluble resin;
[Y] oxide particles of at least one metal selected from the group consisting of aluminum, zirconium, titanium, zinc, indium, tin, antimony, and cerium; and
[V] a chain transfer agent.

2. The array substrate according to claim 1, wherein the [X] alkali-soluble resin is a polymer comprising a (X1) constitutional unit having an aromatic ring and a (X2) constitutional unit having a (meth)acryloyloxy group.

3. The array substrate according to claim 2, wherein the content of the (X1) constitutional unit having the aromatic ring in the [X] alkali-soluble resin is 20 mol % to 90 mol % of the whole of the polymer.

4. The array substrate according to claim 1, wherein the [Y] oxide particles are particles of a titanic acid salt.

5. The array substrate according to claim 1, wherein the [V] chain transfer agent comprises a compound having a mercapto group.

6. The array substrate according to claim 1, wherein one of the common electrode and the pixel electrode has a comb-like shape and the other has a solid-like shape, and the one of the common electrode and the pixel electrode having the comb-like shape is disposed on the interlayer insulation film.

7. The array substrate according to claim 1, wherein the interlayer insulation film has a permittivity of 4 to 8.

8. The array substrate according to claim 1, wherein the interlayer insulation film has a refractive index of 1.55 to 1.85 at a wavelength of 633 nm.

9. The array substrate according to claim 1, wherein the interlayer insulation film has a light transmittance equal to 85% or more than 85% at a wavelength of 400 nm.

10. A liquid crystal display element comprising:
an array substrate for an FFS-mode liquid crystal display element comprising:
a common electrode;
a pixel electrode; and
an interlayer insulation film disposed between the common electrode and the pixel electrode,
wherein the interlayer insulation film is formed using a radiation-sensitive resin composition containing:
[X] an alkali-soluble resin;
[Y] oxide particles of at least one metal selected from the group consisting of aluminum, zirconium, titanium, zinc, indium, tin, antimony, and cerium; and
[V] a chain transfer agent.

11. A radiation-sensitive resin composition comprising:
[X] an alkali-soluble resin;
[Y] oxide particles of at least one metal selected from the group consisting of aluminum, zirconium, titanium, zinc, indium, tin, antimony, and cerium; and
[V] a chain transfer agent;
wherein the radiation-sensitive resin composition is usable for forming an interlayer insulation film of
an array substrate used for an FFS-mode liquid crystal display element, comprising:
a common electrode;
a pixel electrode; and
an interlayer insulation film disposed between the common electrode and the pixel electrode.

12. The liquid crystal display element according to claim 10, wherein the [X] alkali-soluble resin is a polymer comprising a (X1) constitutional unit having an aromatic ring and a (X2) constitutional unit having a (meth)acryloyloxy group.

13. The liquid crystal display element according to claim 10, wherein the content of the constitutional unit having the aromatic ring (X1) in the [X] alkali-soluble resin is 20 mol % to 90 mol % of the whole of the polymer.

14. The liquid crystal display element according to claim 10, wherein the [Y] oxide particles are particles of a titanic acid salt.

15. The liquid crystal display element according to claim 10, wherein the [V] chain transfer agent comprises a compound having a mercapto group.

16. The radiation-sensitive resin composition according to claim 11, wherein the [X] alkali-soluble resin is a polymer comprising a (X1) constitutional unit having an aromatic ring and a (X2) constitutional unit having a (meth)acryloyloxy group.

17. The radiation-sensitive resin composition according to claim 11, wherein the content of the (X1) constitutional unit having the aromatic ring in the [X] alkali-soluble resin is 20 mol % to 90 mol % of the whole of the polymer.

18. The radiation-sensitive resin composition according to claim 11, wherein the [Y] oxide particles are particles of a titanic acid salt.

19. The radiation-sensitive resin composition according to claim 11, wherein the [V] chain transfer agent comprises a compound having a mercapto group.
